(19) United States
(12) Patent Application Publication
(10) Pub. No.: US 2025/0344534 A1
(43) Pub. Date: Nov. 6, 2025

(54) SOLID-STATE IMAGING DEVICE

(71) Applicant: Sony Semiconductor Solutions Corporation, Kanagawa (JP)

(72) Inventors: Chie Tokumitsu, Kanagawa (JP); Ken Yahata, Kanagawa (JP); Shunsuke Kasashima, Kanagawa (JP); Shinichiro Noudo, Kumamoto (JP); Yukari Taguchi, Kumamoto (JP); Yosuke Mogami, Kanagawa (JP)

(21) Appl. No.: 18/876,784

(22) PCT Filed: Jul. 6, 2023
(86) PCT No.: PCT/JP2023/025064

§ 371 Date: Dec. 19, 2024

(30) Foreign Application Priority Data
Jul. 19, 2022 (JP) 2022-114497

(51) Int. Cl. H10F 39/00; H04N 25/62

(52) U.S. Cl. CPC H10F 39/8057; H04N 25/62; H10F 39/802; H10F 39/8053; H10F 39/8063

(57) ABSTRACT

Solid-state imaging devices configured to suppress large pixel to a small pixel light leakage are disclosed. In one example, a solid-state imaging device includes a pixel array in which unit pixels are two-dimensionally arranged. Each of the unit pixels includes a first photoelectric conversion unit that is formed in a semiconductor substrate, a second photoelectric conversion unit that has a smaller area than an area of the first photoelectric conversion unit, an inter-pixel light shielding film between the unit pixels on a side of incident light relative to the semiconductor substrate, a spacer layer that is provided on the side of the incident light relative to the inter-pixel light shielding film, and a light shielding wall between the unit pixels on the side of the incident light relative to the inter-pixel light shielding film and sections the spacer layer.

### TECHNICAL FIELD

The present disclosure relates to a solid-state imaging device, and particularly to a solid-state imaging device capable of suppressing light leakage from a large pixel to a small pixel.

### BACKGROUND ART

As a structure to enlarge a dynamic range of pixels, there is a solid-state imaging device including large pixels with high sensitivity in which areas of photoelectric conversion regions are enlarged and small pixels with low sensitivity in which areas of photoelectric conversion regions are reduced (see PTL 1, for example).

### CITATION LIST

### Patent Literature

### [PTL 1]

JP 2017-163010A

### SUMMARY

### Technical Problem

In the solid-state imaging device provided with the large pixels and the small pixels as described above, the amount of light received by the large pixels is significantly larger as compared with the small pixels. If light leakage from the large pixels to the small pixels occurs, even a small amount for the large pixels may considerably affect image quality of the small pixels. In the pixel structure provided with the large pixels and the small pixels, more light leakage occurs in a specific direction depending on arrangement of the pixels and arrangement of color filters, and flare with a characteristic color tone and anisotropy may occur. The present disclosure was made in view of such circumstances, and an object thereof is to suppress light leakage from large pixels to small pixels.

### Solution to Problem

A solid-state imaging device according to a first aspect of the present disclosure includes:

a pixel array unit in which a plurality of unit pixels are two-dimensionally arranged,
and each of the unit pixels includes
a first photoelectric conversion unit that is formed in a semiconductor substrate,
a second photoelectric conversion unit that has a smaller area than an area of the first photoelectric conversion unit,
an inter-pixel light shielding film that is provided on at least a part of a boundary between the unit pixels on a side of incident light relative to the semiconductor substrate,
a spacer layer that is provided on the side of the incident light relative to the inter-pixel light shielding film, and
a light shielding wall that is provided on at least a part of the boundary between the unit pixels on the side of the incident light relative to the inter-pixel light shielding film and sections the spacer layer.

In the first aspect of the present disclosure, the pixel array unit in which the plurality of unit pixels are two-dimensionally arranged is provided, and each of the unit pixels includes the first photoelectric conversion unit that is formed in the semiconductor substrate, the second photoelectric conversion unit that has a smaller area than the area of the first photoelectric conversion unit, the inter-pixel light shielding film that is provided on at least a part of the boundary between the unit pixels on the side of the incident light relative to the semiconductor substrate, the spacer layer that is provided on the side of the incident light relative to the inter-pixel light shielding film, and the light shielding wall that is provided on at least a part of the boundary between the unit pixels on the side of the incident light relative to the inter-pixel light shielding film and sections the spacer layer.

A solid-state imaging device according to a second aspect of the present disclosure includes:
a pixel array unit in which a plurality of unit pixels are two-dimensionally arranged,
and each of the unit pixels includes
a first photoelectric conversion unit that is formed in a semiconductor substrate,
a second photoelectric conversion unit that has a smaller area than an area of the first photoelectric conversion unit,
a color filter that is provided on a side of incident light relative to the semiconductor substrate, and
a low N wall with a lower refractive index than a refractive index of the color filter in the same layer as the color filter.

In the second aspect of the present disclosure, the pixel array unit in which the plurality of unit pixels are two-dimensionally arranged is provided, and each of the unit pixels includes the first photoelectric conversion unit that is formed in the semiconductor substrate, the second photoelectric conversion unit that has the smaller area than the area of the first photoelectric conversion unit, the color filter that is provided on the side of the incident light relative to the semiconductor substrate, and the low N wall with a lower refractive index than the refractive index of the color filter in the same layer as the color filter.

The solid-state imaging device may be an independent device or may be a module incorporated in another apparatus.

### BRIEF DESCRIPTION OF DRAWINGS

FIG. 1 is a diagram illustrating a schematic configuration of a solid-state imaging device to which the technology of the present disclosure is applied.

FIG. 2 is a plan view illustrating a first layout example of unit pixels.

FIG. 3 is a plan view illustrating a second layout example of the unit pixels.

FIG. 4 is a diagram illustrating an arrangement example of on-chip lenses in a case where the unit pixels are arranged in the second layout example.

FIG. 5 is a plan view illustrating yet another layout example of the unit pixels.

FIG. 6 is a diagram illustrating a circuit configuration example of the unit pixels.

FIG. 7 is a sectional view illustrating a configuration example of unit pixels according to a first embodiment.

FIG. 8 is a plan view of the unit pixels at a predetermined depth position according to the first embodiment.

FIG. 9 is a diagram illustrating a configuration example of comparative unit pixels to be compared with the unit pixels according to the first embodiment.

FIG. 10 is a diagram for explaining results of comparing optical characteristics between the unit pixels according to the first embodiment and the comparative unit pixels.

FIG. 11 is a diagram for explaining results of comparing optical characteristics between the unit pixels according to the first embodiment and the comparative unit pixels.

FIG. 12 is a diagram for explaining a relationship between a width of an inter-pixel light shielding film and a width of a light shielding wall.

FIG. 13 is a diagram for explaining a relationship between the width of the inter-pixel light shielding film and the width of the light shielding wall.

FIG. 14 is a sectional view illustrating a second configuration example of the light shielding wall.

FIG. 15 is a diagram for explaining results of comparing optical characteristics between the comparative unit pixels and unit pixels in the first configuration example or the second configuration example of the light shielding wall.

FIG. 16 is a sectional view illustrating a third configuration example of the light shielding wall.

FIG. 17 is a sectional view illustrating a fourth configuration example of the light shielding wall.

FIG. 18 is a diagram for explaining a method of manufacturing the unit pixels according to the first embodiment.

FIG. 19 is a diagram for explaining the method of manufacturing the unit pixels according to the first embodiment.

FIG. 20 is a diagram for explaining the method of manufacturing the unit pixels according to the first embodiment.

FIG. 21 is a diagram for explaining the method of manufacturing the unit pixels according to the first embodiment.

FIG. 22 is a sectional view illustrating a first configuration example of unit pixels according to a second embodiment of the present disclosure.

FIG. 23 is a plan view of the unit pixels according to the first configuration example in the second embodiment at a predetermined depth position.

FIG. 24 is a diagram for explaining an effect of the first configuration example of the unit pixels according to the second embodiment.

FIG. 25 is a plan view illustrating a modification example of a low N wall of the unit pixels according to the first configuration example.

FIG. 26 is a sectional view illustrating a second configuration example of the unit pixels according to the second embodiment of the present disclosure.

FIG. 27 is a plan view of the unit pixels according to the second configuration example in the second embodiment at a predetermined depth position.

FIG. 28 is a plan view illustrating modification examples of recessed portions in the first configuration example and the second configuration example.

FIG. 29 is a sectional view illustrating a third configuration example of the unit pixels according to the second embodiment of the present disclosure.

FIG. 30 is a plan view illustrating modification examples of recessed portions in the third configuration example.

FIG. 31 is a sectional view illustrating a fourth configuration example of the unit pixels according to the second embodiment of the present disclosure.

FIG. 32 is a sectional view illustrating a first configuration example of unit pixels according to a third embodiment of the present disclosure.

FIG. 33 is a plan view of the unit pixels according to the first configuration example in the third embodiment at a predetermined depth position.

FIG. 34 is a plan view for explaining a modification example of the unit pixels according to the first configuration example in the third embodiment.

FIG. 35 is a sectional view illustrating a second configuration example of the unit pixels according to the third embodiment of the present disclosure.

FIG. 36 is a plan view of the unit pixels according to the second configuration example in the third embodiment at a predetermined depth position.

FIG. 37 is a sectional view illustrating a third configuration example of the unit pixels according to the third embodiment of the present disclosure.

FIG. 38 is a plan view of the unit pixels according to the third configuration example in the third embodiment at a predetermined depth position.

FIG. 39 is a diagram illustrating a fourth configuration example of the unit pixels according to the third embodiment of the present disclosure.

FIG. 40 is a diagram illustrating a fifth configuration example of the unit pixels according to the third embodiment of the present disclosure.

FIG. 41 is a diagram illustrating a sixth configuration example of the unit pixels according to the third embodiment of the present disclosure.

FIG. 42 is a diagram illustrating a seventh configuration example of the unit pixels according to the third embodiment of the present disclosure.

FIG. 43 is a diagram illustrating an eighth configuration example of the unit pixels according to the third embodiment of the present disclosure.

FIG. 44 is a sectional view of unit pixels according to a fourth embodiment of the present disclosure.

FIG. 45 is a diagram for explaining an effect of the unit pixels according to the fourth embodiment.

FIG. 46 is a diagram for explaining an effect of the unit pixels according to the fourth embodiment.

FIG. 47 is a diagram for explaining an effect of the unit pixels according to the fourth embodiment.

FIG. 48 is a sectional view of unit pixels illustrating modification examples of the fourth embodiment.

FIG. 49 is a sectional view of unit pixels illustrating modification examples of the fourth embodiment.

FIG. 50 is a diagram for explaining a Fresnel-type on-chip lens.

FIG. 51 is a diagram illustrating a first configuration example of unit pixels according to a fifth embodiment of the present disclosure.

FIG. 52 is a diagram illustrating a second configuration example of the unit pixels according to the fifth embodiment of the present disclosure.

FIG. 53 is a diagram illustrating a third configuration example of the unit pixels according to the fifth embodiment of the present disclosure.

FIG. 54 is a diagram illustrating a fourth configuration example of the unit pixels according to the fifth embodiment of the present disclosure.

FIG. 55 is a diagram illustrating a fifth configuration example of the unit pixels according to the fifth embodiment of the present disclosure.

FIG. 56 is a diagram illustrating a sixth configuration example of the unit pixels according to the fifth embodiment of the present disclosure.

FIG. 57 is a diagram illustrating a seventh configuration example of the unit pixels according to the fifth embodiment of the present disclosure.

FIG. 58 is a diagram for explaining exemplary use of a solid-state imaging device.

FIG. 59 is a block diagram illustrating a configuration example of an imaging device as an electronic device to which the feature of the present technology is applied.

FIG. 60 is a block diagram showing an example of a schematic configuration of a vehicle control system.

FIG. 61 is an explanatory diagram showing an example of installation positions of a vehicle external information detection unit and an imaging unit.

### DESCRIPTION OF EMBODIMENTS

Modes for embodying the technology of the present disclosure (hereinafter referred to as “embodiments”) will be described below with reference to the accompanying drawings. The descriptions will be given in the following order.
1. Schematic configuration example of solid-state imaging device
2. Layout example of unit pixels
3. Circuit example of unit pixels
4. First embodiment of unit pixels
4.1 Unit pixel configuration example
4.2 Unit pixel structure in comparative example
4.3 Results of optical characteristics in first embodiment and comparative example
4.4 Concerning relationship between width of inter-pixel light shielding film and width of light shielding wall
4.5 Second configuration example of light shielding wall
4.6 Third configuration example of light shielding wall
4.7 Fourth configuration example of light shielding wall
4.8 Manufacturing method in first embodiment
4.9 Summary of first embodiment
5. Second embodiment of unit pixels
5.1 First configuration example in second embodiment
5.2 Modification example of low N wall
5.3 Second configuration example in second embodiment
5.4 Modification examples of recessed portion
5.5 Third configuration example in second embodiment
5.6 Modification examples of recessed portion
5.7 Fourth configuration example in second embodiment
5.8 Summary of second embodiment
6. Third embodiment of unit pixels
6.1 First configuration example in third embodiment
6.2 Second configuration example in third embodiment
6.3 Third configuration example in third embodiment
6.4 Fourth configuration example in third embodiment
6.5 Fifth configuration example in third embodiment
6.6 Sixth configuration example in third embodiment
6.7 Seventh configuration example in third embodiment
6.8 Eighth configuration example in third embodiment
6.9 Summary of third embodiment
7. Fourth embodiment of unit pixels
7.1 Configuration example in fourth embodiment
7.2 Modification Example
7.3 Summary of fourth embodiment
8. Fifth embodiment of unit pixels
8.1 First configuration example in fifth embodiment
8.2 Second configuration example in fifth embodiment
8.3 Third configuration example in fifth embodiment
8.4 Fourth configuration example in fifth embodiment
8.5 Fifth configuration example in fifth embodiment
8.6 Sixth configuration example in fifth embodiment
8.7 Seventh configuration example in fifth embodiment
8.8 Summary of fifth embodiment
9. Summary of all embodiments
10. Exemplary use of solid-state imaging device
11. Example of application to electronic device
12. Example of application to moving body

In the drawings referred to in the following description, the same or similar portions will be denoted by the same or similar reference signs, and redundant descriptions will be omitted. The drawings are schematic, and relationships between thicknesses and plan view dimensions, ratios of thicknesses of respective layers, and the like differ from the actual ones. In addition, drawings may include portions where dimensional relationships and ratios differ between the drawings in some cases.

In addition, it is to be understood that definitions of directions such as upward and downward in the following description are merely definitions provided for the sake of brevity and are not intended to limit technical ideas of the present disclosure. For example, when an object is observed after being rotated by 90 degrees, up-down is converted into and interpreted as left-right, and when an object is observed after being rotated by 180 degrees, up down is interpreted as being inverted.

Also, in regard to a P-type or N-type semiconductor region in the following description, even semiconductor regions of the same conductive type do not mean that the concentrations of impurities in the semiconductor regions are the same in a strict sense.

### 1. Schematic Configuration Example of Solid-State Imaging Device

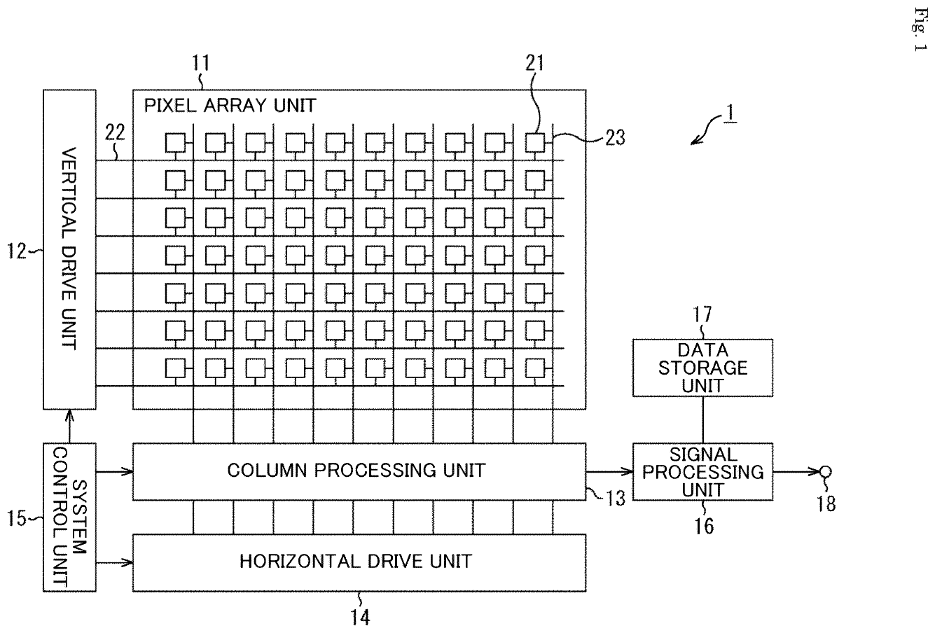

FIG. 1 is a diagram illustrating a schematic configuration of a solid-state imaging device to which the technology of the present disclosure is applied.

As a solid-state imaging device 1 in FIG. 1, a configuration of a CMOS image sensor, which is a type of solid-state imaging device of an X-Y address scheme, for example, is illustrated. The CMOS image sensor is an image sensor manufactured by applying or partially using a CMOS process.

The solid-state imaging device 1 includes a pixel array unit 11 and a peripheral circuit unit. The peripheral circuit unit includes, for example, a vertical drive unit 12, a column processing unit 13, a horizontal drive unit 14, and a system control unit 15.

The solid-state imaging device 1 further includes a signal processing unit 16 and a data storage unit 17. The signal processing unit 16 and the data storage unit 17 may be mounted on the same substrate as that for the pixel array unit 11, the vertical drive unit 12, and the like or may be arranged on another substrate. Also, an external signal processing unit, for example, a digital signal processor (DSP) circuit or the like provided on a semiconductor chip which is different from the solid-state imaging device 1 may be caused to execute processing of the signal processing unit 16 and the data storage unit 17.

The pixel array unit 11 has a configuration in which unit pixels 21 including a photoelectric conversion unit that generates and accumulates charge in accordance with amounts of received light are two-dimensionally arranged in a matrix shape in a row direction and a column direction. Here, the row direction denotes a layout direction of pixel rows of the pixel array unit 11, that is, in a horizontal direction, while the column direction denotes a layout direction of pixel columns of the pixel array unit 11, that is, in a vertical direction.

Also, a pixel drive wiring 22 as a row signal line is routed in the row direction for each pixel row, and a vertical signal line 23 as a column signal line is routed in the column direction for each pixel column, in the pixel array unit 11. The pixel drive wiring 22 transmits a drive signal for performing driving at the time of reading a signal from the unit pixels 21. Although the pixel drive wiring 22 is illustrated as one wiring in FIG. 1, the number thereof is not limited to one. An end of the pixel drive wiring 22 is connected to an output terminal corresponding to each row of the vertical drive unit 12.

The vertical drive unit 12 is configured of a shift register, an address decoder, or the like, and drives each unit pixel 21 of the pixel array unit 11 at the same time, on a per-row basis, or the like. The vertical drive unit 12 configures, along with the system control unit 15, a drive unit that controls operations of each unit pixel 21 of the pixel array unit 11. Although illustration of a specific configuration will be omitted, the vertical drive unit 12 typically has two scanning systems, namely a read-out scanning system and a sweep-out scanning system.

The read-out scanning system selectively scans the unit pixels 21 of the pixel array unit 11 in order in units of rows in order to read signals from the unit pixels 21. The signals read from the unit pixels 21 are analog signals. The sweep-out scanning system performs sweep-out scanning on a read-out row on which read-out scanning is performed by the read-out scanning system, ahead of the read-out scanning by an exposure time.

The sweep-out scanning performed by the sweep-out scanning system sweeps unnecessary charges from the photoelectric conversion units of the unit pixels 21 in a reading row, thereby resetting the photoelectric conversion unit of each unit pixel 21. A so-called electronic shutter operation is performed by sweeping (resetting) the unnecessary charges performed by the sweep-out scanning system. Here, the electronic shutter operation denotes an operation of discarding charges of the photoelectric conversion units and newly starting exposure (starting accumulation of charges).

A signal read through the reading operation in the reading scanning system corresponds to the amount of light received after the immediately previous reading operation or the electronic shutter operation. In addition, a period from a read timing in an immediately previous read-out operation or a sweep-out timing in the electronic shutter operation to a read timing in a current read-out operation is an exposure period of the unit pixels 21.

Signals output from the unit pixels 21 in the pixel row selected and scanned by the vertical drive unit 12 are input to the column processing unit 13 through the vertical signal lines 23 for the respective pixel columns. The column processing unit 13 performs predetermined signal processing on the signal output from each unit pixel 21 of the selected row through the vertical signal line 23 for each pixel column of the pixel array unit 11, and temporarily holds a pixel signal after the signal processing.

Specifically, the column processing unit 13 performs at least noise removal processing, such as correlated double sampling (CDS) processing and double data sampling (DDS) processing, as signal processing. For example, the CDS processing removes pixel-specific fixed pattern noise such as reset noise and threshold variations of amplification transistors within the unit pixels. In addition to the noise removal processing, the column processing unit 13 can also have, for example, an analog-digital (AD) conversion function to convert an analog pixel signal into a digital signal and output the digital signal.

The horizontal drive unit 14 is configured by a shift register, an address decoder, or the like, and sequentially selects unit circuits corresponding to pixel columns in the column processing unit 13. Through selective scanning by the horizontal drive unit 14, pixel signals subjected to the signal processing for each unit circuit in the column processing unit 13 are sequentially output.

The system control unit 15 is configured of a timing generator that generates various timing signals or the like, and performs drive control on the vertical drive unit 12, the column processing unit 13, the horizontal drive unit 14, and the like on the basis of various timings generated by the timing generator.

The signal processing unit 16 has at least a calculation processing function and performs various signal processing such as calculation processing on a pixel signal output from the column processing unit 13. The data storage unit 17 temporarily stores data required for signal processing in the signal processing unit 16. The pixel signal on which the signal processing unit 16 has performed the signal processing is converted into a predetermined format and is output to outside of the apparatus from the output unit 18.

### 2. Layout Example of Unit Pixels

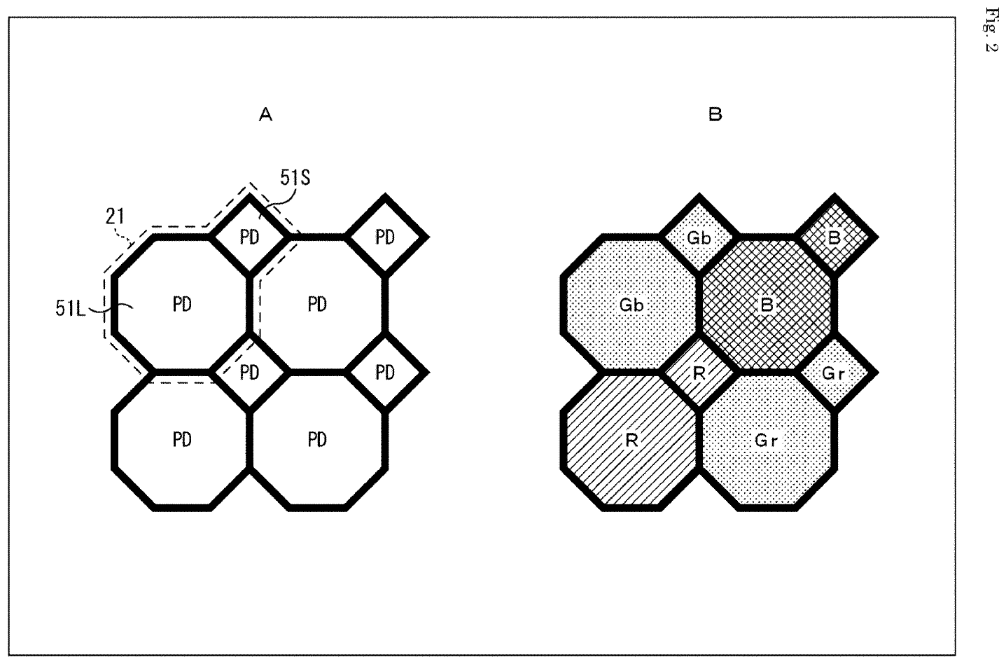

In FIG. 2, A is a plan view illustrating a first layout example of the unit pixels 21 in the pixel array unit 11.

In FIG. 2, A is a plan view in which 2×2 unit pixels 21 are arranged, that is two unit pixels 21 are arranged in each of the row direction and the column direction. Each unit pixel 21 is configured in units surrounded by the dashed line in A of FIG. 2, for example, and includes one first photoelectric conversion unit 51L and a second photoelectric conversion unit 51S arranged on the right upper side with respect to the first photoelectric conversion unit 51L.

The first photoelectric conversion unit 51L is formed to have an octagonal planar shape and has a photoelectric conversion region that is larger than that of the second photoelectric conversion unit 51S. The second photoelectric conversion unit 51S is formed to have a rhombus shape obtained by rotating a quadrangle by 45 degrees and has a photoelectric conversion region that is smaller than that of the first photoelectric conversion unit 51L. Therefore, the first photoelectric conversion unit 51L is a photoelectric conversion unit with high sensitivity, and the second photoelectric conversion unit 51S is a photoelectric conversion unit with low sensitivity. The second photoelectric conversion unit 51S is arranged at a corner position in a diagonal direction of the first photoelectric conversion unit 51L.

Note that hereinafter, the first photoelectric conversion unit 51L and the second photoelectric conversion unit 51S will be simply referred to as photoelectric conversion units 51 in a case where there is no particular need to distinguish the first photoelectric conversion unit 51L and the second photoelectric conversion unit 51S. Also, a region corresponding to the first photoelectric conversion unit caused to have high sensitivity may be referred to as a large pixel, and a region corresponding to the second photoelectric conversion unit caused to have low sensitivity may be referred to as a small pixel, in each unit pixel 21.

Color filters are arranged in a Bayer layout in units of unit pixels 21 as units of same colors, as illustrated in B of FIG. 2, for example. On-chip lenses are arranged in circular shapes with diameters that have different sizes in accordance with the areas of the photoelectric conversion regions above the first photoelectric conversion unit 51L and the second photoelectric conversion unit 51S, respectively.

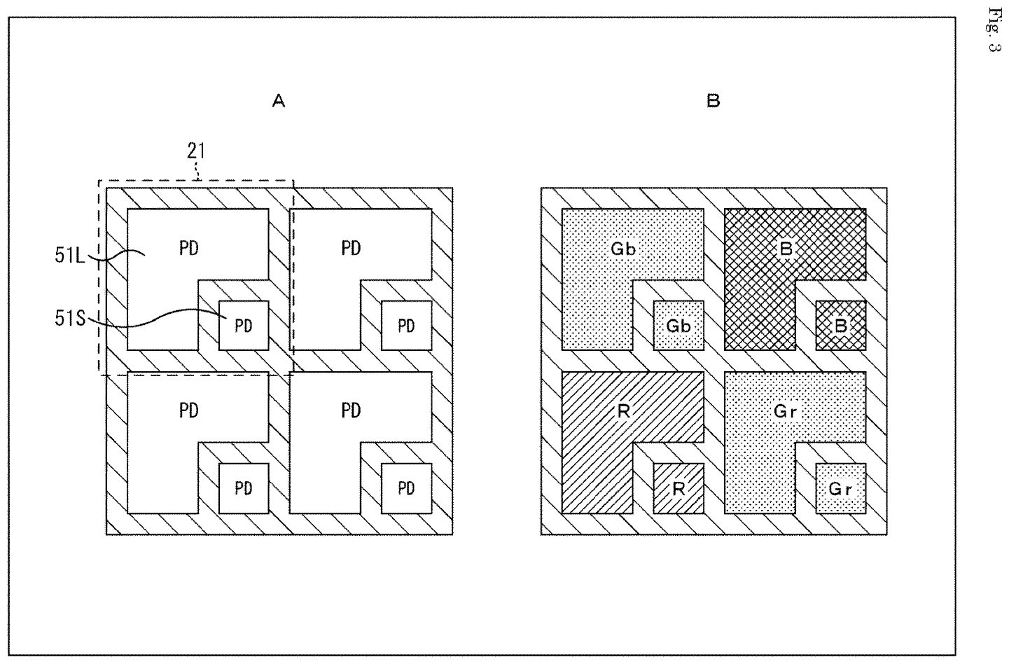

In FIG. 3, A is a plan view illustrating a second layout example of the unit pixels 21 in the pixel array unit 11.

In FIG. 3, A is an example in which 2×2 unit pixels 21 are arranged, that is, two unit pixels 21 are arranged in the row direction and the column direction, and each unit pixel 21 is formed to have a quadrangular planar shape and has the first photoelectric conversion unit 51L formed into an L shape and the second photoelectric conversion unit 51S formed into a quadrangular shape within the quadrangular region. The L shape is a shape obtained by connecting a line in the longitudinal direction and a line in the lateral direction, and the lengths of the line in the longitudinal direction and the line in the lateral direction may be the same or different from each other. Also, the direction of L in the L shape may be any direction. In other words, the L shape may be in a direction obtained by rotating the L letter by 90 degrees, 180 degrees, or 270 degrees.

Color filters are arranged in a Bayer layout in units of unit pixels 21 as units of same colors, as illustrated in B of FIG. 3, for example.

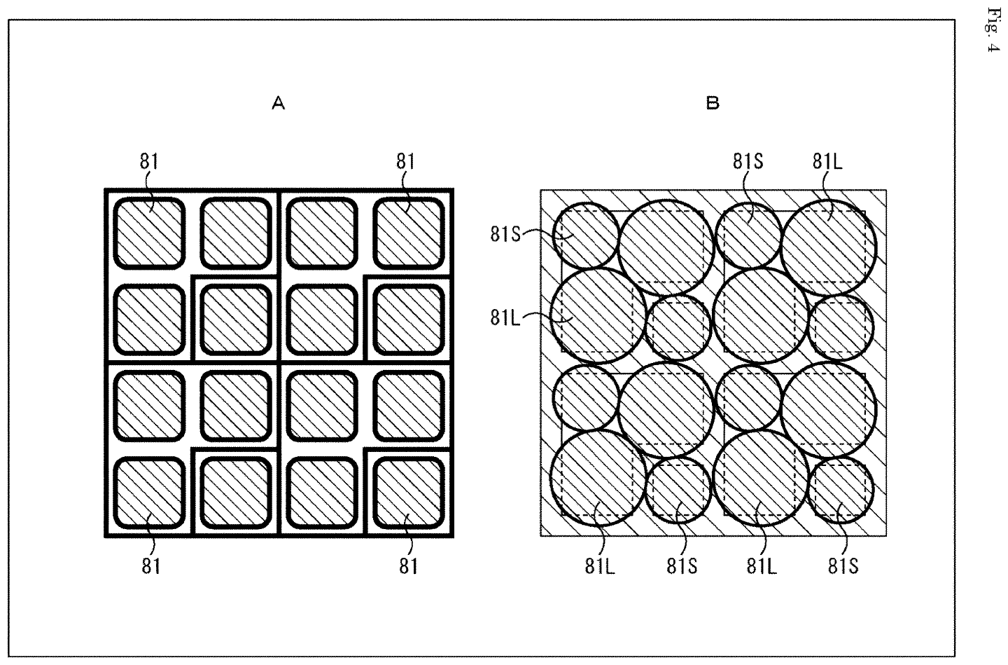

FIG. 4 is a diagram illustrating an arrangement example of on-chip lenses in a case where the unit pixels 21 are arranged in the second layout example.

In a case where the unit pixels 21 are arranged in the second layout example, for example, it is possible to arrange on-chip lenses 81 formed to have the same shape and size in arrangement of 2×2 inside each unit pixel 21 as illustrated in A of FIG. 4.

Alternatively, it is possible to align and arrange small on-chip lenses 81S with a small diameter and large on-chip lenses 81L with a large diameter in diagonal directions, respectively, and to alternately arrange the small on-chip lenses 81S and the large on-chip lenses 81L in the column direction and the row direction, as illustrated in B of FIG. 4. The small on-chip lenses 81S are arranged on the second photoelectric conversion units 51S.

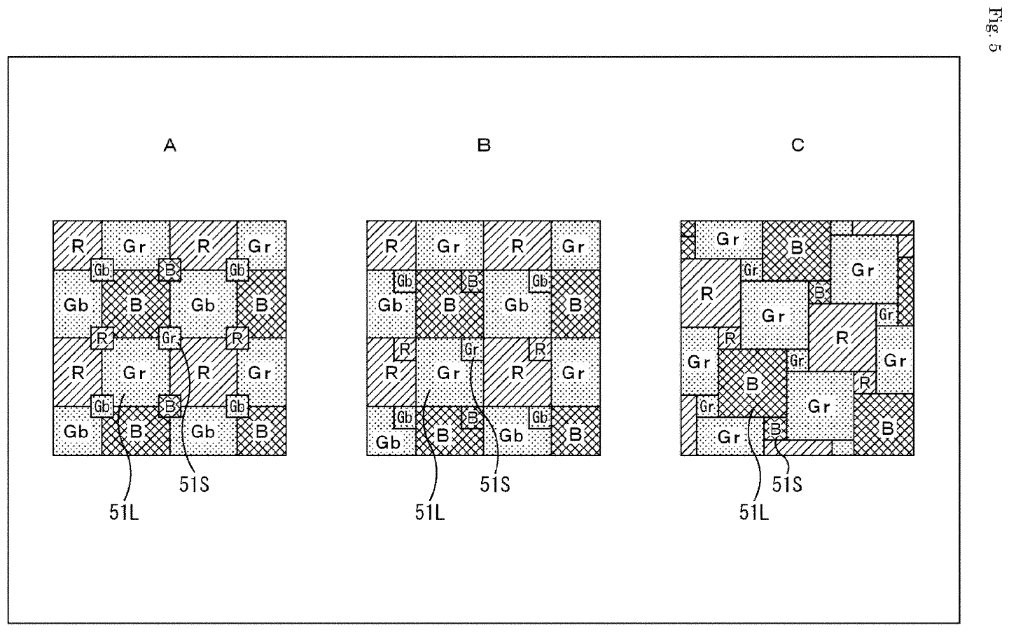

FIG. 5 is a plan view illustrating yet another layout example of the unit pixels 21. In FIG. 5, the photoelectric conversion units 51 and the color filters are illustrated in an overlapping manner for simplification.

In FIG. 5, A illustrates an example in which the second photoelectric conversion units 51S formed to have a quadrangular planar shape are arranged at the positions of four corners of the first photoelectric conversion unit 51L formed to have a quadrangular planar shape such that the second photoelectric conversion units 51S have a shape similar to that of the first photoelectric conversion unit 51L.

In FIG. 5, B illustrates an arrangement configuration in which each unit pixel 21 has a quadrangular planar shape and the region thereof is sectioned into the first photoelectric conversion unit 51L and the second photoelectric conversion unit 51S. However, the area that the second photoelectric conversion unit 51S occupies in the unit pixel 21 is smaller as compared with the first photoelectric conversion unit 51L.

In FIG. 5, C illustrates an example in which the first photoelectric conversion units 51L are arranged with a deviation from adjacent first photoelectric conversion units 51L in the row direction and the column direction by a predetermined amount (within the size of the first photoelectric conversion units 51L) and the second photoelectric conversion units 51S are arranged in gaps between the adjacent first photoelectric conversion units 51L.

Note that although an example in which each unit pixel 21 includes two types of photoelectric conversion units 51 with different areas of photoelectric conversion regions in a plan view will be described in the following embodiments, each unit pixel 21 may be configured of three types of large, middle, and small photoelectric conversion units 51 or may be configured of four types of photoelectric conversion units 51.

The color filters are also not limited to primary colors, namely red (R), green (G), and blue (B) and may be complementary colors such as cyan, magenta, and yellow. Also, the color filters may be white filters (clear filters) or IR filters. Furthermore, a layout in which the aforementioned various filters are appropriately combined or a configuration in which the color filters are omitted may be adopted. Moreover, surface plasmon filters may be arranged instead of the color filters, or wire grid-type polarization elements may be arranged.

### 3. Circuit Example of Unit Pixels

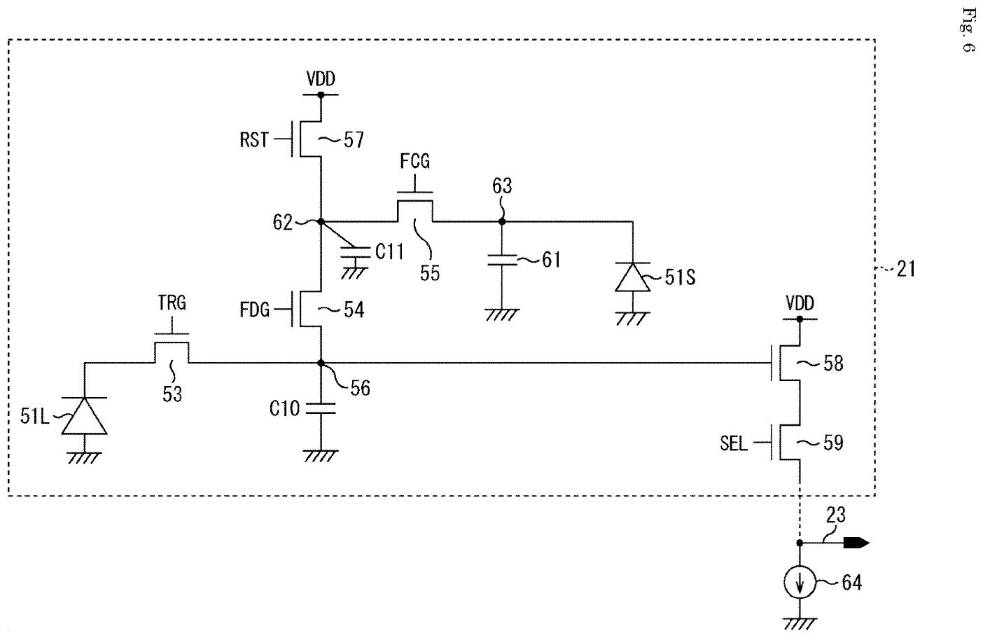

FIG. 6 illustrates a circuit configuration example of the unit pixels 21.

Each unit pixel 21 includes the first photoelectric conversion unit 51L and the second photoelectric conversion unit 51S, which are two photoelectric conversion units 51 with different sensitivity as described above.

The unit pixel 21 further includes a first transfer transistor 53, a second transfer transistor 54, a third transfer transistor 55, a floating diffusion (FD) unit 56, a reset transistor 57, an amplification transistor 58, and a selection transistor 59.

The reset transistor 57 and the amplification transistor 58 are connected to a power supply voltage VDD. The first photoelectric conversion unit 51L includes a so-called embedded-type photodiode with an N-type impurity region formed therein inside a P-type impurity region formed in a semiconductor substrate. Similarly, the second photoelectric conversion unit 51S includes an embedded-type photodiode. The first photoelectric conversion unit 51L and the second photoelectric conversion unit 51S generate charges in accordance with the amounts of received light and accumulate the generated charges to specific amounts.

The unit pixel 21 further includes a charge accumulation unit 61. The charge accumulation unit 61 is configured of, for example, a MOS capacitance or a MIS capacitance.

In FIG. 6, the first transfer transistor 53, the second transfer transistor 54, and the third transfer transistor 55 are connected in series between the first photoelectric conversion unit 51L and the second photoelectric conversion unit 51S. A floating diffusion layer connected between the first transfer transistor 53 and the second transfer transistor 54 corresponds to the FD unit 56. The FD unit 56 includes a parasitic capacitance C10.

A floating diffusion layer connected between the second transfer transistor 54 and the third transfer transistor 55 corresponds to a node 62. The node 62 is provided with a parasitic capacitance C11. A floating diffusion layer connected between the third transfer transistor 55 and the second photoelectric conversion unit 51S corresponds to a node 63. The charge accumulation unit 61 is connected to the node 63.

For the unit pixel 21, a plurality of drive wirings are routed as the pixel drive wirings 22 in FIG. 1 for each pixel row, for example. Also, various drive signals TRG, FDG, FCG, RST, and SEL are supplied from the vertical drive unit 12 in FIG. 1 via a plurality of drive wirings. Since each transistor of the unit pixel 21 is configured of an NMOS transistor, these drive signals are pulse signals, a high level (for example, a power supply voltage VDD) state of which is an active state, and a low level state (for example, a negative potential) of which is a non-active state.

The drive signal TRG is applied to a gate electrode of the first transfer transistor 53. Once the drive signal TRG is brought into an active state, the first transfer transistor 53 is brought into a conduction state, and a charge accumulated in the first photoelectric conversion unit 51L is transferred to the FD unit 56 via the first transfer transistor 53.

A drive signal FDG is applied to the gate electrode of the second transfer transistor 54. When the drive signal FDG becomes active and the second transfer transistor 54 becomes conductive, the potentials of the FD unit 56 and the node 62 are combined to form one charge accumulation region.

A drive signal FCG is applied to the gate electrode of the third transfer transistor 55. When the drive signal FDG and the drive signal FCG become active and the second transfer transistor 54 and the third transfer transistor 55 become conductive, the potentials of the FD unit 56 and the charge accumulation unit 61 are combined to form one charge accumulation region.

In FIG. 6, a first electrode out of two electrodes that the charge accumulation unit 61 has is a node electrode connected to the node 63. A second electrode out of the two electrodes that the charge accumulation unit 61 has is a grounded ground electrode. Note that, as a modification example, the second electrode may be connected to a specific potential other than the ground potential, for example, a power supply potential.

When the charge accumulation unit 61 is a MOS capacitor or an MIS capacitor, for example, the second electrode is an impurity region formed on a silicon substrate, and a dielectric film forming the capacitor is an oxide film or a nitride film formed on the silicon substrate. The first electrode is an electrode formed of a conductive material such as polysilicon or metal above the second electrode and the dielectric film.

In a case where the second electrode is set to a ground potential, the second electrode may be a P-type impurity region electrically connected to a P-type impurity region included in the first photoelectric conversion unit 51L or the second photoelectric conversion unit 51S. In a case where the second electrode is set to a specific potential other than the ground potential, the second electrode may be an N-type impurity region formed inside the P-type impurity region.

In addition to the second transfer transistor 54, the reset transistor 57 is also connected to the node 62. A specific potential, for example, the power supply voltage VDD is connected to the reset transistor 57. The drive signal RST is applied to the gate electrode of the reset transistor 57. Once the drive signal RST is brought into an active state, the reset transistor 57 is brought into a conduction state, and the potential of the node 62 is reset to the level of the power supply voltage VDD.

If the drive signal FDG of the second transfer transistor 54 and the drive signal FCG of the third transfer transistor 55 are brought into an active state when the drive signal RST is brought into an active state, the combined potentials of the node 62, the FD unit 56, and the charge accumulation unit 61 are reset to the level of the power supply voltage VDD.

Note that it is needless to say that the potentials of the FD unit 56 and the charge accumulation unit 61 can be reset to the level of the power supply voltage VDD alone (independently) by individually controlling the drive signal FDG and the drive signal FCG.

The FD unit 56, which is a floating diffusion layer, is a charge-voltage conversion means. That is, when charges are transferred to the FD unit 56, the potential of the FD unit 56 changes depending on the amount of transferred charges.

A current source 64 connected to one end of the vertical signal line 23 is connected to a source side of the amplification transistor 58, and the power supply voltage VDD is connected to a drain side thereof, whereby the amplification transistor 58 configures a source follower circuit with them. The FD unit 56 is connected to the gate electrode of the amplification transistor 58 and serves as an input to the source follower circuit.

The selection transistor 59 is connected between the source of the amplification transistor 58 and the vertical signal line 23. The drive signal SEL is applied to the gate electrode of the selection transistor 59. When the drive signal SEL becomes active, the selection transistor 59 becomes conductive, and the unit pixel 21 enters a selected state.

When the charges are transferred to the FD unit 56, the potential of the FD unit 56 reaches a potential corresponding to the amount of transferred charges, and this potential is input to the source follower circuit described above. When the drive signal SEL becomes active, the potential of the FD unit 56 corresponding to the amount of charge is output to the vertical signal line 23 via the selection transistor 59 as an output of the source follower circuit.

A light receiving area of the photodiode of the first photoelectric conversion unit 51L is larger than that of the second photoelectric conversion unit 51S. Therefore, in a case where an object with a certain illuminance is imaged for a certain exposure time, the amount of charge generated by the first photoelectric conversion unit 51L is larger than the amount of charge generated by the second photoelectric conversion unit 51S.

Therefore, when the charge generated by the first photoelectric conversion unit 51L and the charge generated by the second photoelectric conversion unit 51S are transferred to the FD unit 56 and are subjected to charge-voltage conversion, respectively, a voltage change before and after the charge generated by the first photoelectric conversion unit 51L is transferred to the FD unit 56 is larger than a voltage change before and after the charge generated by the second photoelectric conversion unit 51S is transferred to the FD unit 56. Therefore, when the first photoelectric conversion unit 51L and the second photoelectric conversion unit 51S are compared, the first photoelectric conversion unit 51L has higher sensitivity than the second photoelectric conversion unit 51S.

On the other hand, even if high illuminance light is incident on the second photoelectric conversion unit 51S and charges exceeding a saturation charge amount of the second photoelectric conversion unit 51S are generated, the charges generated exceeding the saturation charge amount can be accumulated in the charge accumulation unit 61, and it is thus possible to perform charge-voltage conversion after adding both the charge accumulated in the second photoelectric conversion unit 51S and the charge accumulated in the charge accumulation unit 61 when the charges generated by the second photoelectric conversion unit 51S are subjected to the charge-voltage conversion.

In this manner the second photoelectric conversion unit 51S can capture an image with gradation over a wider illuminance range than the first photoelectric conversion unit 51L. In other words, the second photoelectric conversion unit 51S can capture an image with a wider dynamic range.

Two images, namely an image with high sensitivity captured using the first photoelectric conversion unit 51L and an image with a wide dynamic range captured using the second photoelectric conversion unit 51S, are synthesized into one image through wide dynamic range image synthesis processing of synthesizing one image from two images by a signal processing unit 16 included inside the solid-state imaging device 1 or an image signal processing apparatus externally connected to the solid-state imaging device 1.

### 4. First Embodiment of Unit Pixels

### 4.1 Unit Pixel Configuration Example

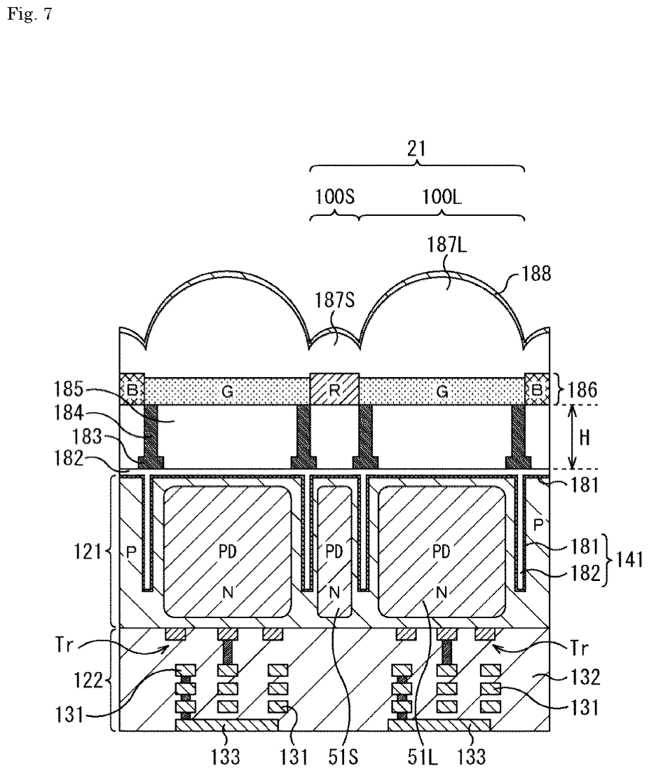

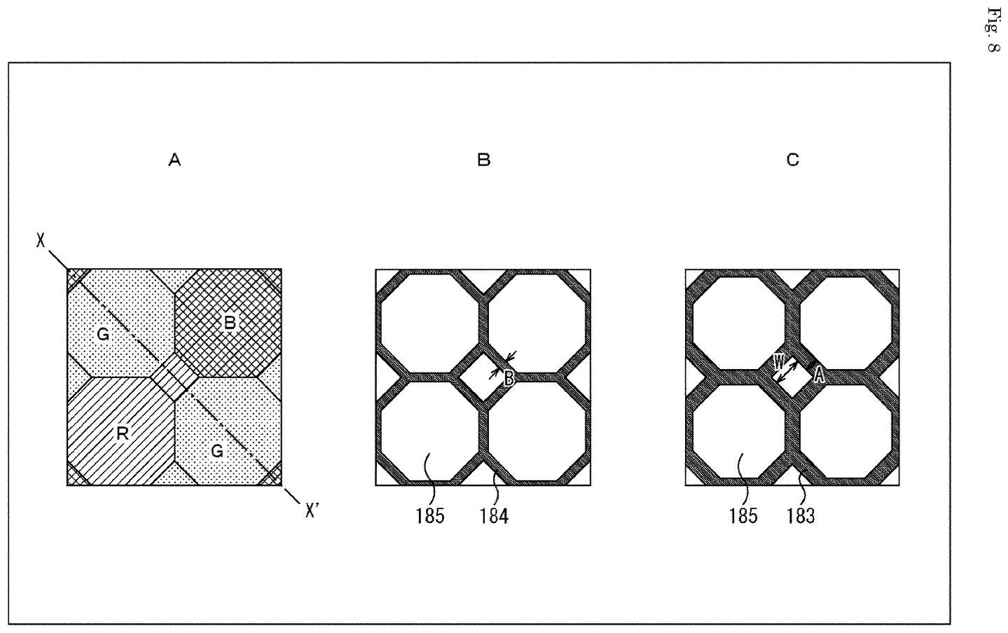

FIG. 7 is a sectional view illustrating a configuration example of unit pixels 21 according to a first embodiment of the present disclosure and illustrates a sectional view along the line X-X′ in A of FIG. 8. In FIG. 8, A to C are plan views of the unit pixels 21 in FIG. 7 at a predetermined depth position.

In the first embodiment, the first layout example illustrated in FIG. 2 is employed as a layout of the unit pixels 21.

Each unit pixel 21 according to the first embodiment is configured of a large pixel 100L including a first photoelectric conversion unit 51L with high sensitivity formed into an octagonal shape and a small pixel 100S including a second photoelectric conversion unit 51S with low sensitivity formed into a rhombus shape obtained by rotating a quadrangle by 45 degrees. In a case where the first photoelectric conversion unit 51L and the second photoelectric conversion unit 51S are not particularly distinguished, the first photoelectric conversion unit 51L and the second photoelectric conversion unit 51S will be simply referred to as photoelectric conversion units 51.

The unit pixel 21 according to the first embodiment includes a semiconductor substrate 121 and a wiring layer 122 formed on a front surface side thereof (the lower side in the drawing).

The semiconductor substrate 121 is configured of a silicon substrate using silicon (Si), for example, as a semiconductor. The thickness of the semiconductor substrate 121 is appropriately set in accordance with an expected wavelength region of incident light. For example, the thickness of the semiconductor substrate 121 is about 2 μm to 6 μm if the expected wavelength region is only a visible light region, and the thickness is about 3 μm to 15 μm in a case where a near-infrared region is also detected. It is a matter of course that the thickness of the semiconductor substrate 121 is not limited only to the range.

The first photoelectric conversion unit 51L is formed in the region of the large pixel 100L in the semiconductor substrate 121, and the second photoelectric conversion unit 51S is formed in the region of the small pixel 100S. The semiconductor substrate 121 is configured of, for example, a P-type (first conductivity type) semiconductor region. The photoelectric conversion unit 51 is configured of an PN junction-type photodiode with an N-type (second conductivity type) semiconductor region formed therein in the region of the P-type semiconductor region in the semiconductor substrate 121. The vicinities of the interfaces of both the front and rear surfaces of the semiconductor substrate 121 are P-type semiconductor regions that also serve as hole charge accumulation regions to reduce a dark current.

In the semiconductor substrate 121, an element separation unit 141 that separates the photoelectric conversion units 51 (photoelectric conversion elements) is formed in a region between adjacent photoelectric conversion units 51. The element separation unit 141 is configured by embedding a fixed charge film 181 and an insulating film 182 inside a trench formed by digging the semiconductor substrate 121 from the rear surface side up to a predetermined depth. By including the components in this manner, it is possible to block crosstalk caused by rolling of electrons with the insulating film 182 and also to reduce crosstalk as light by interface reflection due to a difference in refractive indexes. The element separation unit 141 may be formed of the P-type semiconductor region and have a grounded configuration.

Also, the element separation unit 141 may be formed by embedding light shielding metal in addition to the fixed charge film 181 and the insulating film 182 inside the trench. The light shielding metal is preferably a material that has a high light shielding property and can be worked with high precision through microfabrication, such as etching, for example, and is preferably formed of a metal film of Al, W, or Cu, for example. In other cases, the light shielding metal may be formed of silver, gold, platinum, Mo, Cr, Ti, nickel, iron, or tellurium, or an alloy containing such metal. In order to enhance adhesion to the insulating film 182 as a base, barrier metal, for example, Ti, Ta, W, Co, Mo, or an alloy, a nitride, an oxide, or a carbide thereof may be included below the light shielding metal.

The element separation unit 141 may have a shape surrounding the entire outer periphery of the first photoelectric conversion unit 51L and the second photoelectric conversion unit 51S or may have a shape surrounding a part of the outer periphery in a plan view. Also, although the element separation unit 141 does not penetrate through the semiconductor substrate 121 in the example in FIG. 7, the element separation unit 141 may be formed to penetrate through the semiconductor substrate 121 to reach the wiring layer 122.

The wiring layer 122 includes a plurality of metal wirings 131 and an inter-layer insulating film 132. The metal wirings 131 in the plurality of layers inside the wiring layer 122 transmit an image signal generated by the unit pixel 21 and transmit a signal to be applied to the unit pixel 21. The metal wirings 131 can be configured of, for example, metal such as Al or Cu. A through-via that connects the upper and lower metal wirings 131 can be configured of, for example, metal such as W or Cu. For example, a silicon oxide film or the like can be used as the inter-layer insulating film 132.

Also, one or more pixel transistors Tr are formed at an interface between the semiconductor substrate 121 and the wiring layer 122. The pixel transistors Tr correspond to any of the first transfer transistor 53, the second transfer transistor 54, the third transfer transistor 55, the reset transistor 57, the amplification transistor 58, and the selection transistor 59 explained in FIG. 6. The pixel transistor Tr includes an N-type source region and drain region formed inside the P-type semiconductor region and is configured by forming a gate electrode on the substrate surface between the source region and the drain region via a gate insulating film. A junction electrode 133 is formed on the surface of the wiring layer 122 on the side opposite to the side of the semiconductor substrate 121 and is electrically connected to a junction electrode of a logic substrate, which is not illustrated, through metal junction such as Cu—Cu junction. It is possible to reduce the chip size by establishing junction with the logic substrate and vertically stacking various peripheral circuit functions.

The fixed charge film 181 is formed to cover right above the P-type semiconductor region on the rear surface side of the semiconductor substrate 121, which is the upper surface in the drawing. The fixed charge film 181 includes a negative fixed charge caused by an oxygen dipole and serves to enhance pinning. The fixed charge film 181 can be configured of an oxide or a nitride containing at least one of Hf, Al, zirconium, Ta, and Ti, for example. The fixed charge film 181 can be formed by CVD, sputtering, or atomic layer deposition (ALD). When ALD is employed, it is possible to simultaneously form a silicon oxide film that reduces the interface level while forming the fixed charge film 181, which is preferable. The fixed charge film 181 is made of an oxide or nitride containing at least one of lanthanum, cerium, neodymium, promethium, samarium, europium, gadolinium, terbium, dysprosium, holmium, thulium, ytterbium, lutetium, and yttrium. The fixed charge film 181 can also be configured of a hafnium oxynitride or an aluminum oxynitride. Moreover, silicon or nitrogen can be added to the fixed charge film 181 such that the amount of silicon or nitrogen does not degrade insulation. This can improve the heat resistance and the like. It is desirable that the fixed charge film 181 also have a role of an anti-reflection film for a silicon substrate having a high refractive index by controlling the film thickness or by stacking multiple layers.

The insulating film 182 is formed above the fixed charge film 181. Also, the insulating film 182 preferably has a lower refractive index than the fixed charge film 181 from the viewpoint of anti-reflection, and SiO₂ or a composite material (such as SiON or SiOC) containing SiO₂ as a main component, for example, can be used. It is possible to suppress degradation of dark characteristics by the insulating film 182.

The inter-pixel light shielding film 183 and the light shielding wall 184 are formed on the insulating film 182 above the element separation unit 141, and a spacer layer 185 is formed above the photoelectric conversion unit 51 where the inter-pixel light shielding film 183 and the light shielding wall 184 are not formed.

The inter-pixel light shielding film 183 is included in a planar shape on the side of the on-chip lens 187 relative to the semiconductor substrate 121, an upper part of the photoelectric conversion unit 51 is opened therefrom, and the inter-pixel light shielding film 183 shields light at the boundary between the unit pixels 21 and suppresses crosstalk between the unit pixels. Although it is only necessary that the inter-pixel light shielding film 183 be a material that shields light, it is preferable to form the inter-pixel light shielding film 183 by a metal film of Al, W, or Cu, for example, as a material that has a high light shielding property and can be worked with high precision in microfabrication, for example, etching. In other cases, it is possible to configure the inter-pixel light shielding film 183 by silver, gold, platinum, Mo, Cr, Ti, nickel, iron, tellurium, or an alloy containing such metal. Furthermore, it is also possible to configure the inter-pixel light shielding film 183 by staking a plurality of such materials. In order to enhance adhesion to the insulating film 182 as a base, barrier material, for example, Ti, Ta, W, Co, Mo, an alloy, a nitride, an oxide, or a carbide thereof may be included below the light shielding metal. Moreover, the inter-pixel light shielding film 183 may also serve as a light shield for pixels that determine an optical black level, and may also serve as a light shield for preventing noise from entering the peripheral circuit region. It is desirable that the inter-pixel light shielding film 183 be grounded so as not to be destroyed by plasma damage caused by accumulated charges during working. The grounded structure may include a grounded structure in a region outside an effective region such that all the inter-pixel light shielding films 183 are electrically connected.

The light shielding wall 184 is located between the on-chip lens 187 and the semiconductor substrate 121 and is included at least on a part of each boundary between the unit pixels 21. The light shielding wall 184 is formed by embedding light shielding metal in the formed trench, for example. The light shielding metal is preferably formed of a metal film of Al, W, or Cu, for example, as a material that has a high light shielding property and can be worked with high precision in microfabrication, for example, etching. In other cases, it is possible to configure the light shielding metal of silver, gold, platinum, Mo, Cr, Ti, nickel, iron, tellurium, or an alloy containing such metal. Alternatively, the light shielding wall 184 may have a structure in which a low-refractive-index material with a lower refractive index than the spacer layer 185 is embedded to suppress crosstalk by a total reflection phenomenon due to a difference in refractive indexes. The light shielding wall 184 may be configured of an air gap (refractive index 1) by blocking an upper end of the trench instead of embedding the low-refractive-index material.

The spacer layer 185 is a layer obtained by embedding a region above the photoelectric conversion unit 51 up to the same height as a height H, which is the total height of the inter-pixel light shielding film 183 and the light shielding wall 184, in order to increase the height of the on-chip lens 187. It is desirable that the material of the spacer layer 185 be transparent with respect to a target wavelength in order to guide light from the on-chip lens 187 to the photoelectric conversion unit 51 without any loss, and it is possible to use, for example, SiO₂, SiN, or SiON. Note that the total height H of the inter-pixel light shielding film 183 and the light shielding wall 184 may change depending on a pixel size ratio between the large pixel 100L and the small pixel 100S and an incident angle specification of a module lens. An upper limit value of the height H is set such that no sensitivity loss occurs within an angular range of the module lens.

The color filter 186 is formed on the upper surfaces of the light shielding wall 184 and the spacer layer 185, and a large on-chip lens 187L, a small on-chip lens 187S, and an anti-reflection film 188 are formed on the color filter 186.

The color filter 186 is a filter that selectively allows light of any of colors red, green, or blue to be transmitted therethrough. The color filter 186 is formed by rotationally applying a photosensitive resin containing a colorant such as a pigment or a dye, for example. Although it is assumed that each of the colors red, green, and blue is arranged in a Bayer layout for each unit pixel 21 as illustrated in A of FIG. 8, for example, the colors may be arranged in another layout method. The thickness of the color filter 186 may be different for each color in consideration of color reproducibility based on the spectroscopic spectrum and sensor sensitivity specifications. In a case of a monochrome sensor, an infrared sensor, or the like, the color filter 186 may not be included.

The on-chip lens 187 collects incident light from an object via the module lens on the photoelectric conversion unit 51. The on-chip lens 187 includes the large on-chip lens 187L above the first photoelectric conversion unit 51L and the small on-chip lens 187S above the second photoelectric conversion unit 51S. The small on-chip lens 187S may not be formed above the second photoelectric conversion unit 51S so as not to collect light on the photoelectric conversion unit 51 as a low-sensitivity pixel. The on-chip lens 187 can be configured of, for example, an organic material such as a styrene-based resin, an acrylic resin, a styrene-acrylic resin, or a siloxane-based resin. Moreover, it is also possible to configure the on-chip lens 187 by dispersing titanium oxide particles in the aforementioned organic material or a polyimide-based resin. In addition, the on-chip lens 187 may be configured of an inorganic material such as silicon nitride (SiN) or a silicon oxynitride (SiON). Also, the anti-reflection film 188 using a material with a refractive index that is different from that of the on-chip lens 187 is formed on the surface of the on-chip lens 187. It is desirable that the film thickness d of the anti-reflection film 188 approximately satisfy d=λ/(4n) when the refractive index is defined as n and an expected average wavelength is defined as λ.

In FIG. 8, B illustrates a plan view of the light shielding wall 184, and C of FIG. 8 illustrates a plan view of the inter-pixel light shielding film 183.

In comparison between a width A of the inter-pixel light shielding film 183 and a width B of the light shielding wall 184, the width A of the inter-pixel light shielding film 183 is formed to be larger than the width B of the light shielding wall 184 (width A>width B) as is obvious from the sectional view in FIG. 7.

A minimum opening width W of the inter-pixel light shielding film 183 illustrated in C of FIG. 8 is a width of the inter-pixel light shielding film 183 surrounding the second photoelectric conversion unit 51S and is formed to be equal to or less than the height H, which is the total height of the inter-pixel light shielding film 183 and the light shielding wall 184 in the sectional view in FIG. 7 (W≤H). The minimum opening width W of the inter-pixel light shielding film 183 is further preferably equal to or less than ½ the height H (W≤H/2).

In the solid-state imaging device 1 including the unit pixels 21 according to the first embodiment configured as described is a solid-state imaging device of a back-illuminated type in which incident light is collected on the on-chip lens 187 formed on the rear surface side of the semiconductor substrate 121 and is subjected to photoelectric conversion by the photoelectric conversion unit 51. Each unit pixel 21 according to the first embodiment includes the large pixel 100L and the small pixel 100S, which have different areas of photoelectric conversion units and enables high-sensitivity imaging by the large pixel 100L and low-sensitivity imaging by the small pixel 100S.

Each unit pixel 21 according to the first embodiment includes the first photoelectric conversion unit 51L and the second photoelectric conversion unit 51S with different areas of photoelectric conversion regions formed in the semiconductor substrate 121, the inter-pixel light shielding film 183 provided on at least a part of a boundary between unit pixels 21 on the side of the incident light relative to the semiconductor substrate 121, the spacer layer 185 that is provided on the side of the incident light relative to the inter-pixel light shielding film 183, the light shielding wall 184 that is included on at least a part of a boundary between unit pixels 21 on the side of the incident light relative to the inter-pixel light shielding film 183 and sections the spacer layer 185, and the on-chip lens 187 that collects the incident light on the photoelectric conversion units 51.

Each unit pixel 21 according to the first embodiment includes the spacer layer 185 to increase the height of the on-chip lens 187 and the light shielding wall 184 that sections the spacer layer 185 in units of photoelectric conversion units 51 and shields light, to thereby suppress crosstalk from the large pixel 100L to the small pixel 100S.

### 4.2 Unit Pixel Structure in Comparative Example

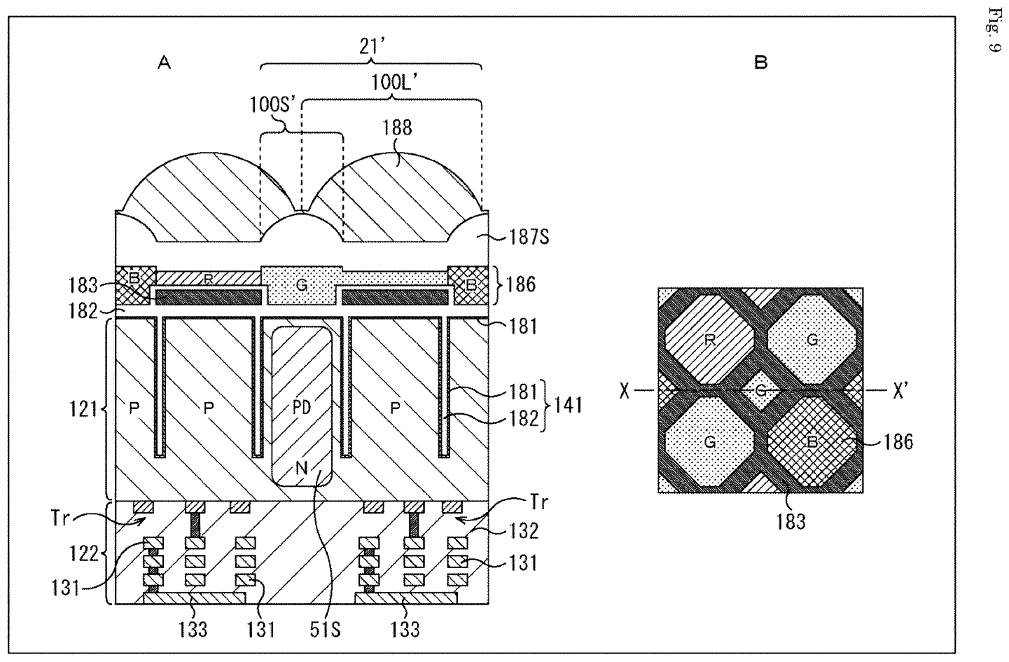

A unit pixel 21′ (hereinafter, also referred to as a comparative unit pixel 21′) in a comparative example to be compared with the unit pixel 21 according to the first embodiment will be described with reference to FIG. 9.

In FIG. 9, A is a sectional view illustrating a configuration example of the comparative unit pixel 21′ and illustrates a sectional view along the line X-X′ in B of FIG. 9. In FIG. 9, B is a plan view of the comparative unit pixel 21′.

The comparative unit pixel 21′ includes a large pixel 100L′ and a small pixel 100S′ with different areas of photoelectric conversion units similarly to the unit pixel 21 according to the first embodiment. A configuration of each part in the large pixel 100L′ and the small pixel 100S′ corresponding to that in the unit pixel 21 is denoted by the same reference sign.

The comparative unit pixel 21′ is different from the unit pixel 21 according to the first embodiment in that the comparative unit pixel 21′ does not include the spacer layer 185 and the light shielding wall 184 separating the spacer layer 185. In other words, the inter-pixel light shielding film 183 is formed on the insulating film 182 on the side of the light incident surface of the semiconductor substrate 121, and the color filter 186 is formed right above the inter-pixel light shielding film 183. The other configurations of the comparative unit pixel 21′ are similar to those of the unit pixel 21 according to the first embodiment.

### 4.3 Results of Optical Characteristics in First Embodiment and Comparative Example

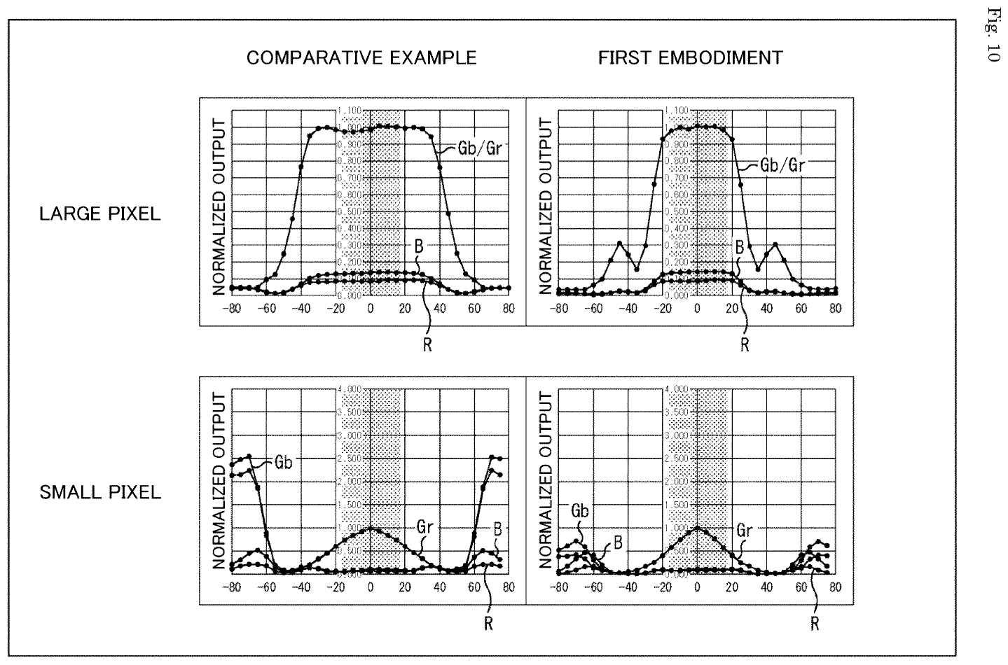

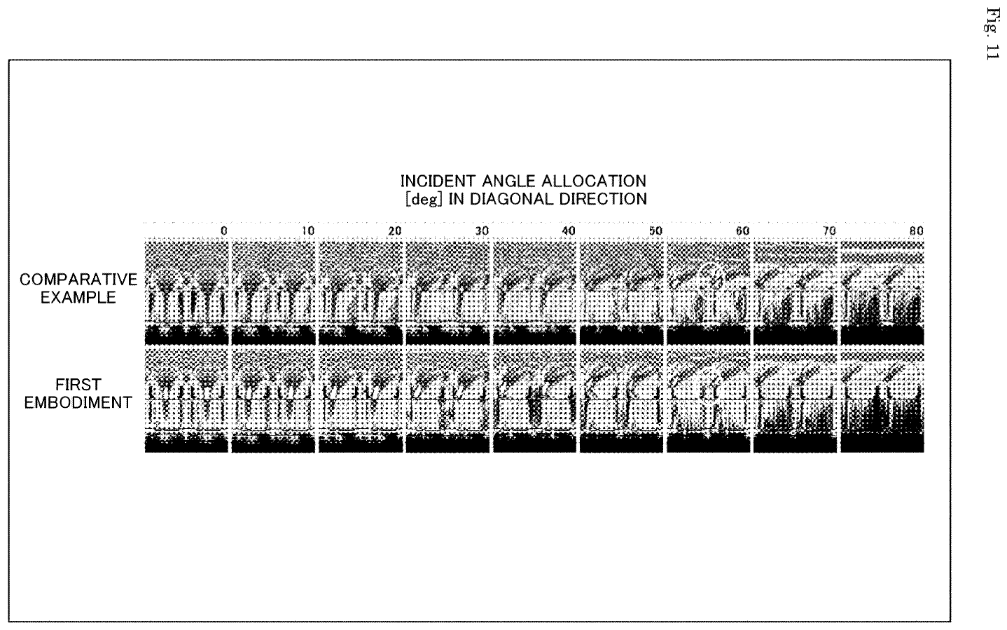

Results of comparing optical characteristics of the unit pixel 21 according to the first embodiment and the unit pixel 21′ according to the comparative example will be described with reference to FIGS. 10 and 11.

FIG. 10 illustrates optical simulation results of oblique incidence characteristics of the unit pixel 21 and the comparative unit pixel 21′ in the diagonal direction at a wavelength of 530 nm.

FIG. 11 illustrates light intensity distributions of the unit pixel 21 and the comparative unit pixel 21′ at each incident angle in the diagonal direction at the wavelength of 530 nm.

In the optical simulation, calculation was performed by setting the length of an octagon with missing parts located in the diagonal direction in the longitudinal and lateral directions to 3 um as a planar size of the first photoelectric conversion unit 51L of the large pixel 100L of the unit pixel 21 and setting the length of a square in the longitudinal direction and lateral directions to 1.12 um as a planar size of the second photoelectric conversion unit 51S of the small pixel 100S. Also, the minimum opening width W of the inter-pixel light shielding film 183 was set to 740 nm, the height H which was the total height of the inter-pixel light shielding film 183 and the light shielding wall 184 was set to 1260 nm including the thickness of 260 nm of the inter-pixel light shielding film 183. The width A of the inter-pixel light shielding film 183 surrounding the small pixel was set to 540 nm, and the width B of the light shielding wall 184 was set to 240 nm. The same conditions other than the height H and the width B of the light shielding wall 184 were applied to the comparative unit pixel 21′ as well.

In the optical simulation, calculation was performed by dividing parallel light with a wavelength of 530 nm in units of 10 degrees from 0 degrees to 80 degrees in the diagonal direction. The region of about ±20 degrees with the dot pattern represents upper and lower beam angular ranges assumed for the module lens.

First, referring to the oblique incidence characteristics in FIG. 10 for the unit pixel 21′ in the comparative example, outputs of green pixels corresponding to the incident wavelength of 530 nm (green component) reacted in both the large pixel 100L′ and the small pixel 100S′ within the angular range of the module lens. Although slight color mixing was observed in the large pixel 100L′, it is possible to perform correction through signal processing in consideration of the color mixing, such as linear matrix processing or white balance processing.

On the other hand, extreme output floating due to crosstalk from the large pixel 100L′ occurred in the region of the incident angle of equal to or greater than 50 degrees in the small pixel 100S′, and crosstalk of several times the original output (around 0 degrees) of the small pixel 100S′ occurred.

Next, referring to the light intensity distribution in FIG. 11 for the unit pixel 21′ in the comparative example, it is possible to ascertain that light collected by the large on-chip lens 187L of the large pixel 100L′ crossed the inter-pixel light shielding film 183 and strongly leaked to the second photoelectric conversion unit 51S of the adjacent small pixel 100S′ in the region of equal to or greater than 50 degrees. In a case where a flare component at a high angle occurs in the large and small pixel structure, not only output floating but also extreme coloring occurs, which leads an unacceptable influence on image quality.

Furthermore, referring to the oblique incidence characteristics in FIG. 10 for the large pixel 100L′ in the comparative example, it is possible to ascertain that high sensitivity was maintained up to less than ±40 degrees, which was wider than the upper and lower beam angular range of the module lens. In a state where sensitivity of unnecessary light is high in the large pixel 100L′, various stray light components are likely to be caught, which is not desirable in view of flare.

Next, referring to the oblique incidence characteristics in FIG. 10 for the large pixel 100L of the unit pixel 21 according to the first embodiment, high sensitivity was maintained up to ±20 degrees, which was substantially the same as the upper and lower beam angular range of the module lens, and the sensitivity was suppressed at larger angles thereof. In regard to the small pixel 100S, extreme output floating due to crosstalk from the large pixel 100L′ like the one that occurred in the region of the incident angle of equal to or greater than 50 degrees in the unit pixel 21′ in the comparative example was suppressed.

Next, referring to the light intensity distributions in FIG. 11, the effect of the unit pixel 21 according to the first embodiment appeared at an incident angle of equal to or greater than 60 degrees. Focusing on the light intensity distribution at 60 degrees surrounded by the white line, for example, it is possible to ascertain that the light crossed the inter-pixel light shielding film 183 and leaked directly from the large pixel 100L′ to the small pixel 100S′ in the unit pixel 21′ in the comparative example, while light from the large on-chip lens 187L of the large pixel 100L crossed the light shielding wall 184, then hit the light shielding wall 184 on the opposite side, and was attenuated before reaching the second photoelectric conversion unit 51S of the small pixel 100S in the unit pixel 21 according to the first embodiment.

Unnecessary light at a high angle and crosstalk hit the light shielding wall 184, and it is thus possible to considerably suppress crosstalk from the large pixel 100L to the small pixel 100S by providing the spacer layer 185, increasing the height of the on-chip lens 187, and providing the light shielding wall 184 at the boundary portion of the large and small pixels in this manner. Also, it is possible to suppress unnecessary light sensitivity at each large pixel 100L. Flare is suppressed by suppressing crosstalk and unnecessary light sensitivity. In particular, the effect significantly appears in a pixel structure of the unit pixel 21 in which the ratio between areas of the photoelectric conversion regions of the first photoelectric conversion unit 51L of the large pixel 100L and the second photoelectric conversion unit 51S of the small pixel 100S is equal to or greater than double.

### 4.4 Concerning Relationship Between Width of Inter-Pixel Light Shielding Film and Width of Light Shielding Wall

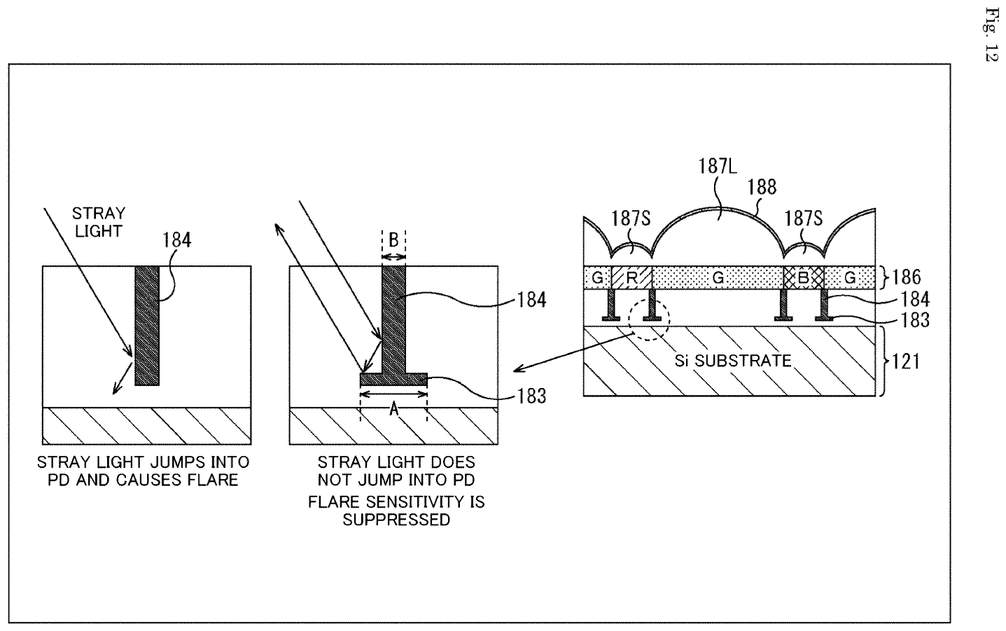

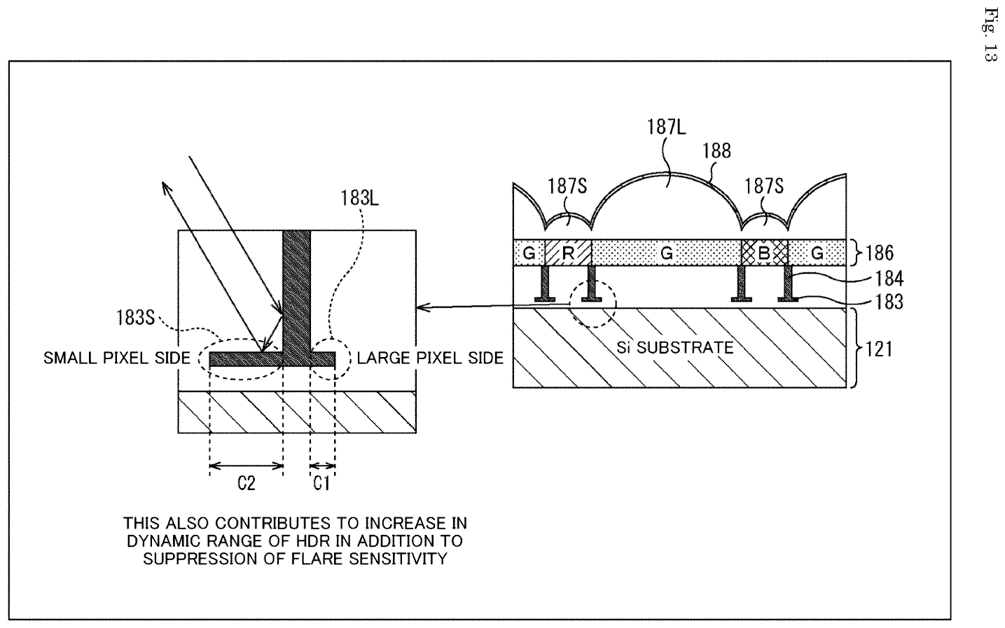

Next, a relationship between the width A of the inter-pixel light shielding film 183 and the width B of the light shielding wall 184 will be described with reference to FIGS. 12 and 13.

As described above, the relationship between the width A of the inter-pixel light shielding film 183 and the width B of the light shielding wall 184 is A>B, that is, the width A of the inter-pixel light shielding film 183 is formed to be larger than the width B of the light shielding wall 184.

In a case where the inter-pixel light shielding film 183 is not provided and only the light shielding wall 184 is formed as illustrated in the left diagram in FIG. 12, stray light generated inside an imaging module casing jumps into the photoelectric conversion unit 51 and becomes flare.

On the contrary, stray light is reflected upward by the inter-pixel light shielding film 183 projecting further in a planar direction (lateral direction) than the light shielding wall 184 and is prevented from jumping into the photoelectric conversion unit 51 by providing the inter-pixel light shielding film 183 and the light shielding wall 184 with the relationship of the width A>the width B. It is thus possible to enhance the effect of suppressing flare sensitivity.

In the inter-pixel light shielding film 183, a different width (the length in the planar direction) of the projecting portion projecting further in the planar direction than the light shielding wall 184 can be set for each of the side of the large pixel 100L and the side of the small pixel 100S. It is possible to strengthen the effect of suppressing flare sensitivity by forming a width C1 of a projecting portion 183L on the side of the large pixel to be smaller than a width C2 of a projecting portion 183S on the side of the small pixel, that is, by forming them to meet the relationship of the width C1<the width C2 as illustrated in FIG. 13, for example. Furthermore, this leads to an action of widening a sensitivity difference between the large pixel 100L and the small pixel 100S, and there is also an effect of enlarging the dynamic range of the solid-state imaging device 1.

### 4.5 Second Configuration Example of Light Shielding Wall

Next, a second configuration example of the light shielding wall 184 will be described on the assumption that the aforementioned configuration example of the light shielding wall 184 is a first configuration example.

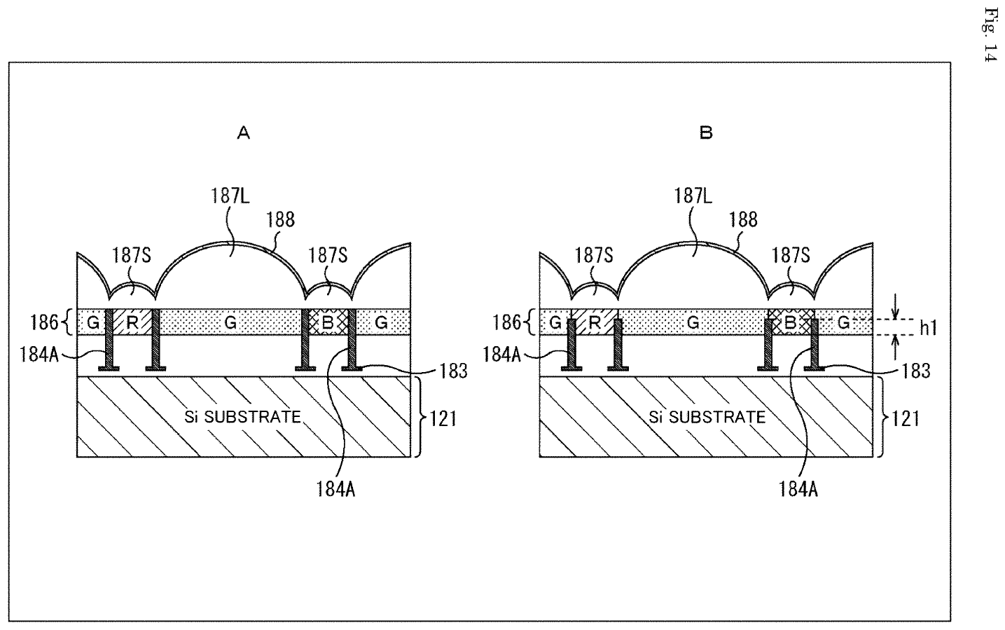

FIG. 14 is a sectional view illustrating the second configuration example of the light shielding wall.

In the aforementioned first configuration example of the light shielding wall 184, the upper surface of the light shielding wall 184 is at the same height as that of the bottom surface of the color filter 186, and the light shielding wall 184 is formed further downward than the layer of the color filter 186. On the contrary, a light shielding wall 184A, which is the second configuration example of the light shielding wall 184, is formed in at least a part of the same layer as that of the color filter 186.

As illustrated in A of FIG. 14, for example, the light shielding wall 184A extends up to the same height as that of the upper surface of the color filter 186 and can have a configuration of completely separating the color filter 186. Alternatively, the light shielding wall 184A may extend up to a height h1 of the color filter 186 from the bottom surface to a midpoint and have a configuration of separating a part of the color filter 186 as illustrated in B of FIG. 14.

In a case where the configuration of completely separating the color filter 186 is adopted as in A of FIG. 14, the effect of suppressing crosstalk is enhanced, while there is a concern of uneven coating of the color filter 186 due to the presence of the light shielding wall 184A.

On the contrary, in a case where the configuration of separating a part of the color filter 186 is adopted as in B of FIG. 14, the concern of uneven coating of the color filter 186 decreases, while the effect of suppressing crosstalk is also limited.

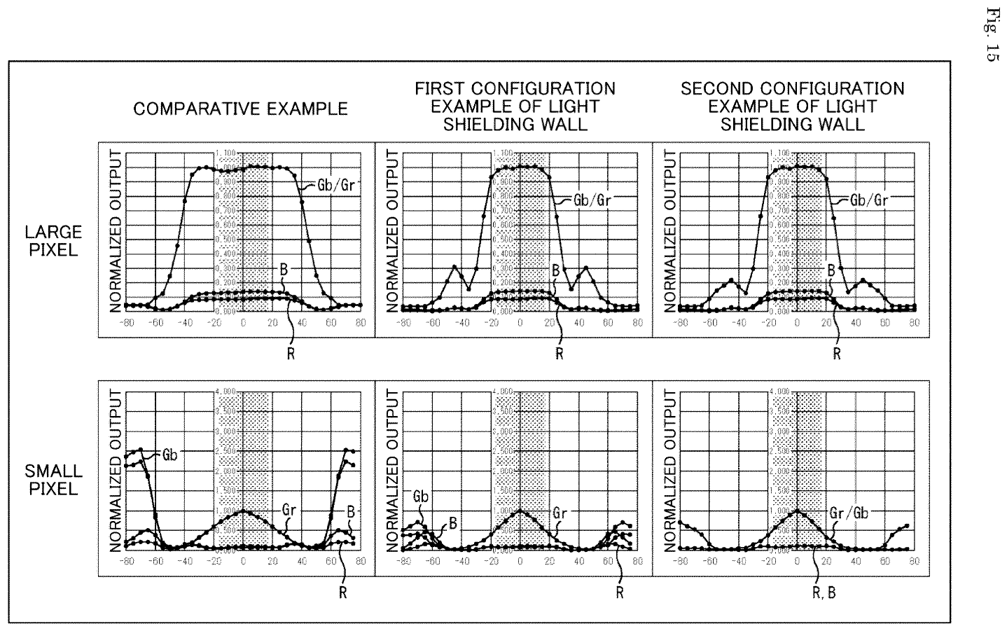

FIG. 15 illustrates optical simulation results of oblique incidence characteristics of the unit pixel 21′ in the comparative example and the unit pixel 21 including the light shielding wall 184 in the first configuration example or the second configuration example in the diagonal direction at the wavelength of 530 nm. As the second configuration example of the light shielding wall 184, the configuration in B of FIG. 14 in which the light shielding wall 184A separates a part of the color filter 186 is employed, and the height h1 of the color filter 186 from the bottom surface is set to 260 nm.

Since oblique incidence characteristics of the unit pixel 21′ in the comparative example and the unit pixel 21 including the light shielding wall 184 in the first configuration example are similar to those in FIG. 10, description thereof will be omitted.

It is possible to ascertain from comparison between oblique incidence characteristics of the unit pixel 21 including the light shielding wall 184 in the first configuration example and the unit pixel 21 including the light shielding wall 184 in the second configuration example that sensitivity of R and B is suppressed in the region of equal to or greater than ±50 degrees of the small pixel 100S in the unit pixel 21 including the light shielding wall 184 in the second configuration example and crosstalk components passing between color filters 186 can be suppressed. Although the configuration of extending the light shielding wall 184 up to the color filter 186 as well is desirable since it is possible to solve extreme coloring from the viewpoint of flare, the number of working processes increases.

### 4.6 Third Configuration Example of Light Shielding Wall

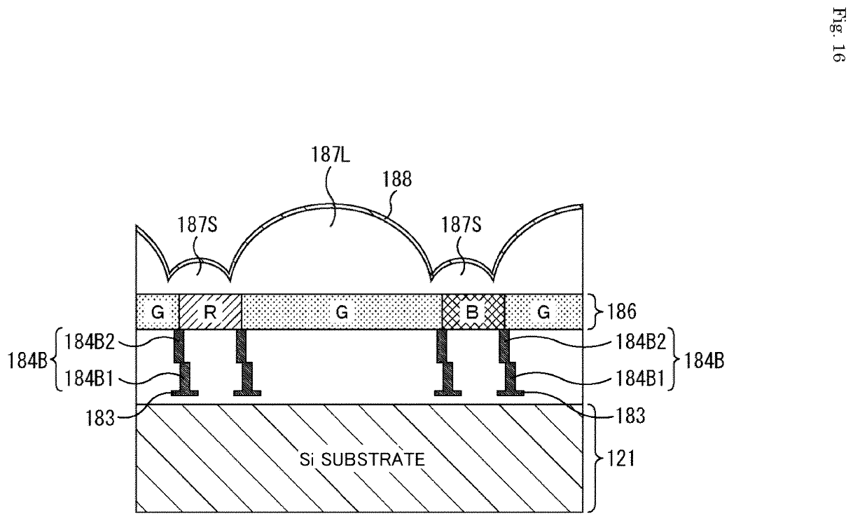

FIG. 16 is a sectional view illustrating a third configuration example of the light shielding wall.

A light shielding wall 184B as a third configuration example of the light shielding wall 184 is configured of a light shielding wall 184B1 in a lower stage (first stage) and a light shielding wall 184B2 in an upper stage (second stage) as illustrated in FIG. 16. The light shielding wall 184B2 in the upper stage is provided with a deviation in the planar direction at a position where pupil correction is performed on the light shielding wall 184B1 in the lower stage. In other words, the light shielding wall 184B2 in the upper stage is arranged with a deviation on the side closer to the center of the pixel array unit 11 than the light shielding wall 184B1 in the lower stage. Also, the color filter 186 and the on-chip lens 187 which are layers located further upward than the light shielding wall 184B2 in the upper stage are also arranged with a deviation on the side closer to the center of the pixel array unit 11 than the light shielding wall 184B1 in the lower stage in a similar manner. A degree of freedom in pupil correction increases, and it is possible to suppress degradation of the oblique incidence characteristics at an image angle end, by configuring the light shielding wall 184B in the two stages in this manner. Note that it is desirable that the light shielding wall 184B2 in the upper stage and the light shielding wall 184B1 in the lower stage be in contact with no gap therebetween as in FIG. 16 to suppress crosstalk.

Although the third configuration example illustrated in FIG. 16 is an example in which the light shielding wall 184B is configured of the two stages, namely the light shielding wall 184B1 in the lower stage and the light shielding wall 184B2 in the upper stage, a multi-stage configuration including three or more stages may also be adopted. Although there is a concern of an embedding failure of the light shielding material in a case where an aspect ratio of the light shielding wall 184 is high, it is possible to avoid the embedding failure through split working of two or more stages like the light shielding wall 184B.

### 4.7 Fourth Configuration Example of Light Shielding Wall

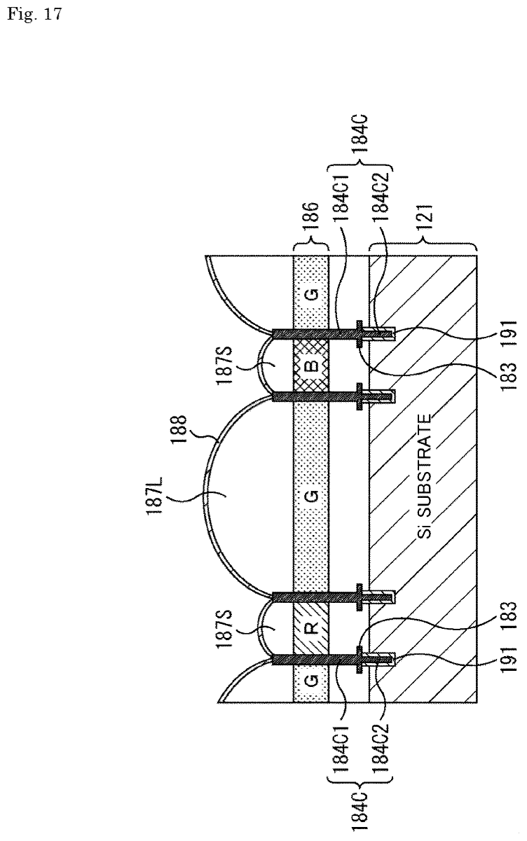

FIG. 17 is a sectional view illustrating a fourth configuration example of the light shielding wall.

A light shielding wall 184C as the fourth configuration example of the light shielding wall 184 is configured of a light shielding wall 184C1 on the side of the on-chip lens 187 than the inter-pixel light shielding film 183 and a light shielding wall 184C2 on the side of the semiconductor substrate 121 as illustrated in FIG. 17. The light shielding wall 184C1 on the side of the on-chip lens 187 extends not only to the color filter 186 but also to the on-chip lens 187 and is configured to separate the on-chip lens 187. The light shielding wall 184C2 on the side of the semiconductor substrate 121 extends up to a predetermined depth of the semiconductor substrate 121, and the periphery of the light shielding wall 184C2 inside the semiconductor substrate 121 is electrically separated from the semiconductor substrate 121 by an insulating film 191. It is also possible to block a crosstalk route inside the on-chip lens 187 by the light shielding wall 184C1 on the side of the on-chip lens 187 and to block a crosstalk route inside the substrate by the light shielding wall 184C2 on the side of the semiconductor substrate 121. Although the light shielding wall 184C in the fourth configuration example can solve extreme coloring in terms of flare, the number of working processes increases. Also, there is a concern of degradation of dark characteristics.

### 4.8 Manufacturing Method in First Embodiment

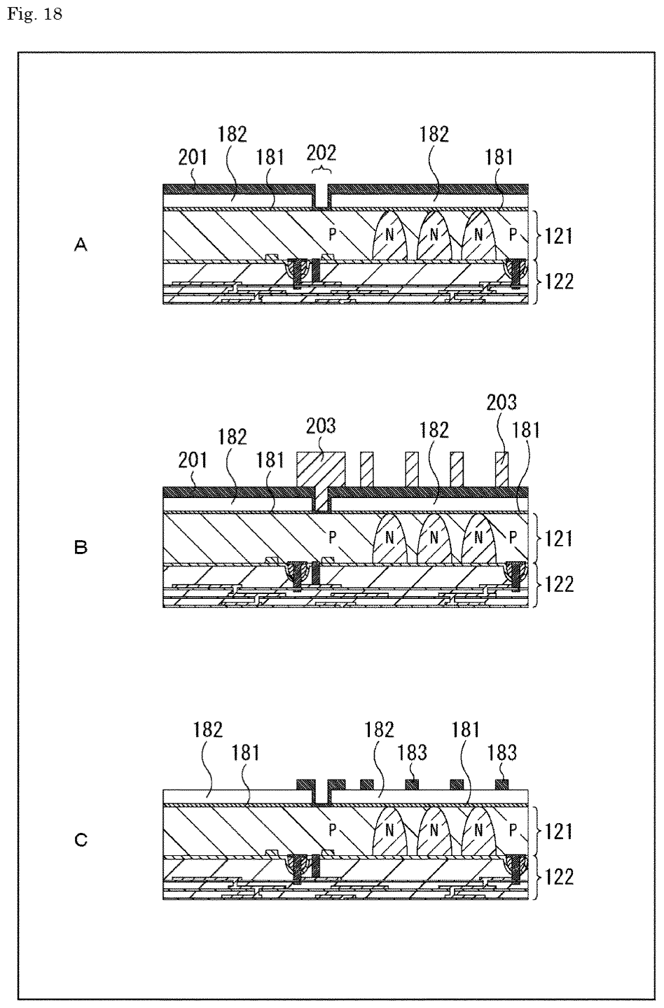

Next, a method of manufacturing the unit pixel 21 according to the first embodiment will be described with reference to FIGS. 18 to 21. In FIGS. 18 to 21, methods of forming the inter-pixel light shielding film 183 and the light shielding wall 184 will be mainly described, and reference signs of the other parts are appropriately omitted.

First, as illustrated in A of FIG. 18, the wiring layer 122 is formed on the side of the front surface of the semiconductor substrate 121, and the fixed charge film 181 and the insulating film 182 are formed on the side of the rear surface of the semiconductor substrate 121, after the photoelectric conversion units 51 and the element separation units 141 are formed inside the semiconductor substrate 121.

More specifically the photoelectric conversion units 51 that are separated by the element separation units 141 produced by P-type semiconductor regions are formed in regions where pixel regions are to be formed in the semiconductor substrate 121, which is a silicon substrate, for example. The photoelectric conversion units 51 are formed to have PN junctions including N-type semiconductor regions ranging over the entire region in the substrate thickness direction and P-type semiconductor regions that are in contact with the N-type semiconductor regions and face both the front and rear surfaces of the substrate. Impurity regions of the N-type semiconductor regions or the P-type semiconductor regions can be formed through ion injection of desired impurities from the front surface side of the substrate using a resist as a mask. P-type semiconductor well regions that are in contact with the element separation units 141 are formed in regions in the substrate surface corresponding to each of the large pixels 100L and the small pixels 100S, and a plurality of pixel transistors Tr are formed in the P-type semiconductor well regions. The pixel transistors Tr are formed of source regions and drain regions of the N type, gate insulating films, and gate electrodes.

Furthermore, the wiring layer 122 is formed on the front surface of the semiconductor substrate 121. The wiring layer 122 includes metal wirings 131 in a plurality of layers configured of aluminum or copper, for example, and an inter-layer insulating film 132 located therebetween and configured of a silicon oxide film or the like. The pixel transistors Tr is connected to predetermined metal wirings 131 via through-vias, and drive voltages to drive the pixel transistors Tr are applied to the pixel transistors Tr. After the inter-layer insulating film 132, which is a silicon oxide film or the like, is flattened through chemical-mechanical polishing (CMP), the metal wirings 131 in the plurality of layers are formed by repeating formation of the through-vias to establish connection to the metal wiring 131 in the layer located below, and further forming the metal wiring 131 thereon.

Next, the fixed charge film 181 and the insulating film 182 are formed on the rear surface of the semiconductor substrate 121 using chemical vapor deposition (CVD), sputtering, atomic layer deposition (ALD), or the like. It is desirable that the fixed charge film 181 that is in contact with the semiconductor substrate 121 be formed through ALD by which a satisfactory coverage can be obtained in an atomic layer level. In a case where silicon oxide, for example, is formed through ALD as the insulating film 182 formed thereon, film peeling due to a blister phenomenon is likely to occur if the film thickness is reduced, and the film thickness of the insulating film 182 is at least equal to or greater than 20 nm, and is preferably a thickness of equal to or greater than 50 nm.

Next, an inter-pixel light shielding film material 201 is formed on the insulating film 182 as illustrated in A of FIG. 18. The inter-pixel light shielding film material 201 is, for example, tungsten (W), and CVD or sputtering can be used as a film forming method. An opening portion 202 where the fixed charge film 181 and the insulating film 182 are opened is provided in a region outside the pixel array unit 11, and the inter-pixel light shielding film material 201 is connected to the P-type semiconductor region in the semiconductor substrate 121 through the opening portion 202. Since there is a risk of occurrence of plasma damage when the inter-pixel light shielding film material 201 is worked in an electrically floating state, film formation is performed such that the inter-pixel light shielding film material 201 is connected to the P-type semiconductor region grounded to the ground potential at the opening portion 202. The opening portion 202 can be formed by forming a resist pattern with a width of several μm on the insulating film 182 and performing anisotropic etching or wet etching.

The inter-pixel light shielding film material 201 may be formed in a plurality of laminated films to enhance adhesion to the insulating film 182 located below the inter-pixel light shielding film material 201. For example, titanium, titanium nitride, or a laminated film thereof may be formed as a layer tightly adhering to the insulating film 182. The inter-pixel light shielding film material 201 can also serve as a light shielding film for a black level calculation pixel that is a pixel to calculate a black level of an image signal or a light shielding film to prevent an operation error of a peripheral circuit.

Next, a resist 203 is patterned on the inter-pixel light shielding film material 201 in formation regions of the inter-pixel light shielding films 183, and the inter-pixel light shielding film material 201 is then partially removed by anisotropic etching or the like, as illustrated in B of FIG. 18. In this manner, the inter-pixel light shielding films 183 are formed as illustrated in C of FIG. 18. Residues are removed by chemical cleaning as needed.

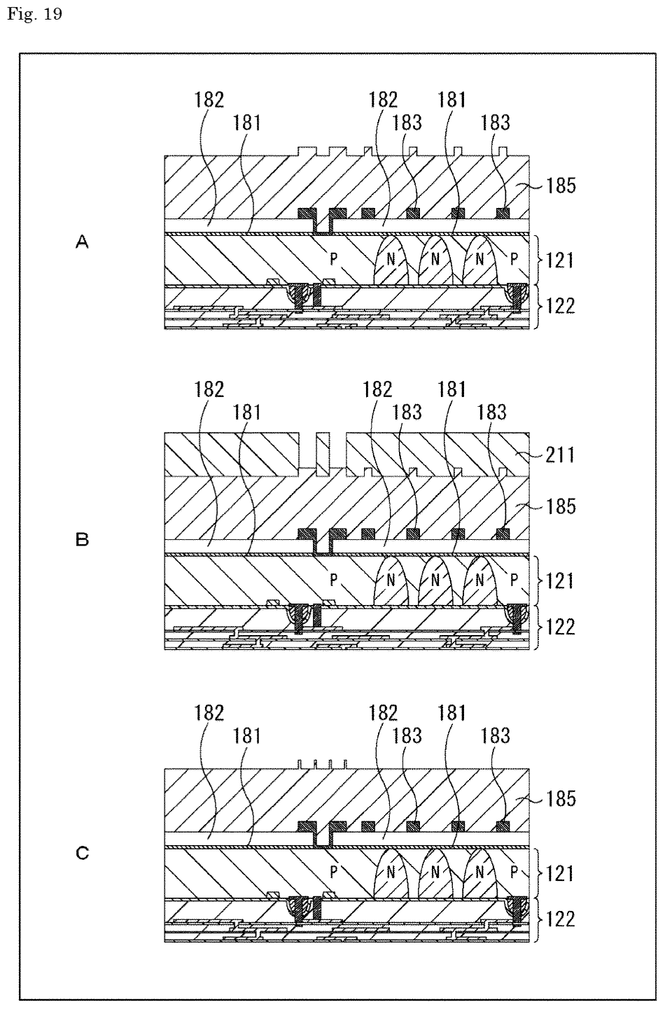

Next, the spacer layer 185 is formed by forming a transparent inorganic film, for example, silicon oxide (SiO₂) on the insulating film 182 and the inter-pixel light shielding films 183 using CVD or the like as illustrated in A of FIG. 19. In a case where unevenness is generated on the upper surface of the spacer layer 185 due to an influence of steps of working of the inter-pixel light shielding films 183 located as a base as illustrated in A of FIG. 19, a reversely worked resist mask 211 may be formed with respect to regions which are grounded on the semiconductor substrate 121 where the areas of the inter-pixel light shielding films 183 are large as illustrated in B of FIG. 19, and the projecting portions of the spacer layer 185 may be removed through time-managed etching as illustrated in C of FIG. 19.

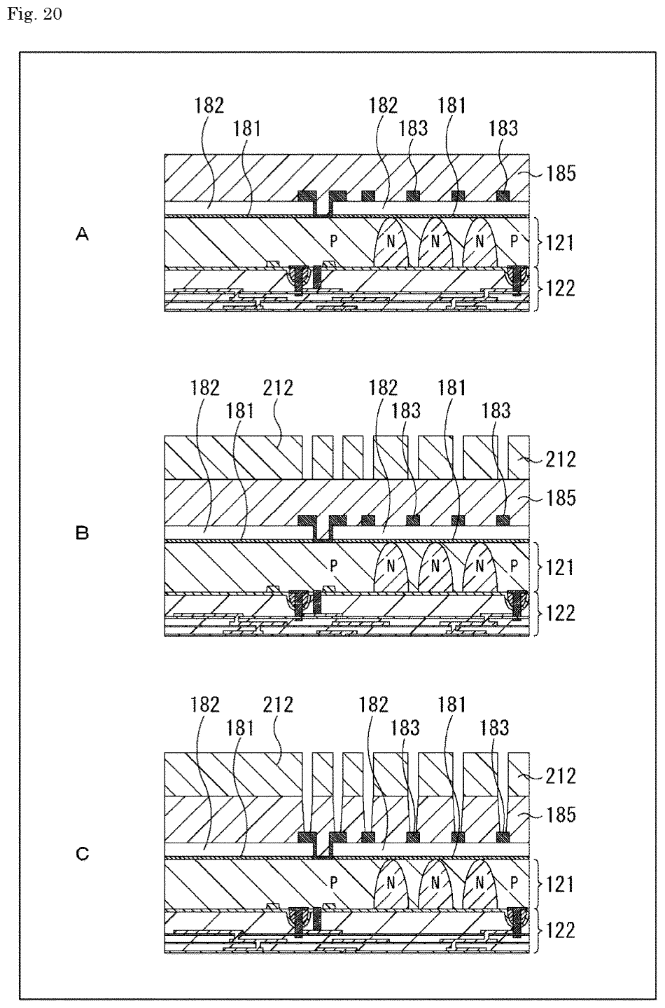

Thereafter, the spacer layer 185 may be flattened through CMP as illustrated in A of FIG. 20. Note that in a case where a degree of flatness of the spacer layer 185 is satisfactory, the processes from B of FIG. 19 to A of FIG. 20 can be omitted.

Next, after resist masks 212 are formed in regions other than regions where the light shielding walls 184 are formed as illustrated in B of FIG. 20, the spacer layer 185 is removed through etching, and upper portions of the inter-pixel light shielding films 183 are exposed as illustrated in C of FIG. 20. The regions where the spacer layer 185 are removed have an octagonal shape or a quadrangular shape in a plan view, which is the same planar shape of the light shielding walls 184 illustrated in B of FIG. 8. Note that since there is a concern of cracking due to stress concentration in microfabrication of such a high aspect ratio, finished corners of sides of the octagonal shape or the quadrangular shape may not be linear and may be intentionally rounded. A radius of curvature in this case is preferably equal to or greater than 1/10, more desirably equal to or greater than 1/7 the pixel size of the small pixels 100S.

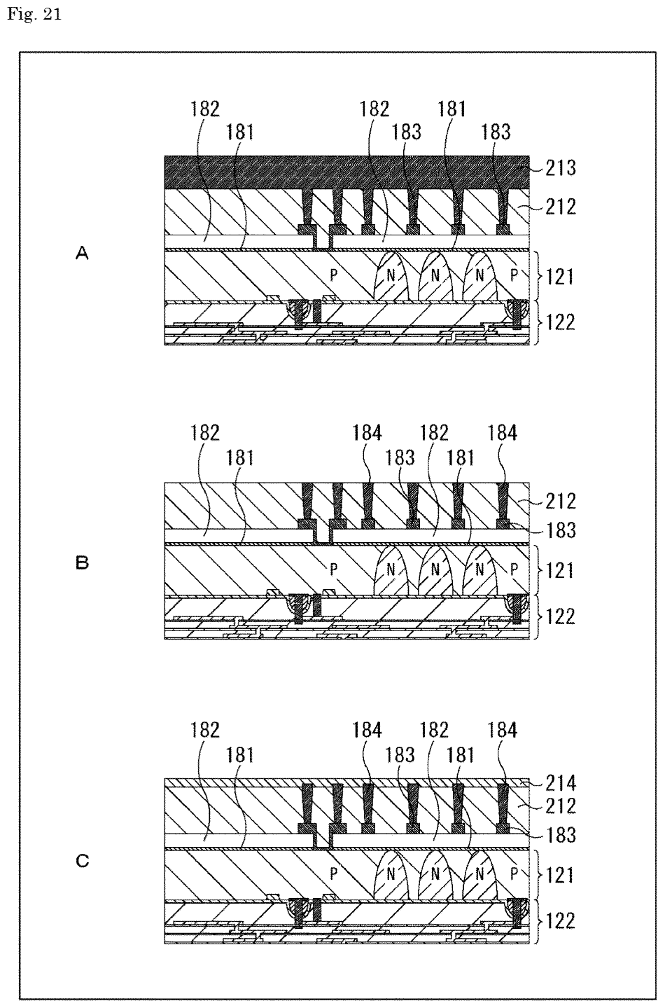

Next, a light shielding wall metal material 213 is formed on the resist mask 212 as illustrated in A of FIG. 21. The light shielding wall metal material 213 is, for example, tungsten (W), and it is possible to use CVD or sputtering as a film formation method. The light shielding wall metal material 213 is also embedded in trench portions in the spacer layer 185 above the inter-pixel light shielding films 183.

Next, the light shielding wall metal material 213 in the upper layer of the spacer layer 185 is removed by CMP or entire surface etch-back as illustrated in B of FIG. 21. In this manner, the light shielding walls 184 are completed.

Next, the spacer layer 185 and the light shielding walls 184 are protected with a protection film 214 such as an oxide film as illustrated in C of FIG. 21. Although the protection film 214 is omitted in the sectional view of FIG. 7, the protection film 214 is a film for protection since the organic material of the color filters 186 and the like formed on the spacer layer 185 may be brought into contact with the light shielding walls 184 which is a metal material and may change in quality. The protection film 214 also has a role of protecting the metal material of the inter-pixel light shielding films 183 from a peeling agent or the like in a case where peeling of layers located further upward than the color filters 186 is needed due to an exposure trouble or out of specification.

Next, although illustration is omitted, the color filters 186 are formed by rotation-applying, for example, a photosensitizer and a resist containing a pigment or a dye to a wafer and then performing exposure, development, and post-baking. In a case where the color filters 186 are dye resists, UV curing or additional baking may be performed.

Finally, the on-chip lenses 187 are formed. First, an organic material such as a styrene-based resin (refractive index n of about 1.6), an acrylic resin (n of about 1.5), or a styrene-acrylic copolymer-based resin (n of about 1.5 to 1.6), for example, is formed as a material of the on-chip lenses 187 through rotation-application. The material of the on-chip lenses 187 may be a hybrid of organic and inorganic materials in which fine TiO particles are dispersed in the aforementioned resin or a polyimide resin. Alternatively, an inorganic material such as SiN (n of about 1.9 to 2) or SiON (about 1.45 to 1.9) may be formed as a material of the on-chip lenses 187 through CVD or the like. Then, the resists are formed into lens shapes through exposure and reflow on the material of the on-chip lenses 187, and the lens shapes of the resists are transferred to the material of the on-chip lenses 187 through anisotropic etching. Next, the anti-reflection films 188 are formed on the surface of the on-chip lenses 187 for the purpose of improving sensitivity and preventing flare. It is desirable that SiO₂, for example, be used as a material of the anti-reflection films 188 and the coating be performed in accordance with a reflection preventing design approximately following the 4/λ law. Each anti-reflection film 188 is not necessarily limited to a single layer and may be a multilayer film. It is also possible to reduce areas of flat and ineffective regions at diagonal portions where curved surfaces of the on-chip lenses 187 are not formed through the formation of the anti-reflection films 188.

Note that large on-chip lenses 187L above the first photoelectric conversion units 51L and small on-chip lenses 187S above the second photoelectric conversion units 51S, which have different areas and lens thicknesses, may be formed through two times working, namely lithography, etching, lithography, and etching. In a case where it is possible to achieve control merely by the resist mask, one-time exposure and one-time etching may be adopted.

The unit pixels 21 according to the first embodiment can be manufactured as described above.

### 4.9 Summary of First Embodiment

Each unit pixel 21 according to the first embodiment includes the first photoelectric conversion unit 51L and the second photoelectric conversion unit 51S with different areas of photoelectric conversion regions formed in the semiconductor substrate 121, the inter-pixel light shielding film 183 provided on at least a part of a boundary between unit pixels 21 on the side of the incident light relative to the semiconductor substrate 121, the spacer layer 185 that is provided on the side of the incident light relative to the inter-pixel light shielding film 183, the light shielding wall 184 that is included on at least a part of a boundary between unit pixels 21 on the side of the incident light relative to the inter-pixel light shielding film 183 and sections the spacer layer 185, and the on-chip lens 187 that collects the incident light on the photoelectric conversion units 51.

The unit pixels 21 according to the first embodiment can suppress crosstalk from the large pixels 100L to the small pixels 100S by including the spacer layer 185 that increases the height of the on-chip lenses 187 and the light shielding walls 184 that sections the spacer layers 185 and shields light. Also, it is possible to suppress unnecessary light sensitivity at each large pixel 100L. It is possible to suppress flare by suppressing crosstalk and unnecessary light sensitivity.

### 5. Second Embodiment of Unit Pixels

### 5.1 First Configuration Example in Second Embodiment

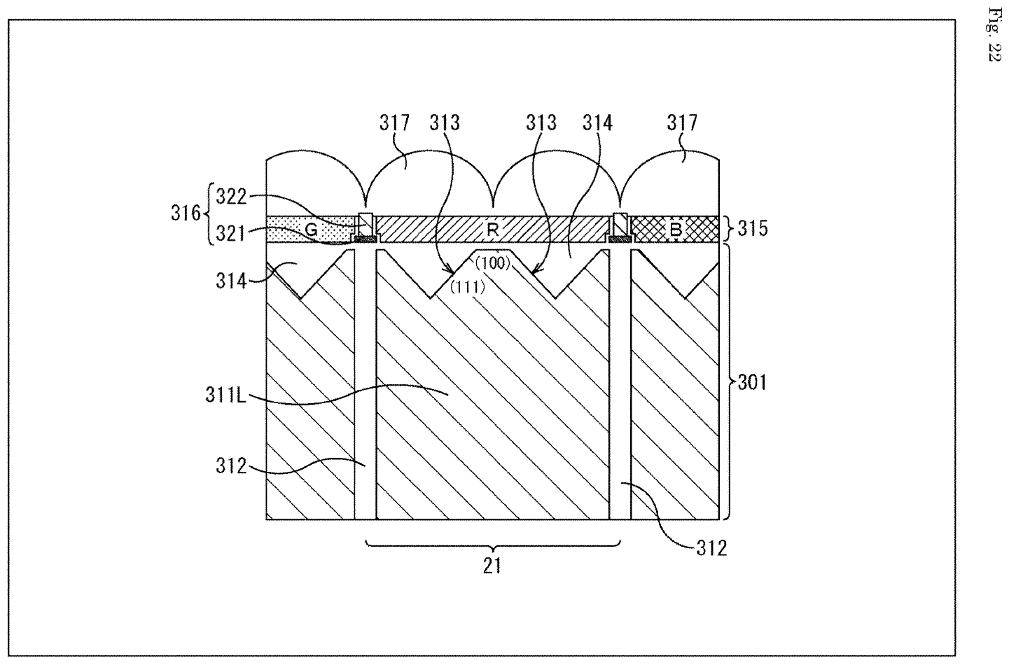

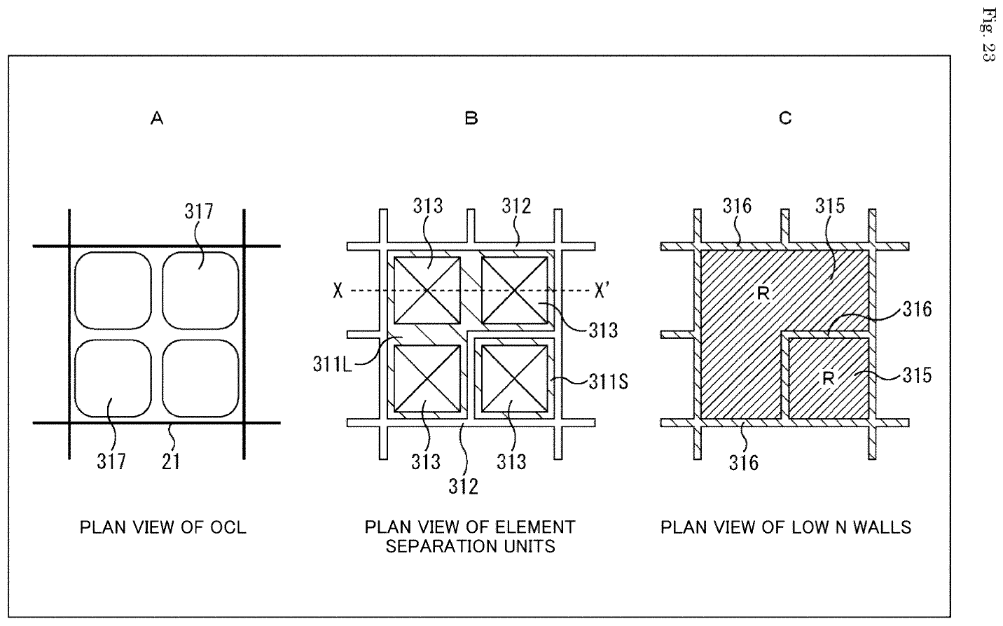

FIG. 22 is a sectional view illustrating a first configuration example of unit pixels 21 according to a second embodiment of the present disclosure and illustrates a sectional view along the line X-X′ in B of FIG. 23. In FIG. 23, A to Care plan views of the unit pixels 21 in FIG. 22 at a predetermined depth position.

In the second embodiment, the second layout example illustrated in FIG. 3 is employed as a layout of the unit pixels 21. As a layout of the on-chip lenses, the layout in A of FIG. 4 in which arrangement of the same shapes and sizes is performed. Although reference signs that are different from those in the aforementioned first embodiment are applied in the second embodiment, corresponding parts to the first embodiment will be briefly described.

For the unit pixels 21 in the first embodiment described above, the configuration of suppressing crosstalk by forming the spacer layer 185 and increasing the height of the on-chip lens 187 has been described. On the contrary, the spacer layer 185 is omitted, and instead, a light shielding wall (hereinafter, referred to as a low N wall) made of a low refractive index material is provided in the same layer as the color filters for the unit pixels 21 in the second embodiment.

Each unit pixel 21 according to the first configuration example in the second embodiment is formed to have a quadrangular planar shape as illustrated in A of FIG. 23. In the unit pixel 21, a first photoelectric conversion unit 311L with a large area of a photoelectric conversion region and a second photoelectric conversion unit 311S (B of FIG. 23) with a smaller photoelectric conversion region than the first photoelectric conversion unit 311L are formed on a semiconductor substrate 301 configured of a P-type (first conductivity type) semiconductor region, for example, as illustrated in FIG. 22. The semiconductor substrate 301 is configured of a silicon substrate using silicon (Si), for example, as a semiconductor and corresponds to the semiconductor substrate 121 according to the first embodiment. Although a wiring layer in which pixel transistors Tr (FIG. 7) and the like are formed is formed on the front surface side of the semiconductor substrate 301, which is the lower side in the drawing, similarly to the first embodiment, illustration thereof is omitted.

As illustrated in B of FIG. 23, the first photoelectric conversion unit 311L is formed into an L shape in a plan view, and the second photoelectric conversion unit 311S is formed into a quadrangular shape. Therefore, the first photoelectric conversion unit 311L is the photoelectric conversion unit 311 with high sensitivity, and the second photoelectric conversion unit 311S is the photoelectric conversion unit 311 with low sensitivity. The first photoelectric conversion unit 311L and the second photoelectric conversion unit 311S are configured of PN junction-type photodiodes similar to the first embodiment. In a case where the first photoelectric conversion unit 311L and the second photoelectric conversion unit 311S are not particularly distinguished, the first photoelectric conversion unit 311L and the second photoelectric conversion unit 311S will be simply referred to as photoelectric conversion units 311. Element separation units 312 that separate the photoelectric conversion elements are formed at a boundary between the first photoelectric conversion unit 311L and the second photoelectric conversion unit 311S and a boundary between the adjacent unit pixels 21.

As illustrated in FIG. 22, the element separation units 312 are configured by embedding an insulating film such as a silicon oxide film (SiO₂) in trenches penetrating through the semiconductor substrate 301. On the side of a light receiving surface of the semiconductor substrate 301, recessed portions 313 with inverted pyramid structures are formed. Four recessed portions 313 are arranged in a 2×2 layout in each unit pixel 21, three recessed portions 313 are arranged in the first photoelectric conversion unit 311L, and one recessed portion 313 is arranged in the second photoelectric conversion unit 311S, as illustrated in B of FIG. 23. The surfaces of the recessed portions 313 are formed of a (111) plane of the semiconductor substrate 301, and a planar portion of the semiconductor substrate 301 where the recessed portions 313 are not formed is formed of a (100) plane of the semiconductor substrate 301. The insulating films 314 of the same material as that of the element separation units 312 are embedded in upper portions of the (111) plane of the recessed portions 313 with the inverted pyramid structure.

In FIG. 22, a color filter 315 is formed on the side of the rear surface, which is the surface on the upper side, of the semiconductor substrate 301. The color filter 315 of a red color (R), a green color (G), or a blue color (B), for example, is arranged in a Bayer layout for each unit pixel 21 as illustrated in B of FIG. 3. A low N wall 316 configured of a lamination including an inter-pixel light shielding film 321 and a low refractive index resin film 322 is formed in the same layer as the color filter 315 and immediately above the element separation units 312.

The inter-pixel light shielding film 321 is configured of a material that is similar to that of the inter-pixel light shielding film 183 in the first embodiment. In other words, the inter-pixel light shielding film 321 is made of any material as long as the material shields light, and is preferably formed of a metal film of Al, W, or Cu, for example, as a material that has a high light shielding property and can be worked with high precision in microfabrication, for example, etching. In other cases, the inter-pixel light shielding film 321 can be configured of silver, gold, platinum, Mo, Cr, Ti, nickel, iron, tellurium, or an alloy containing such metal. Furthermore, it is also possible to configure the inter-pixel light shielding film 321 by staking a plurality of such materials. In order to enhance adhesion to the element separation units 312 as a base, barrier metal, for example, Ti, Ta, W, Co, Mo, or an alloy, a nitride, an oxide, or a carbide thereof may be included below the light shielding metal.

The low refractive index resin film 322 is configured of a material with a lower refractive index than that of the color filter 315. The low refractive index resin film 322 can be formed of, for example, an organic resin film of a styrene-based resin, an acrylic resin, a styrene-acrylic copolymer resin, or a siloxane resin. The low refractive index resin film 322 may be formed of, for example, an inorganic film of SiN, SiO₂, or SiON.

In FIG. 23, C is a plan view of the layer of the color filters 315 and the low N walls 316. The low N walls 316 have an arrangement similar to that of the element separation units 312 in B of FIG. 23 in a plan view, and specifically, the low N walls 316 are formed at the boundary between the first photoelectric conversion unit 311L and the second photoelectric conversion unit 311S and the boundary between the adjacent unit pixels 21.

As illustrated in FIG. 22, the on-chip lenses 317 are formed on the color filters 186 and the low N walls 316. Four on-chip lenses 317 are arranged in a 2×2 arrangement inside each unit pixel 21 with three on-chip lenses 317 arranged on the first photoelectric conversion unit 311L and with one on-chip lens 317 arranged on the second photoelectric conversion unit 311S as illustrated in A of FIG. 23. An anti-reflection film may be formed on the surface of the on-chip lenses 317 similarly to the first embodiment.

In the solid-state imaging device 1 including the unit pixels 21 according to the second embodiment configured as described is a solid-state imaging device of a back-illuminated type in which incident light is collected on the on-chip lens 317 formed on the rear surface side of the semiconductor substrate 301 and is subjected to photoelectric conversion by the photoelectric conversion unit 311. Each unit pixel 21 according to the second embodiment includes a large pixel including the first photoelectric conversion unit 311L with a larger area of the photoelectric conversion region and a small pixel including the second photoelectric conversion unit 311S with a smaller photoelectric conversion region than that of the first photoelectric conversion unit 311L and enables high-sensitivity imaging with the large pixel and low-sensitivity imaging with the small pixel.

Each unit pixel 21 according to the first configuration example in the second embodiment includes the first photoelectric conversion unit 311L and the second photoelectric conversion unit 311S that are formed in the semiconductor substrate 301 and have different areas of photoelectric conversion regions, the element separation units 312 that penetrate through the semiconductor substrate 301 and separate the first photoelectric conversion unit 311L and the second photoelectric conversion unit 311S, the color filters 315 that are provided on the side of incident light relative to the semiconductor substrate 301, the low N walls 316 that are provided between the color filters 315, the recessed portions 313 that are provided on the side of the light receiving surface of the semiconductor substrate 301, and the on-chip lenses 317 that collect the incident light on the photoelectric conversion units 311.

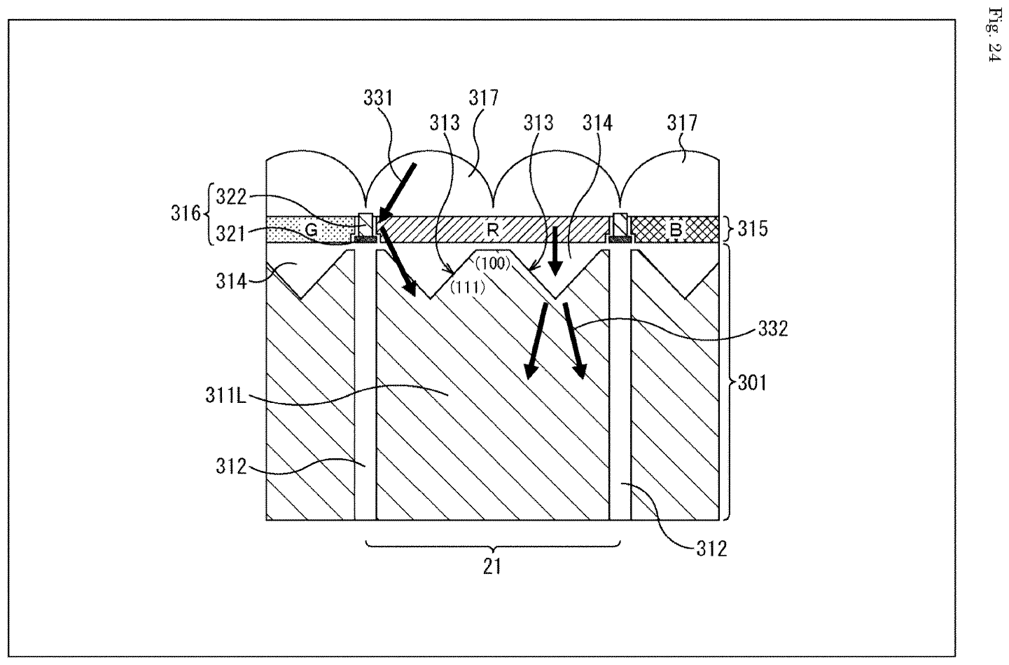

According to the unit pixels 21 of the first configuration example in the second embodiment, it is possible to reflect incident light or stray light at a high angle that is about to pass between the unit pixels 21 or between the large pixel and the small pixel as illustrated by the arrow 331 in FIG. 24 and to suppress color mixing between the pixels by providing the low N walls 316 at the boundary between the first photoelectric conversion unit 311L and the second photoelectric conversion unit 311S and the boundary between the adjacent unit pixels 21 in the same layer as the color filters 315. It is thus possible to suppress colored flare. Moreover, the low N walls 316 are configured by laminating the low refractive index resin film 322 on the inter-pixel light shielding film 321 and reduce a metal absorption loss due to the inter-pixel light shielding film 321 that is a metal film. It is thus possible to improve light receiving sensitivity.

Furthermore, according to the unit pixels 21 of the first configuration example in the second embodiment, it is possible to increase the optical path length by a light scattering effect as illustrated by the arrow 332 in FIG. 24 and to improve light receiving sensitivity by providing the recessed portions 313 on the side of the light receiving surface of the semiconductor substrate 301. This is advantageous for improving sensitivity to a near-infrared wavelength.

### 5.2 Modification Examples of Low N Wall

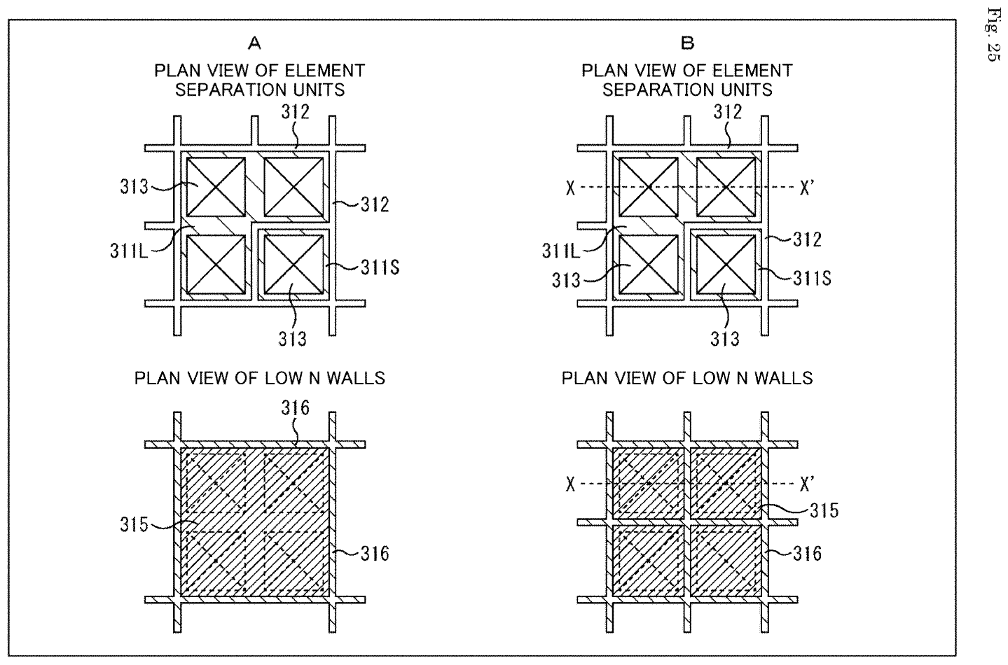

FIG. 25 is a plan view illustrating a modification example of the low N walls 316 of the unit pixels 21 according to the first modification example. FIG. 25 illustrates a plan view of the low N walls 316 and a plan view of the element separation units 312. In the plan view of the low N walls 316, the recessed portions 313 are illustrated by dashed lines.

In the structure of each unit pixel 21 according to the first configuration example illustrated in FIGS. 22 and 23, the low N walls 316 are formed in the same arrangement as that of the element separation units 312. In other words, the low N walls 316 are provided at the boundary between the first photoelectric conversion unit 311L and the second photoelectric conversion unit 311S and the boundary between the adjacent unit pixels 21.

On the contrary, in a first modification example illustrated in A of FIG. 25, the low N wall 316 is provided only at the boundary between the adjacent unit pixels 21 and is not provided at the boundary between the first photoelectric conversion unit 311L and the second photoelectric conversion unit 311S. According to the first modification example, it is possible to suppress color mixing between the unit pixels 21 and to suppress colored flare. Moreover, since some of the low N walls 316 is omitted as compared with the structure in the first configuration example, it is possible to reduce a metal absorption loss due to the inter-pixel light shielding film 321 that is a metal film. It is thus possible to improve light receiving sensitivity of the unit pixels 21 as compared with the basic structure of the first configuration example.

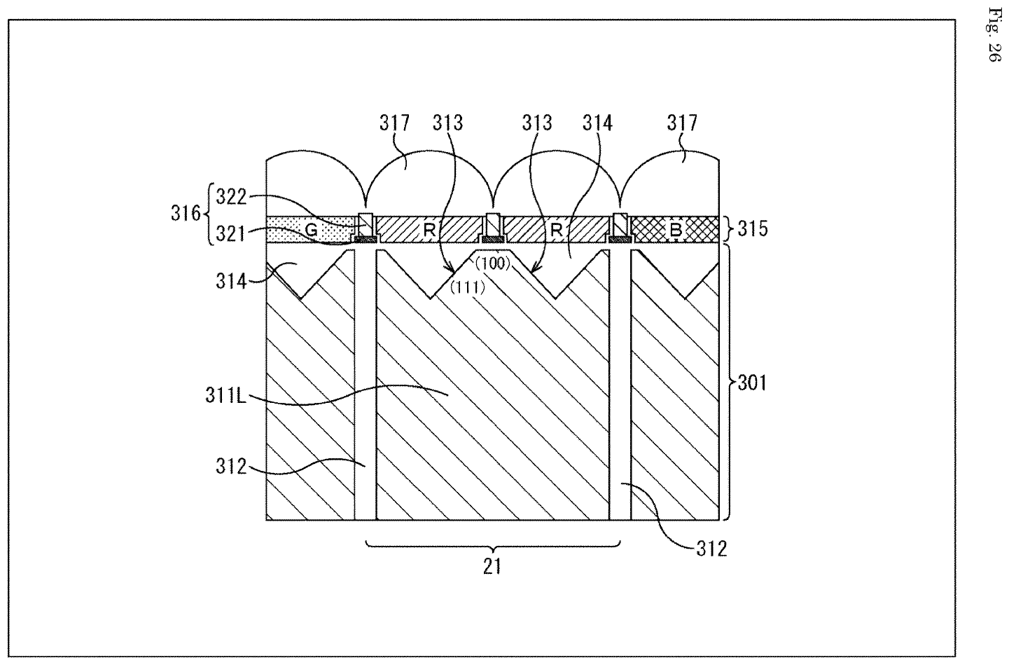

On the other hand, in a second modification example illustrated in B of FIG. 25, the low N walls 316 are provided at a ¼ pixel cycle of the unit pixels 21. In other words, similarly to the low N walls 316 provided in the periphery of one recessed portion 313 in the second photoelectric conversion unit 311S, the low N walls 316 are provided in units of recessed portions 313 in the first photoelectric conversion unit 311L as well. The sectional view along the line X-X′ in B of FIG. 25 is as illustrated in FIG. 26. According to the second modification example, symmetry of the low N walls 316 is secured, and it is thus possible to solve asymmetry of sensitivity outputs from the large and small pixels in response to obliquely incident light.

### 5.3 Second Configuration Example in Second Embodiment

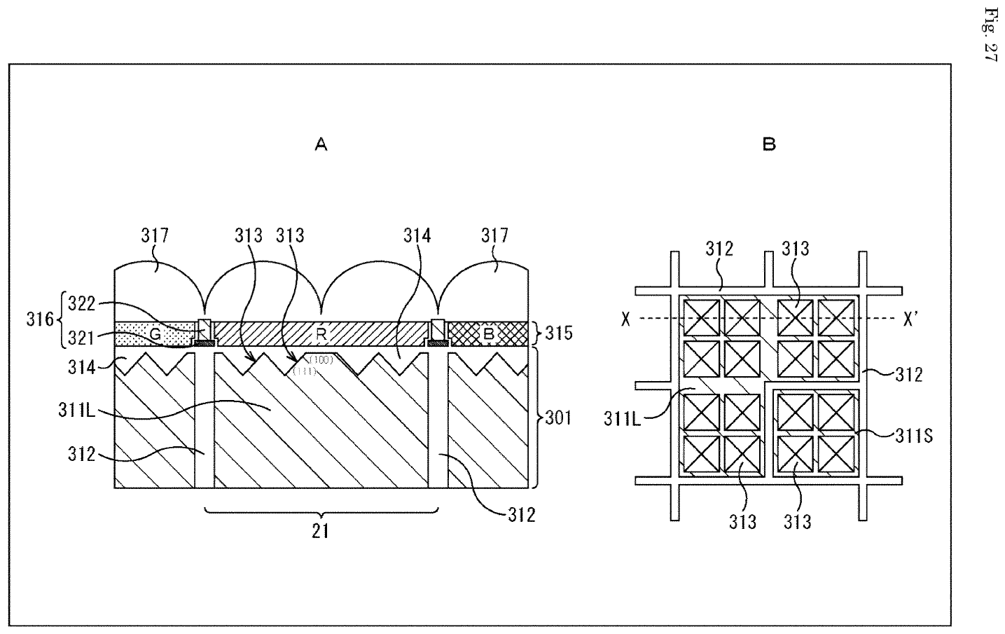

In FIG. 27, A is a sectional view illustrating a second configuration example of the unit pixels 21 according to the second embodiment of the present disclosure and illustrates a sectional view along the line X-X′ in B of FIG. 27. In FIG. 27, Bis a plan view of each unit pixel 21 in A of FIG. 27 at a predetermined depth position.

In FIG. 27, parts corresponding to those in the first configuration example illustrated in FIGS. 22 and 23 are denoted by the same reference signs, and description will be given by focusing on parts different from those in the first configuration example.

In the aforementioned first configuration example, three recessed portions 313 formed in the light receiving surface of the semiconductor substrate 301 are arranged above the first photoelectric conversion unit 311L, one recessed portions 313 is arranged above the second photoelectric conversion unit 311S, and four recessed portions 313 are arranged in the 2×2 layout inside the unit pixel 21.

On the contrary, each recessed portion 313 is formed to have a smaller size in the second configuration example in FIG. 27 as compared with the recessed portion 313 in the first configuration example, and sixteen recessed portions 313 with the small size are arranged in a 4×4 layout in a unit pixel 21. Twelve recessed portions 313 with the small size are arranged above the first photoelectric conversion unit 311L, and four recessed portions 313 with the small size are arranged above the second photoelectric conversion unit 311S.

The unit pixel 21 in the second configuration example is similar to that in the first configuration example other than that the size of each recessed portion 313 and the number of recessed portions 313 arranged above each of the first photoelectric conversion unit 311L and the second photoelectric conversion unit 311S are different.

The size of the recessed portion 313 can be appropriately determined in accordance with a target wavelength of incident light, quantum efficiency (QE) of which is desired to be improved. It is possible to improve sensitivity of a longer wavelength as the size of the recessed portion 313 is increased. It is possible to arrange four recessed portions 313 in 2×2 in a unit pixel 21 as in the first configuration example in a case where a wavelength of about 940 nm is set as a target wavelength for the purpose of improving sensitivity to near-infrared light of about 850 nm to 940 nm, or it is possible to arrange sixteen recessed portions 313 in 4×4 as in the second configuration example in a case where a wavelength of about 850 nm is set as a target wavelength.

It is possible to suppress color mixing between pixels by providing the low N walls 316 in the same layer as the color filter 315 also in the unit pixel 21 according to the second configuration example. It is thus possible to suppress colored flare. Since a metal absorption loss is reduced by the low N walls 316 configured by laminating the low refractive index resin film 322 on the inter-pixel light shielding film 321, it is possible to improve light receiving sensitivity. Moreover, it is possible to increase the optical path length by a light scattering effect and to improve light receiving sensitivity by providing the recessed portions 313 on the side of the light receiving surface of the semiconductor substrate 301.

### 5.4 Modification Examples of Recessed Portion

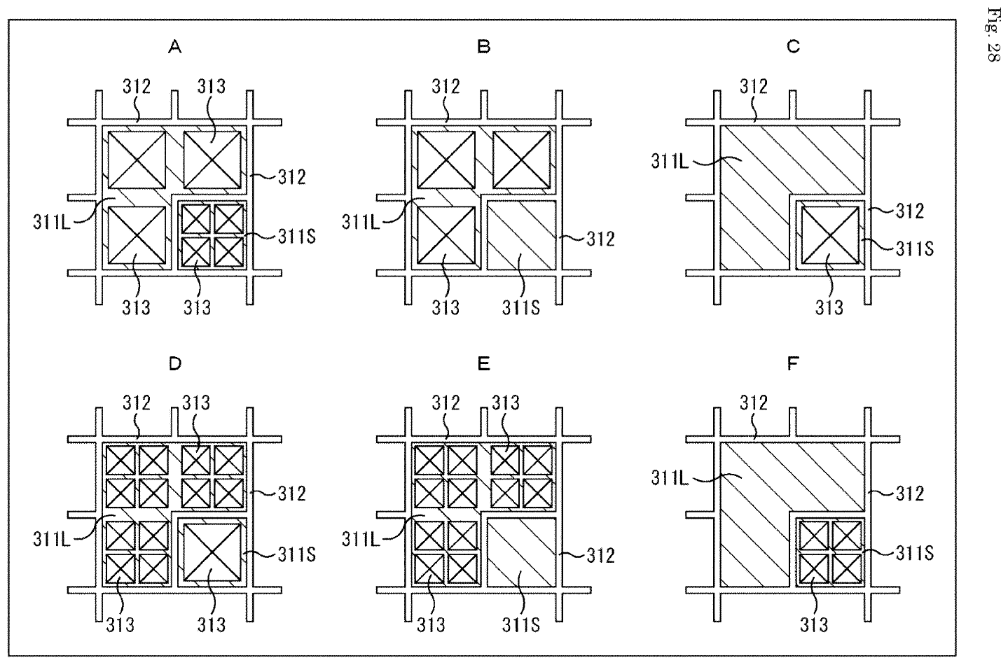

FIG. 28 is a plan view illustrating modification examples of the recessed portions 313 in the first configuration example and the second configuration example.

In the first configuration example and the second configuration example described above, the plurality of recessed portions 313 with the same size are provided inside the unit pixel 21.

However, recessed portions 313 with a large size and recessed portions 313 with a small size may be appropriately combined and arranged inside the unit pixel 21. Alternatively, there may be a region where the recessed portions 313 are not arranged.

For example, a configuration in which three recessed portions 313 with a large size are arranged above the first photoelectric conversion unit 311L and four recessed portions 313 with a small size are arranged above the second photoelectric conversion unit 311S as illustrated in A of FIG. 28 may be adopted.

Alternatively, a configuration in which three recessed portions 313 with a large size are arranged above the first photoelectric conversion unit 311L and no recessed portions 313 are arranged above the second photoelectric conversion unit 311S as illustrated in B of FIG. 28, for example, may be adopted.

Alternatively, a configuration in which no recessed portions 313 are arranged above the first photoelectric conversion unit 311L and one recessed portion 313 with a large size is arranged above the second photoelectric conversion unit 311S as illustrated in C of FIG. 28, for example, may be adopted.

Alternatively, a configuration in which twelve recessed portions 313 with a small size are arranged above the first photoelectric conversion unit 311L and one recessed portion 313 with a large size is arranged above the second photoelectric conversion unit 311S as illustrated in D of FIG. 28, for example, may be adopted.

Alternatively, a configuration in which twelve recessed portions 313 with a small size are arranged above the first photoelectric conversion unit 311L and no recessed portions 313 are arranged above the second photoelectric conversion unit 311S as illustrated in E of FIG. 28, for example, may be adopted.

Alternatively, no recessed portions 313 are arranged above the first photoelectric conversion unit 311L and four recessed portions 313 with a small size are arranged above the second photoelectric conversion unit 311S as illustrated in F of FIG. 28, for example, may be adopted.

As described above, the unit pixel 21 according to the second embodiment can have a configuration in which one recessed portion 313 or a plurality of recessed portions 313 are provided in at least one of the first photoelectric conversion unit 311L and the second photoelectric conversion unit 311S. A configuration in which no recessed portions 313 are provided in one of the first photoelectric conversion unit 311L and the second photoelectric conversion unit 311S may be adopted.

Note that it is needless to say that combinations of numbers and arrangements of the recessed portions 313 other than those illustrated in A to F of FIG. 28 may be employed. For example, the size of each recessed portion 313 may be further reduced, and the number of recessed portions 313 to be arranged above the first photoelectric conversion unit 311L may be increased to be greater than twelve, or the number of recessed portions 313 to be arranged above the second photoelectric conversion unit 311S may be increased to be greater than four.

### 5.5 Third Configuration Example in Second Embodiment

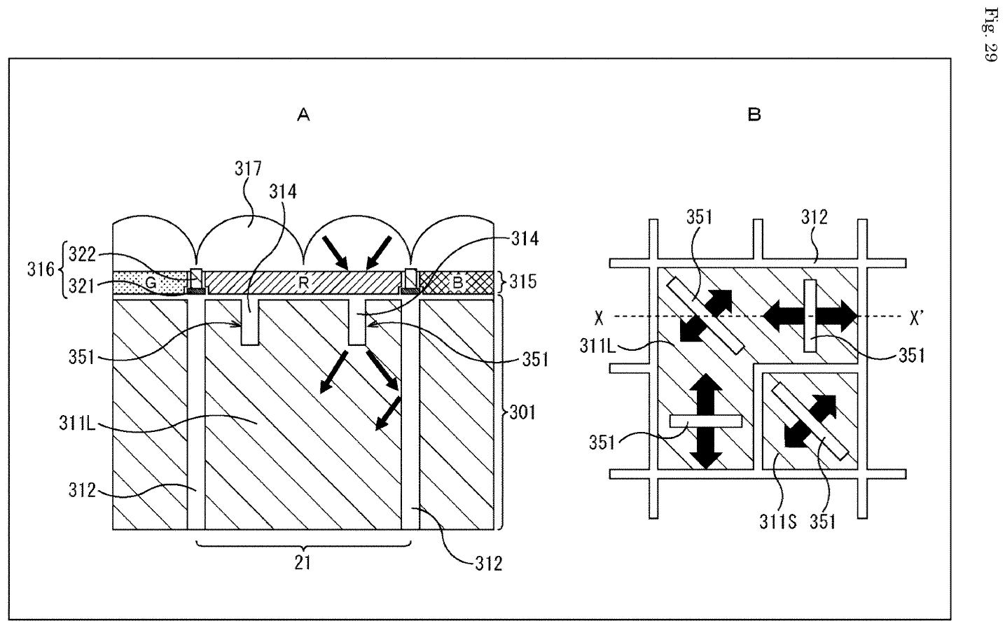

In FIG. 29, A is a sectional view illustrating a third configuration example of the unit pixels 21 according to the second embodiment of the present disclosure and illustrates a sectional view along the line X-X′ in B of FIG. 29. In FIG. 29, B is a plan view of each unit pixel 21 in A of FIG. 29 at a predetermined depth position.

The unit pixels 21 according to the third configuration example in the second embodiment illustrated in FIG. 29 is different in that the recessed portions 313 in the first configuration example are replaced with recessed portions 351, and the other points are the same as those in the first configuration example.

The recessed portions 313 in the first configuration example are formed of the inverted pyramid structures with respect to the light receiving surface of the semiconductor substrate 301. On the contrary, the recessed portions 351 in the third configuration example are formed of trench structures obtained by digging the semiconductor substrate 301 with a specific width up to a predetermined depth.

Four recessed portions 351 formed of the trench structures are arranged in a 2×2 layout in each unit pixel 21, three recessed portions 351 are arranged in the first photoelectric conversion unit 311L, and one recessed portion 351 is arranged in the second photoelectric conversion unit 311S as illustrated in the plan view in B of FIG. 29. One recessed portion 351 is formed into a rectangular shape that is thin and long in the horizontal direction, the vertical direction, or an oblique direction and scatters light in a direction perpendicular to the longitudinal direction of the rectangular shape as illustrated by the thick black arrows. The recessed portions 351 formed of the trench structures can enhance a scattering effect as compared with the recessed portions 313 in the first configuration example formed of the inverted pyramid structures and can improve light receiving sensitivity. On the other hand, there is a concern of an increase in leaking of light to adjacent unit pixels 21.

### 5.6 Modification Examples of Recessed Portion

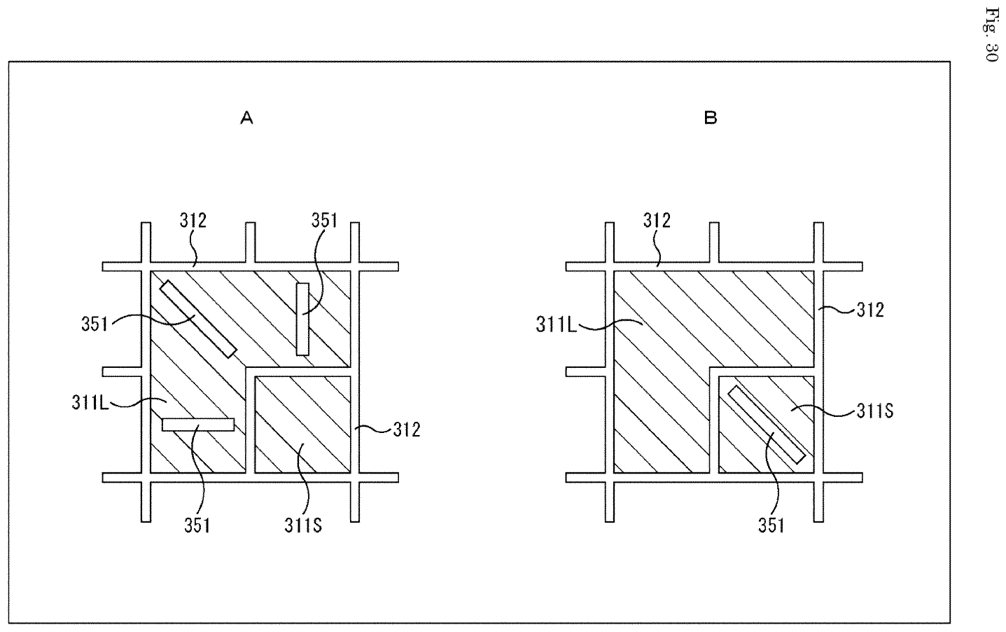

FIG. 30 is a plan view illustrating a modification example of the recessed portions 351 in the third configuration example.

It is possible to employ a configuration in which three recessed portions 351 are arranged above the first photoelectric conversion unit 311L and no recessed portions 351 are arranged above the second photoelectric conversion unit 311S as illustrated in A of FIG. 30 or a configuration in which no recessed portions 351 are arranged above the first photoelectric conversion unit 311L and one recessed portion 351 is arranged above the second photoelectric conversion unit 311S as illustrated in B of FIG. 30 also for the recessed portions 351 of the trench structures similarly to the modification examples of the recessed portions 313 of the inverted pyramid structure explained in FIG. 28. Moreover, the number and the shape of the recessed portions 351 to be arranged above at least one of the first photoelectric conversion unit 311L and the second photoelectric conversion unit 311S may be changed.

It is possible to suppress color mixing between the pixels by providing the low N walls 316 in the same layer as the color filter 315 also in the unit pixels 21 according to the third configuration example. It is thus possible to suppress colored flare. Since the low N walls 316 configured by laminating the low refractive index resin film 322 on the inter-pixel light shielding film 321 reduces a metal absorption loss, it is possible to improve light receiving sensitivity. Moreover, it is possible to increase the optical path length by a light scattering effect and to improve light receiving sensitivity by providing the recessed portions 351 on the side of the light receiving surface of the semiconductor substrate 301.

### 5.7 Fourth Configuration Example in Second Embodiment

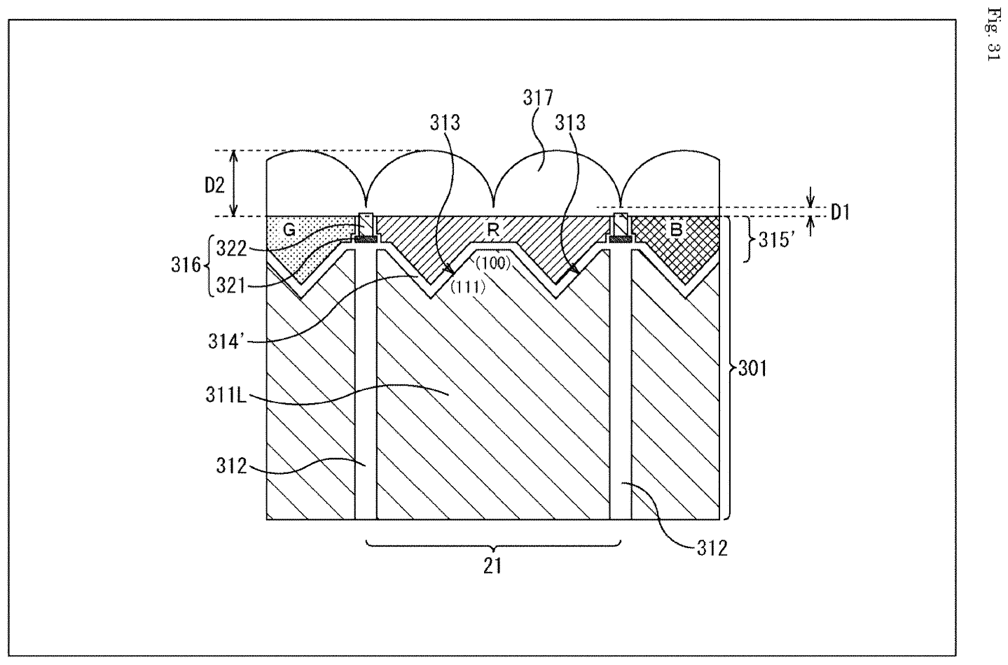

FIG. 31 is a sectional view illustrating a fourth configuration example of the unit pixels 21 according to the second embodiment of the present disclosure.

In FIG. 31, parts corresponding to those in the first configuration example illustrated in FIG. 22 are denoted by the same reference signs, and description will be given by focusing on parts different from those in the first configuration example.

In the first configuration example illustrated in FIG. 22, the upper portions of the (111) planes of the recessed portions 313 formed in the light receiving surface of the semiconductor substrate 301 are formed to be flat with an insulating film 314 that is the same material as that of the element separation units 312, and the color filters 315 or the low N walls 316 are formed on the flat insulating film 314.

On the contrary, color filters 315′ are formed on the upper portions of the (111) planes of the recessed portions 313 formed in the light receiving surface of the semiconductor substrate 301 via an insulating film 314′ with a predetermined film thickness in the fourth configuration example in FIG. 31. In other words, lower surfaces of the color filters 315′ are not flat, and the color filters 315′ are embedded up to the depressions of the recessed portions 313. In this manner, it is possible to lower the positions of the upper surfaces of the color filters 315′ as compared with the positions of the upper surfaces of the color filters 315 in the first configuration example. It is possible to form a thickness D1 from the upper surfaces of the color filters 315′ to the lowermost portion (depressions) of the hemispherical surface of the on-chip lenses 317 to be thinner than that in the first configuration example by lowering the position of the upper surfaces of the color filters 315′. It is possible to form the thickness D1 up to the lowermost portions of the hemispherical surfaces of the on-chip lenses 317 to be thin and to thereby form a total thickness D2 of the on-chip lenses 317 to be thin.

Since the thickness D1 up to the lowermost portions of the hemispherical surfaces of the on-chip lenses 317 corresponds to a path through which obliquely incident light at a high angle passes, it is possible to further suppress crosstalk between the unit pixels and inter-pixel crosstalk between the large pixels and the small pixels as the thickness D1 can be formed to be thinner.

It is possible to suppress color mixing between the pixels by providing the low N walls 316 in the same layer as the color filters 315′ also in the unit pixels 21 according to the fourth configuration example. It is thus possible to suppress colored flare. Since the low N walls 316 configured by laminating the low refractive index resin film 322 on the inter-pixel light shielding film 321 reduces a metal absorption loss, it is possible to improve light receiving sensitivity. Moreover, it is possible to increase the optical path length by a light scattering effect and to improve light receiving sensitivity by providing the recessed portions 313 on the side of the light receiving surface of the semiconductor substrate 301. It is possible to form the on-chip lenses 317 to have a thin total thickness D2 by embedding the color filters 315′ in depressions of the recessed portions 313 and to suppress crosstalk between the pixels.

### 5.8 Summary of Second Embodiment

The unit pixel 21 according to the second embodiment includes the first photoelectric conversion unit 311L and the second photoelectric conversion unit 311S that are formed in the semiconductor substrate 301 and have different areas of photoelectric conversion regions, the element separation units 312 that penetrate through the semiconductor substrate 301 and separate the first photoelectric conversion unit 311L and the second photoelectric conversion unit 311S, the color filters 315 (or 315′) provided on the side of incident light relative to the semiconductor substrate 301, the low N walls 316 that are formed in the same layer as the color filter 315 and have a lower refractive index than the color filters 315, the recessed portions 313 (or the recessed portions 351) provided on the side of the light receiving surface of the semiconductor substrate 301, and the on-chip lenses 317 that collect the incident light on the photoelectric conversion units 311.

According to the unit pixel 21 of the second embodiment, it is possible to reflect incident light or stray light at a high angle that is about to pass between the unit pixels 21 or between the large pixel and the small pixel and to suppress color mixing between the pixels by providing the low N walls 316 in the same layer as the color filter 315. It is thus possible to suppress colored flare. Moreover, the low N walls 316 are configured by laminating the low refractive index resin film 322 on the inter-pixel light shielding film 321 and reduce a metal absorption loss due to the inter-pixel light shielding film 321 that is a metal film. It is thus possible to improve light receiving sensitivity.

Furthermore, according to the unit pixel 21 of the second embodiment, it is possible to increase the optical path length by a light scattering effect and to improve light receiving sensitivity by providing the recessed portions 313 or 351 on the side of the light receiving surface of the semiconductor substrate 301.

### 6. Third Embodiment of Unit Pixels

### 6.1 First Configuration Example in Third Embodiment

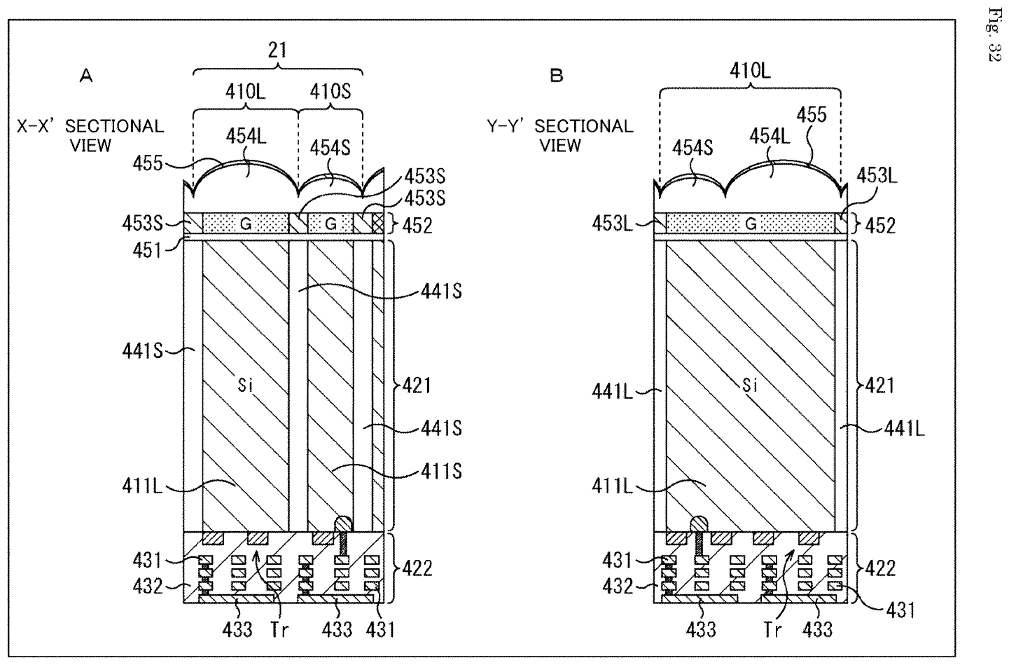

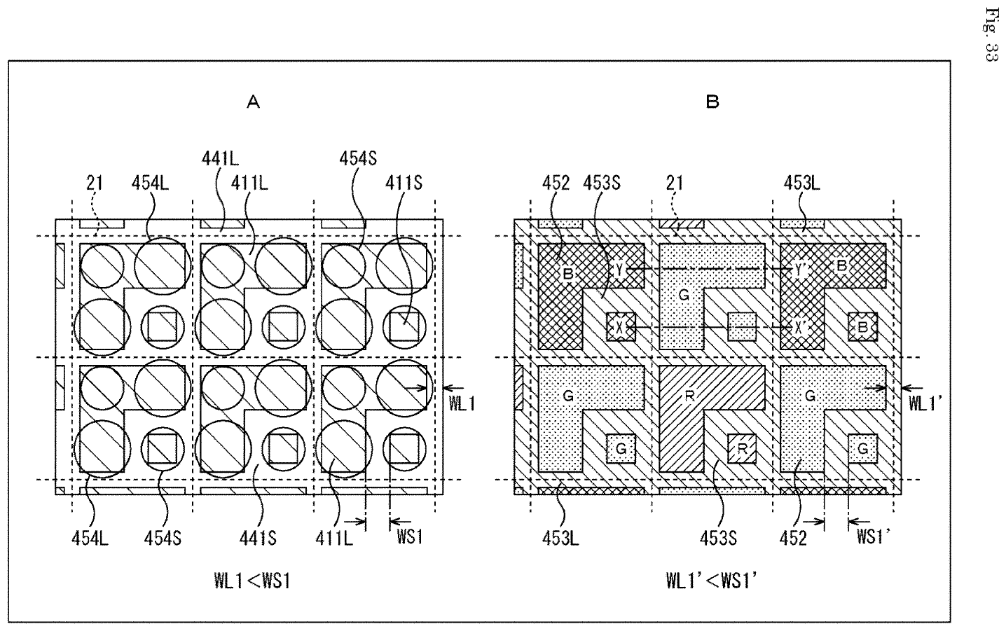

FIG. 32 is a sectional view illustrating a first configuration example of unit pixels 21 according to a third embodiment of the present disclosure. In FIG. 32, A illustrates a sectional view along the line X-X′ in FIG. 33, and B of FIG. 32 illustrates a sectional view along the line Y-Y′ in FIG. 33. In FIG. 33, A and B are plan views of the unit pixels 21 in FIG. 32 at a predetermined depth position.

In the third embodiment, the second layout example illustrated in FIG. 3 is employed as a layout of the unit pixels 21. The layout illustrated in B of FIG. 4 is employed as a layout of the on-chip lenses. Although reference signs that are different from those in the aforementioned first and second embodiments will be applied in the third embodiment, parts corresponding to those in the first or second embodiment will be briefly described.

The unit pixels 21 according to the third embodiment are the same as those in the aforementioned second embodiment in that low N walls that are light shielding walls made of a low refractive index material are included in the same layer as color filters. On the other hand, the unit pixels 21 according to the third embodiment are different from those in the aforementioned second embodiment in that recessed portions are not provided in a light receiving surface of a semiconductor substrate. The following provides a specific description.

Each unit pixel 21 according to the third embodiment includes a large pixel 410L including a first photoelectric conversion unit 411L with high sensitivity formed into an L shape and a small pixel 410S including a second photoelectric conversion unit 411S with low sensitivity formed into a quadrangular shape. In a case where the first photoelectric conversion unit 411L and the second photoelectric conversion unit 411S are not particularly distinguished, the first photoelectric conversion unit 411L and the second photoelectric conversion unit 411S will be simply referred to as photoelectric conversion units 411.

The unit pixel 21 according to the third embodiment includes a semiconductor substrate 421 and a wiring layer 422 formed on the side of a front surface thereof (the lower side in the drawing).

The semiconductor substrate 421 is configured of a silicon substrate using silicon (Si), for example, as a semiconductor. The thickness of the semiconductor substrate 421 is appropriately set in accordance with an expected wavelength region of incident light. For example, the thickness of the semiconductor substrate 421 is about 2 μm to 6 μm if the expected wavelength region is only a visible light region, and the thickness is about 3 μm to 15 μm in a case where a near-infrared region is also detected. It is a matter of course that the thickness of the semiconductor substrate 421 is not limited only to the range.

The first photoelectric conversion unit 411L is formed in the region of a large pixel 400L in the semiconductor substrate 421, and the second photoelectric conversion unit 411S is formed in the region of the small pixel 410S. The semiconductor substrate 421 is configured of, for example, a P-type (first conductivity type) semiconductor region. The photoelectric conversion unit 411 is configured of an PN junction-type photodiode with an N-type (second conductivity type) semiconductor region formed therein in the region of the P-type semiconductor region in the semiconductor substrate 421. The vicinities of the interfaces of both the front and rear surfaces of the semiconductor substrate 421 are P-type semiconductor regions that also serve as hole charge accumulation regions to reduce a dark current.

In the semiconductor substrate 421, element separation units 441 that separate the photoelectric conversion units 411 (photoelectric conversion elements) are formed in a region between the adjacent photoelectric conversion units 411. The element separation units 441 are configured of element separation units 441S that separate the first photoelectric conversion unit 411L of the large pixel 410L and the second photoelectric conversion unit 411S of the small pixel 410S and element separation units 441L that separate the first photoelectric conversion units 411L of the large pixels 410L. In other words, the element separation units 441 are configured of the element separation units 441S in the periphery of the second photoelectric conversion unit 411S of the small pixel 410S and the other element separation units 441L at the pixel boundary portions of the unit pixels 21. As will be described later in detail, the element separation units 441S and the element separation units 441L are configured to have different widths (thicknesses) in the planar direction in the unit pixels 21 in the first configuration example.

The element separation units 441 are configured by embedding insulating films such as silicon oxide films (SiO₂) in trenches that penetrate through the semiconductor substrate 421. The element separation units 441 may be formed by embedding light shielding metal as described above in the first embodiment.

The wiring layer 422 includes a plurality of metal wirings 431 and an inter-layer insulating film 432. The metal wirings 431 in the plurality of layers inside the wiring layer 422 transmit an image signal generated by the unit pixel 21 and transmit a signal to be applied to the unit pixel 21. The metal wirings 431 can be configured of, for example, metal such as Al or Cu. A through-via that connects the upper and lower metal wirings 431 can be configured of, for example, metal such as W or Cu. For example, a silicon oxide film or the like can be used as the inter-layer insulating film 432.

Also, one or more pixel transistors Tr are formed at an interface between the semiconductor substrate 421 and the wiring layer 422. The pixel transistors Tr correspond to any of the first transfer transistor 53, the second transfer transistor 54, the third transfer transistor 55, the reset transistor 57, the amplification transistor 58, and the selection transistor 59 explained in FIG. 6. A junction electrode 433 is formed on the surface of the wiring layer 422 on the side opposite to the side of the semiconductor substrate 421 and is electrically connected to a junction electrode of a logic substrate, which is not illustrated, through metal junction such as Cu—Cu junction. It is possible to reduce the chip size by establishing junction with the logic substrate and vertically stacking various peripheral circuit functions.

In the drawings, an insulating film 451 configured of a silicon oxide film (SiO₂) or the like is formed on the side of the rear surface, which is the surface on the upper side, of the semiconductor substrate 421. Note that the insulating film 451 may be formed on a fixed charge film as in the first embodiment. For the insulating film 451, it is possible to use SiO₂ or a composite material (such as SiON or SiOC) containing SiO₂ as a main component similarly to the insulating film 182 in the first embodiment.

Color filters 452 are formed on the upper surface of the insulating film 451. The color filters 452 of a red (R) color, a green (G) color, or a blue (B) color, for example, are arranged in the Bayer layout for each unit pixel 21 as illustrated in B of FIG. 3. Low N walls 453 are formed above the element separation units 441 in the same layer as the color filters 315. The low N walls 453 are configured of a material with a lower refractive index than the color filters 315. It is possible to use a material similar to that of the low refractive index resin film 322 in the second embodiment, for example, as the material of the low N walls 453.

The low N walls 453 are configured of low N walls 453S that separate the first photoelectric conversion unit 411L of the large pixel 410L and the second photoelectric conversion unit 411S of the small pixel 410S and low N walls 453L that separate the first photoelectric conversion units 411L of the large pixels 410L similarly to the element separation units 441. In other words, the low N walls 453 are configured of the low N walls 453S in the periphery of the second photoelectric conversion unit 411S of the small pixel 410S and the other low N walls 453L at the pixel boundary portions of the unit pixels 21. As will be described later in detail, the low N walls 453S and the low N walls 453L are configured to have different widths (thicknesses) in the planar direction in the unit pixels 21 according to the first configuration example.

On-chip lenses 454 are formed above the color filters 452 and the low N walls 453. The on-chip lenses 454 include large on-chip lenses 454L and small on-chip lenses 454S. As a material of the on-chip lenses 454, it is possible to use a material that is similar to that of the on-chip lenses 187 in the first embodiment. Also, an anti-reflection film 455 using a material with a refractive index that is different from that of the on-chip lenses 454 is formed on the surfaces of the on-chip lenses 454.

In FIG. 33, A is a plan view illustrating an arrangement of the first photoelectric conversion units 411L and the second photoelectric conversion units 411S in the unit pixels 21 and an arrangement of the large on-chip lenses 454L and the small on-chip lenses 454S. In A of FIG. 33, the boundaries of the unit pixels 21 are illustrated by the dashed lines.

As illustrated in A of FIG. 33, each first photoelectric conversion unit 411L with a large area of photoelectric conversion region is formed into an L shape in each unit pixel 21, and each second photoelectric conversion unit 411S with a smaller area of photoelectric conversion region than the first photoelectric conversion unit 411L is formed into a quadrangular shape at the remaining corner portion in the unit pixel 21. In regard to the on-chip lenses 454, two large on-chip lenses 454L and one small on-chip lens 454S are arranged above the first photoelectric conversion unit 411L, and one small on-chip lens 454S is arranged above the second photoelectric conversion unit 411S.

Here, in comparison between a width WS1 of each element separation unit 441S that is formed in the periphery of the second photoelectric conversion unit 411S and separates the first photoelectric conversion unit 411L and the second photoelectric conversion unit 411S in the planar direction and a width WL1 of each element separation unit 441L that separates the adjacent first photoelectric conversion units 411L in the planar direction, the width WS1 of the element separation unit 441S is formed to be larger than the width WL1 of the element separation unit 441L (WL1<WS1). This enhances suppression of crosstalk from the large pixel 410L to the small pixel 410S in the semiconductor substrate 421.

In FIG. 33, B is a plan view of the color filters 452 and the low N walls 453. The boundaries of the unit pixels 21 are illustrated by the dashed line also in B of FIG. 33.

Similarly to the element separation units 441, in comparison between a width WS1′ of each low N wall 453S that is formed in the periphery of the second photoelectric conversion unit 411S and separates the first photoelectric conversion unit 411L and the second photoelectric conversion unit 411S in the planar direction and a width WL1′ of each low N wall 453L that separates the adjacent first photoelectric conversion units 411L in the planar direction in a plan view, the width WS1′ of the low N wall 453S is formed to be larger than the width WL1′ of the low N wall 453L (WL1′<WS1′) in regard to the low N walls 453 as well. This enhances suppression of crosstalk from the large pixel 410L to the small pixel 410S on the side of the incident surface relative to the semiconductor substrate 421.

The width WL1 of the element separation units 441L and the width WL1′ of the low N walls 453L may be the same (WL1=WL1′) or may be different from each other (WL1<WL1′ or WL1>WL1′). The width WS1 of the element separation units 441S in the planar direction and the width WS1′ of the low N walls 453S may be the same (WS1=WS1′) or may be different from each other (WS1<WS1′ or WS1>WS1′).

In the solid-state imaging device 1 including the unit pixels 21 according to the third embodiment configured as described is a solid-state imaging device of a back-illuminated type in which incident light is collected on the on-chip lens 410 formed on the rear surface side of the semiconductor substrate 421 and is subjected to photoelectric conversion by the photoelectric conversion unit 411. Each unit pixel 21 according to the third embodiment includes the large pixel 410L including the first photoelectric conversion unit 411L with a large area of photoelectric conversion region and the small pixel 410S including the second photoelectric conversion unit 411S with a smaller photoelectric conversion region than that of the first photoelectric conversion unit 411L and enables high-sensitivity imaging with the large pixel 410L and low-sensitivity imaging with the small pixel 410S.

The unit pixel 21 according to the first configuration example in the third embodiment includes the first photoelectric conversion unit 411L and the second photoelectric conversion unit 411S with different areas of photoelectric conversion regions formed in the semiconductor substrate 421, the element separation units 441 that penetrate through the semiconductor substrate 421 and separate the first photoelectric conversion unit 411L and the second photoelectric conversion unit 411S, the color filters 452 that are provided on the side of incident light relative to the semiconductor substrate 421, the low N walls 453 that are formed in the same layer in the color filters 452 and have a lower refractive index than the color filters 452, and the on-chip lenses 454 that collect the incident light on the photoelectric conversion units 411.

The element separation units 441 are formed such that the width WS1 of the element separation units 441S formed in the periphery of the second photoelectric conversion unit 411S is larger than the width WL1 of the element separation units 441L that separate the first photoelectric conversion units 411L (WL1<WS1), and suppression of crosstalk from the large pixel 410L to the small pixel 410S in the semiconductor substrate 421 is thereby enhanced.

Similarly, the low N walls 453 are formed such that the width WS1′ of the low N walls 453S formed in the periphery of the second photoelectric conversion unit 411S in the planar direction is larger than the width WL1′ of the low N walls 453L that separate the first photoelectric conversion units 411L in the planar direction (WL1′<WS1′), and suppression of crosstalk from the large pixel 410L to the small pixel 410S on the side further upward than the semiconductor substrate 421 is thereby enhanced.

Therefore, according to the unit pixels 21 of the first configuration example in the third embodiment, it is possible to suppress color mixing between the unit pixels 21 and to further enhance suppression of color mixing from the large pixels 410L to the small pixels 410S. It is thus possible to suppress colored flare and to reduce degradation of image quality of the small pixels 410S.

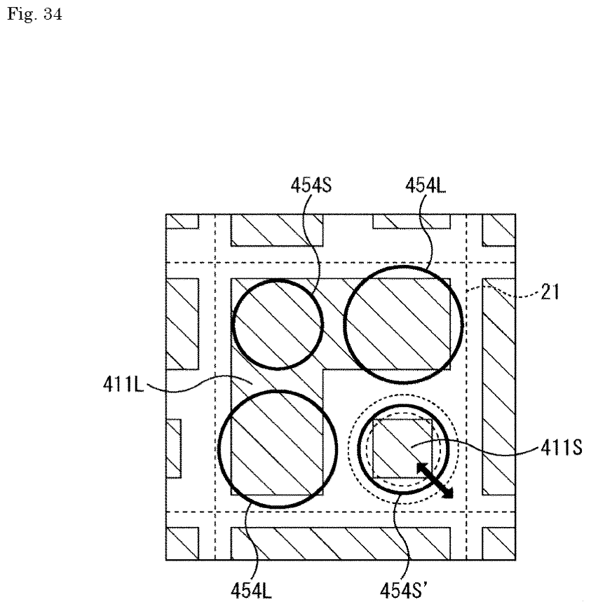

Note that although the sizes (diameters) of the small on-chip lenses 454S arranged above the first photoelectric conversion unit 411L and of the small on-chip lens 454S arranged above the second photoelectric conversion unit 411S are the same size in the aforementioned first configuration example, the small on-chip lens 454S arranged above the second photoelectric conversion unit 411S may be changed to a small on-chip lens 454S′ with a larger or smaller size than that of the small on-chip lenses 454S arranged above the first photoelectric conversion unit 411L as illustrated in FIG. 34. It is possible to adjust a sensitivity ratio between the large pixel 410L and the small pixel 410S by changing the sizes of the small on-chip lenses 454S′ above the second photoelectric conversion unit 411S.

### 6.2 Second Configuration Example in Third Embodiment

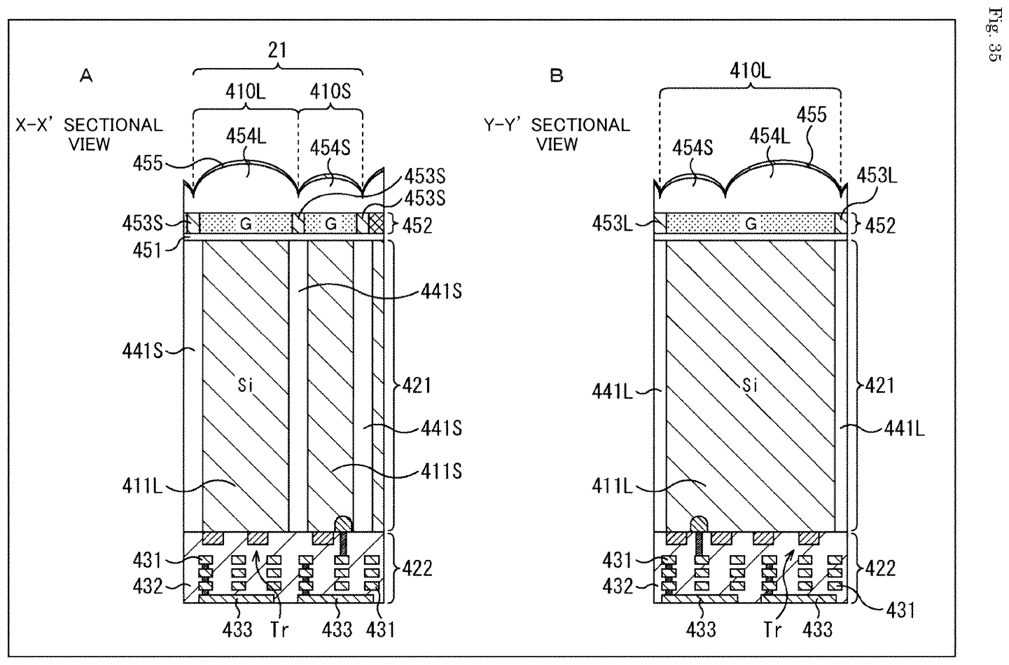

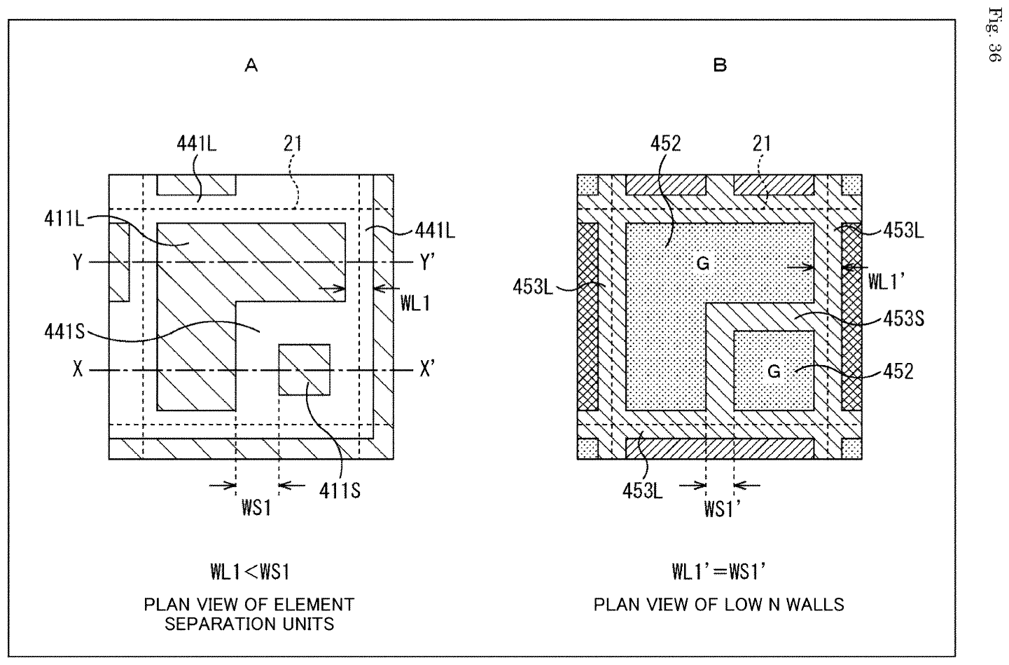

FIG. 35 is a sectional view illustrating a second configuration example of the unit pixels 21 according to the third embodiment of the present disclosure. In FIG. 35, A illustrates a sectional view along the line X-X′ in FIG. 36, and B of FIG. 35 illustrates a sectional view along the line Y-Y′ in FIG. 36. In FIG. 36, A and B are plan views of the unit pixels 21 in FIG. 35 at a predetermined depth position.

In FIGS. 35 and 36, parts corresponding to those in the first configuration example illustrated in FIGS. 32 and 33 are denoted by the same reference signs, and description will be given by focusing on parts different from those in the first configuration example.

The element separation units 441 in the unit pixels 21 according to the second configuration example are configured similarly to those in the first configuration example. In other words, the width WS1 of the element separation units 441S in the periphery of the second photoelectric conversion unit 411S is formed to be larger than the width WL1 of the element separation units 441L that separate the first photoelectric conversion units 411L (WL1<WS1) as illustrated in A of FIG. 36.

On the other hand, although the low N walls 453 are formed such that the width WS1′ of the low N walls 453S formed in the periphery of the second photoelectric conversion unit 411S is larger than the width WL1′ of the low N walls 453L that separate the first photoelectric conversion unit 411L (WL1′<WS1′) in the first configuration example, the low N walls 453 are formed such that the width WS1′ of the low N walls 453S and the width WL1′ of the low N walls 453L are the same (WL1′=WS1′) as illustrated in B of FIG. 36 in the second configuration example.

In other words, only the element separation units 441S that surround the second photoelectric conversion unit 411S are formed to be thick and the element separation units 441L, the low N walls 453L, and the low N walls 453S are formed to be thinner than the element separation units 441S as is known from the sectional view in FIG. 35 as well in the second configuration example.

Therefore, according to the unit pixels 21 of the second configuration example in the third embodiment, it is possible to suppress colored flare by enhancing suppression of crosstalk from the large pixels 410L to the small pixels 410S in the semiconductor substrate 421, and to reduce degradation of image quality of the small pixels 410S.

### 6.3 Third Configuration Example in Third Embodiment

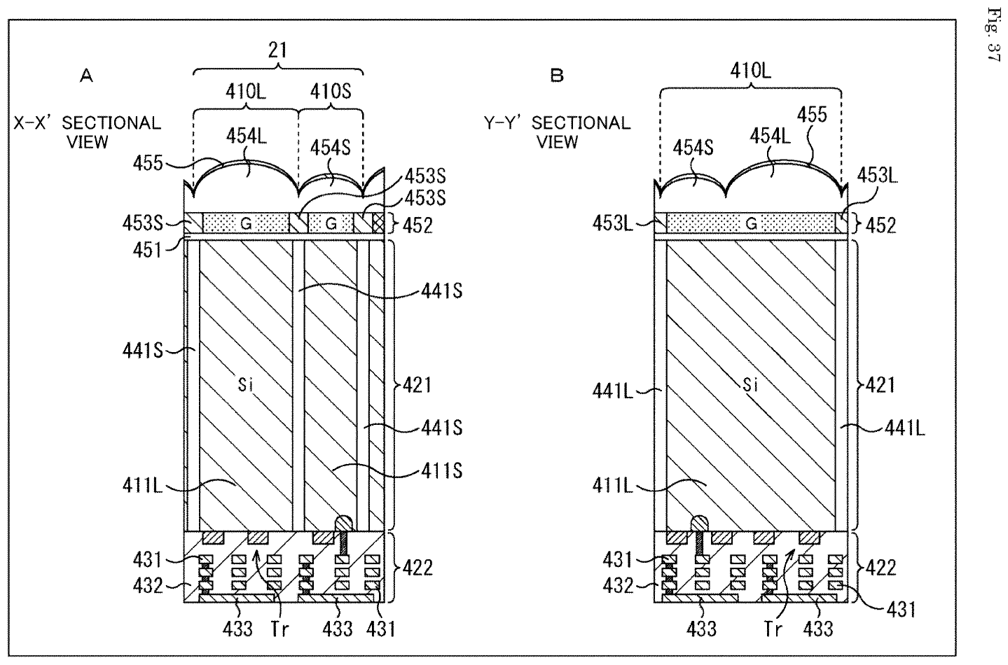

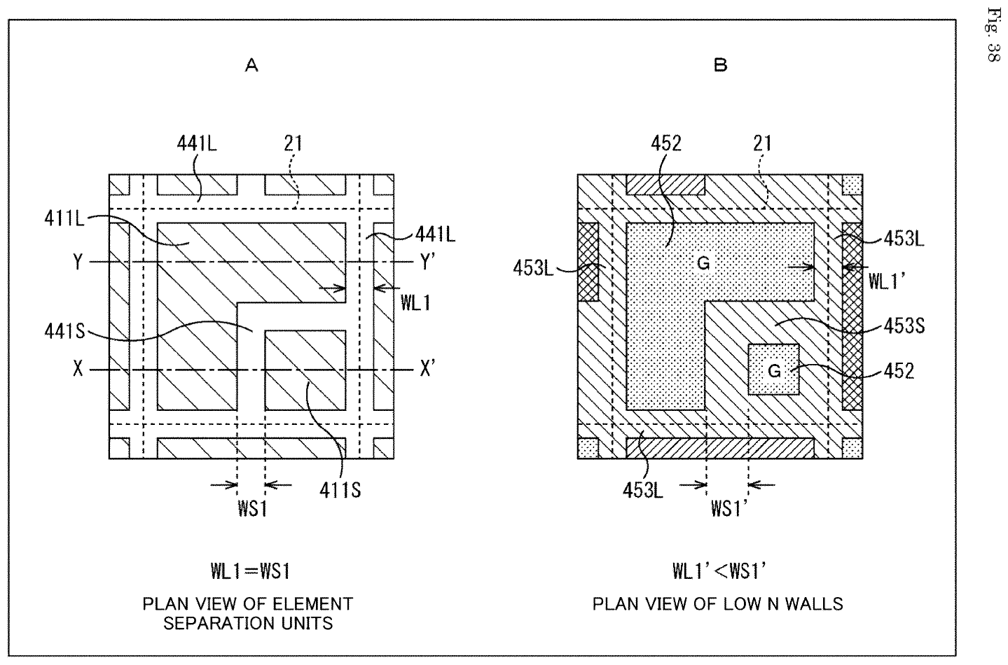

FIG. 37 is a sectional view illustrating a third configuration example of the unit pixels 21 according to the third embodiment of the present disclosure. In FIG. 37, A illustrates a sectional view along the line X-X′ in FIG. 38, and B of FIG. 37 illustrates a sectional view along the line Y-Y′ in FIG. 38. In FIG. 38, A and B are plan views of the unit pixels 21 in FIG. 37 at a predetermined depth position.

In FIGS. 37 and 38, parts corresponding to those in the first configuration example illustrated in FIGS. 32 and 33 are denoted by the same reference signs, and description will be given by focusing on parts different from those in the first configuration example.

In the unit pixels 21 according to the third configuration example, the low N walls 453 are configured similarly to those in the first configuration example. In other words, the width WS1′ of the low N walls 453S formed in the periphery of the second photoelectric conversion unit 411S is formed to be larger than the width WL1′ of the low N walls 453L that separate the first photoelectric conversion units 411L (WL1′<WS1′) as illustrated in B of FIG. 38.

On the other hand, although the element separation units 441 are formed such that the width WS1 of the element separation units 441S in the periphery of the second photoelectric conversion unit 411S is larger than the width WL1 of the element separation units 441L that separate the first photoelectric conversion units 411L (WL1<WS1) in the first configuration example, the width WS1 of the element separation units 441S and the width WL1 of the element separation units 441L are formed to be the same (WL1=WS1) as illustrated in A of FIG. 38 in the third configuration example.

In other words, only the low N walls 453S are formed to be thick, and the element separation units 441L, the element separation units 441S, and the low N walls 453L are formed to be thinner than the low N walls 453S as is known from the sectional view in FIG. 37 in the third configuration example.

Therefore, according to the unit pixels 21 of the third configuration example in the third embodiment, it is possible to suppress colored flare by enhancing suppression of crosstalk from the large pixels 410L to the small pixels 410S on the side further upward than the semiconductor substrate 421 and to reduce degradation of image quality of the small pixels 410S.

### 6.4 Fourth Configuration Example in Third Embodiment

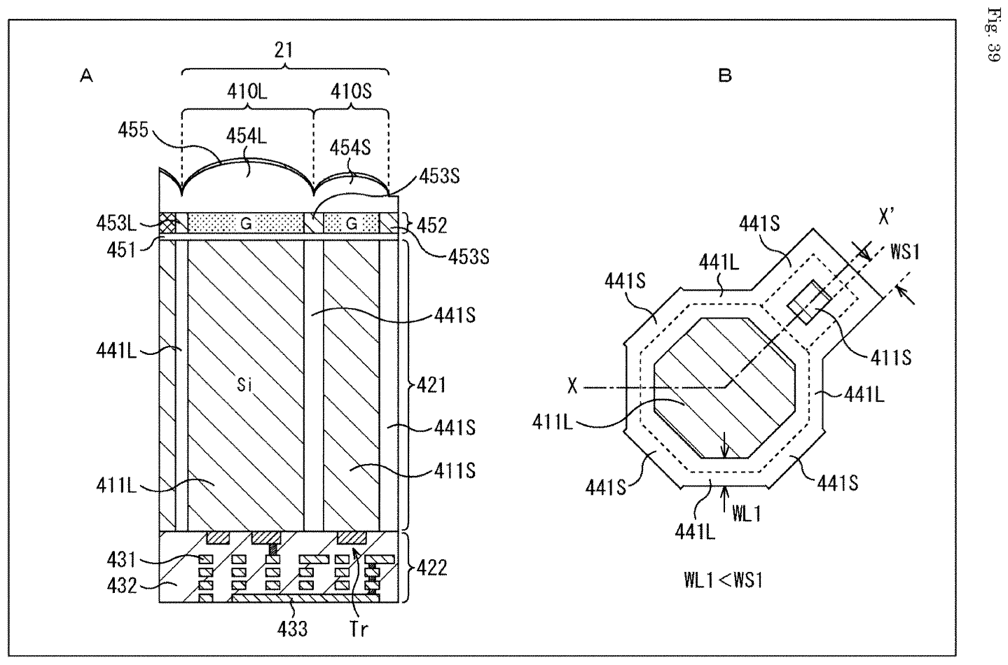

FIG. 39 is a diagram illustrating a fourth configuration example of the unit pixels 21 according to the third embodiment of the present disclosure. In FIG. 39, A is a sectional view along the line X-X′ in B of FIG. 39, and B of FIG. 39 is a plan view of the unit pixels 21 in A of FIG. 39 at a predetermined depth position.

In FIG. 39, parts corresponding to those in the first configuration example illustrated in FIGS. 32 and 33 are denoted by the same reference signs, and description will be given by focusing on parts different from those in the first configuration example.

The fourth configuration example in FIG. 39 is different from the first configuration example illustrated in FIGS. 32 and 33 in that the first layout example illustrated in FIG. 2 is employed as a layout of the unit pixels 21.

On the other hand, the widths of the element separation units 441 and the low N walls 453 in the periphery of the photoelectric conversion units 411 in the planar direction are the same as those in the first configuration example illustrated in FIGS. 32 and 33.

In FIG. 39, B illustrates a plan view of the photoelectric conversion units 411 and the element separation units 441, and the element separation units 441 are formed such that the width WS1 of the element separation units 441S formed in the periphery of the second photoelectric conversion unit 411S is larger than the width WL1 of the element separation units 441L that separate the first photoelectric conversion units 411L (WL1<WS1) as illustrated in B of FIG. 39. This enhances suppression of crosstalk from the large pixel 410L to the small pixel 410S in the semiconductor substrate 421.

Similarly, the low N walls 453 are also formed such that the width WS1′ of the low N walls 453S formed in the periphery of the second photoelectric conversion units 411S is larger than the width WL1′ of the low N walls 453L that separate the first photoelectric conversion units 411L (WL1′<WS1′) although illustration is omitted. This enhances suppression of crosstalk from the large pixels 410L to the small pixels 410S on the side further upward than the semiconductor substrate 421.

Therefore, according to the unit pixels 21 of the fourth configuration example in the third embodiment, it is possible to suppress color mixing between the unit pixels 21 and to further enhance suppression of color mixing from the large pixels 410L to the small pixels 410S. It is thus possible to suppress colored flare and to reduce degradation of image quality of the small pixels 410S.

### 6.5 Fifth Configuration Example in Third Embodiment

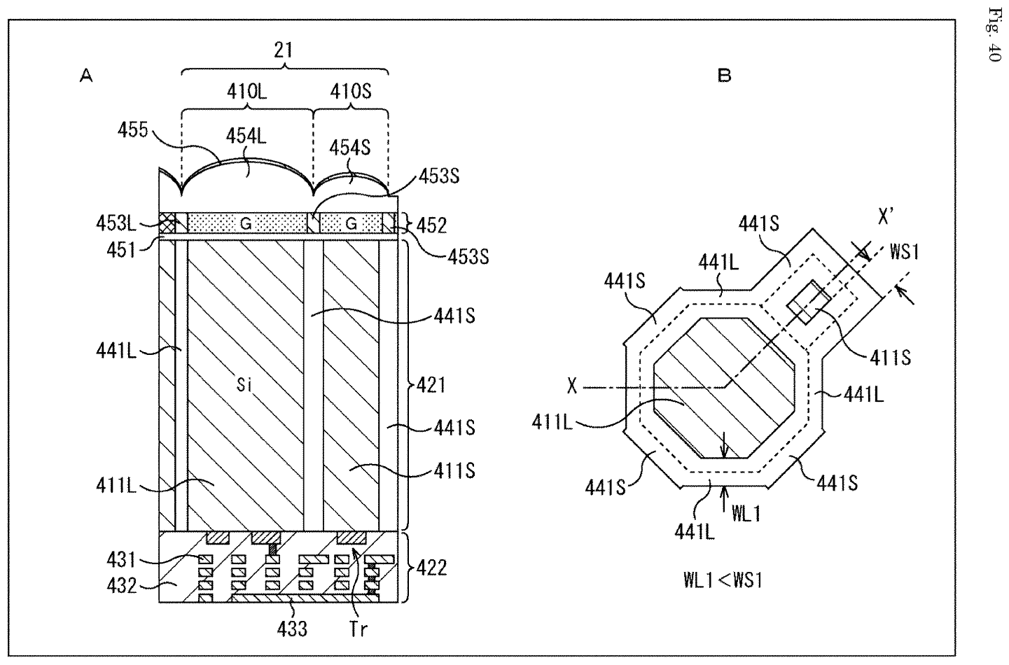

FIG. 40 is a diagram illustrating a fifth configuration example of the unit pixels 21 according to the third embodiment of the present disclosure. In FIG. 40, A is a sectional view along the line X-X′ in B of FIG. 40, and B of FIG. 40 is a plan view of the unit pixels 21 in A of FIG. 40 at a predetermined depth position.

In FIG. 40, parts corresponding to those in the first to fourth configuration examples are denoted by the same reference signs, and description will be given by focusing on different parts.

The fifth configuration example in FIG. 40 is the same as the third configuration example illustrated in FIG. 39 and is different from the first configuration example illustrated in FIGS. 32 and 33 in that the first layout example illustrated in FIG. 2 is employed as a layout of the unit pixels 21.

On the other hand, the widths of the element separation units 441 and the low N walls 453 in the periphery of the photoelectric conversion units 411 in the planar direction are the same as those in the second configuration example illustrated in FIGS. 35 and 36.

In FIG. 40, B illustrates a plan view of the photoelectric conversion units 411 and the element separation units 441, and the element separation units 441 are formed such that the width WS1 of the element separation units 441S formed in the periphery of the second photoelectric conversion unit 411S is larger than the width WL1 of the element separation units 441L that separate the first photoelectric conversion units 411L (WL1<WS1) as illustrated in B of FIG. 40. This enhances suppression of crosstalk from the large pixel 410L to the small pixel 410S in the semiconductor substrate 421.

The low N walls 453 are formed such that the width WS1′ of the low N walls 453S formed in the periphery of the second photoelectric conversion units 411S and the width WL1′ of the low N walls 453L that separate the first photoelectric conversion units 411L are the same width (WL1′=WS1′) although illustration is omitted.

In other words, only the element separation units 441S are formed to be thick, and the element separation units 441L, the low N walls 453L, and the low N walls 453S are formed to be thinner than the element separation units 441S.

Therefore, according to the unit pixels 21 of the fifth configuration example in the third embodiment, it is possible to suppress colored flare by enhancing suppression of crosstalk from the large pixels 410L to the small pixels 410S in the semiconductor substrate 421 and to reduce degradation of image quality of the small pixels 410S.

### 6.6 Sixth Configuration Example in Third Embodiment

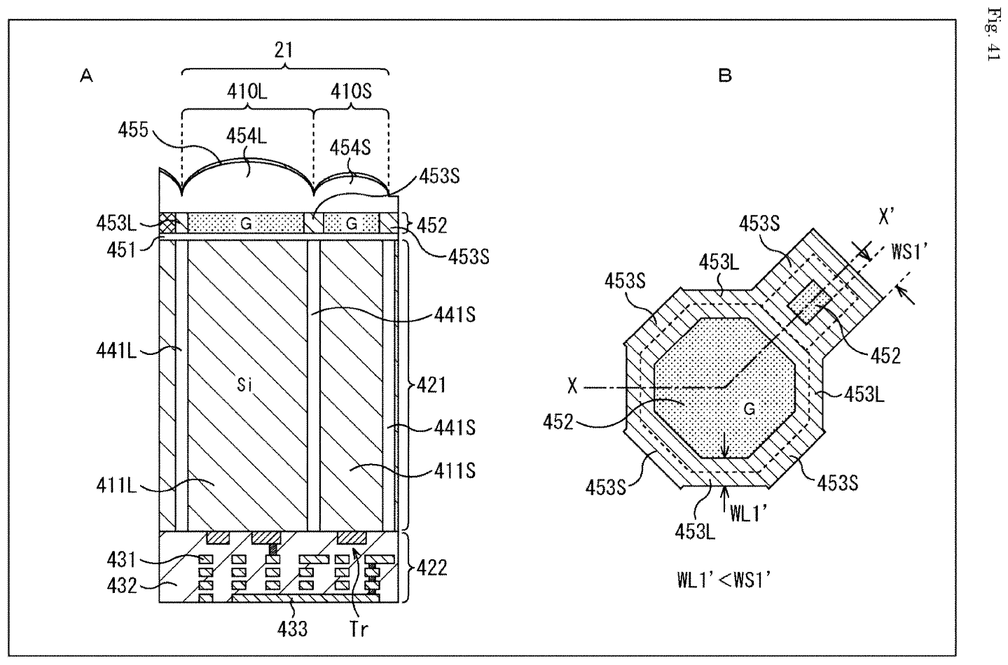

FIG. 41 is a diagram illustrating a sixth configuration example of the unit pixels 21 according to the third embodiment of the present disclosure. In FIG. 41, A is a sectional view along the line X-X′ in B of FIG. 41, and B of FIG. 41 is a plan view of the unit pixels 21 in A of FIG. 41 at a predetermined depth position.

In FIG. 41, parts corresponding to those in the first to fifth configuration examples are denoted by the same reference signs, and description will be given by focusing on different parts.

The sixth configuration example in FIG. 41 is the same as the third configuration example illustrated in FIG. 39 and is different from the first configuration example illustrated in FIGS. 32 and 33 in that the first layout example illustrated in FIG. 2 is employed as a layout of the unit pixels 21.

On the other hand, the widths of the element separation units 441 and the low N walls 453 in the periphery of the photoelectric conversion units 411 in the planar direction are the same as those in the third configuration example illustrated in FIGS. 37 and 38.

In FIG. 41, B illustrates a plan view of the color filters 452 and the low N walls 453, and the low N walls 453 are formed such that the width WS1′ of the low N walls 453S formed in the periphery of the second photoelectric conversion units 411S is larger than the width WL1′ of the low N walls 453L that separate the first photoelectric conversion units 411L (WL1′<WS1′) as illustrated in B of FIG. 41.

The element separation units 441 are formed such that the width WS1 of the element separation units 441S in the periphery of the second photoelectric conversion units 411S and the width WL1 of the element separation units 441L that separate the first photoelectric conversion units 411L are the same widths (WL1=WS1) although illustration is omitted.

In other words, only the low N walls 453S are formed to be thick, and the element separation units 441L, the element separation units 441S, and the low N walls 453L are formed to be thinner than the low N walls 453S.

Therefore, according to the unit pixels 21 of the sixth configuration example in the third embodiment, it is possible to suppress colored flare by enhancing suppression of crosstalk from the large pixels 410L to the small pixels 410S on the side further upward than the semiconductor substrate 421 and to reduce degradation of image quality of the small pixels 410S.

### 6.7 Seventh Configuration Example in Third Embodiment

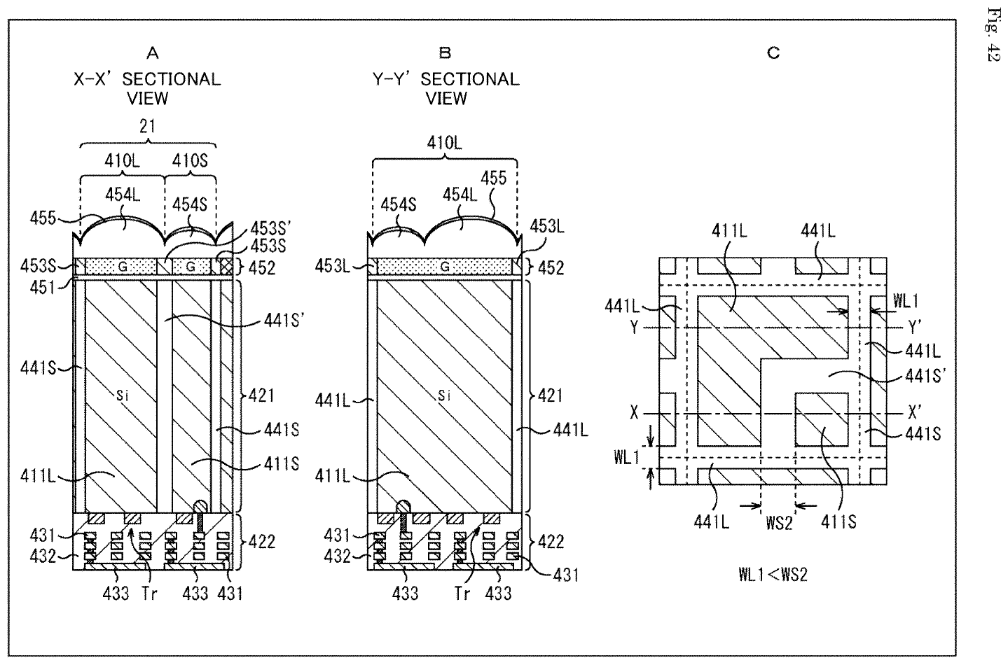

FIG. 42 is a diagram illustrating a seventh configuration example of the unit pixels 21 according to the third embodiment of the present disclosure. In FIG. 42, A is a sectional view along the line X-X′ in C of FIG. 42, and B of FIG. 42 is a sectional view along the line YY′ in C of FIG. 42, and C of FIG. 42 is a plan view of the unit pixels 21 in A and B of FIG. 42 at a predetermined depth position.

In FIG. 42, parts corresponding to those in the first configuration example illustrated in FIGS. 32 and 33 are denoted by the same reference signs, and description will be given by focusing on different parts.

In the first configuration example illustrated in FIGS. 32 and 33, all the widths of both the element separation units 441 and the low N walls 453 surrounding the second photoelectric conversion unit 411S of the small pixel 410S are configured to be larger than the other widths at the pixel boundary portions of the unit pixels 21.

On the contrary, only the widths thereof at the boundary part that separates the first photoelectric conversion unit 411L and the second photoelectric conversion unit 411S in a region located further inward than the pixel boundaries between the unit pixels 21 are formed to be large instead of all the widths in the periphery of the second photoelectric conversion unit 411S as illustrated in C of FIG. 42 in the seventh configuration example.

More specifically, a width WS2 of the element separation unit 441S′ at the boundary part that separate the first photoelectric conversion unit 411L and the second photoelectric conversion unit 411S is formed to be larger than the width WL1 of the element separation units 441L at the pixel boundary portions of the unit pixels 21 (WS2<WL1). This enhances suppression of crosstalk from the large pixel 410L to the small pixel 410S in the semiconductor substrate 421.

Similarly, the low N walls 453 are also formed such that a width WS2′ of the low N wall 453S′ on the boundary part that separates the first photoelectric conversion unit 411L and the second photoelectric conversion unit 411S is larger than the width WL1′ thereof above the element separation units 441L at the pixel boundary portions of the unit pixels 21 (WL1′<WS2′). This enhances suppression of crosstalk from the large pixel 410L to the small pixel 410S on the side of the incident surface relative to the semiconductor substrate 421.

In this manner, a width of at least a part of the periphery instead of the entire periphery of the second photoelectric conversion unit 411S of the small pixel 410S may be formed to be larger than the other parts. The other configurations of the seventh configuration example are the same as those of the first configuration example illustrated in FIGS. 32 and 33.

Therefore, according to the unit pixels 21 of the seventh configuration example in the third embodiment, it is possible to curb color mixing between the unit pixels 21 and to further enhance suppression of color mixing from the large pixels 410L to the small pixels 410S. It is thus possible to suppress colored flare and to reduce degradation of image quality of the small pixels 410S.

### 6.8 Eighth Configuration Example in Third Embodiment

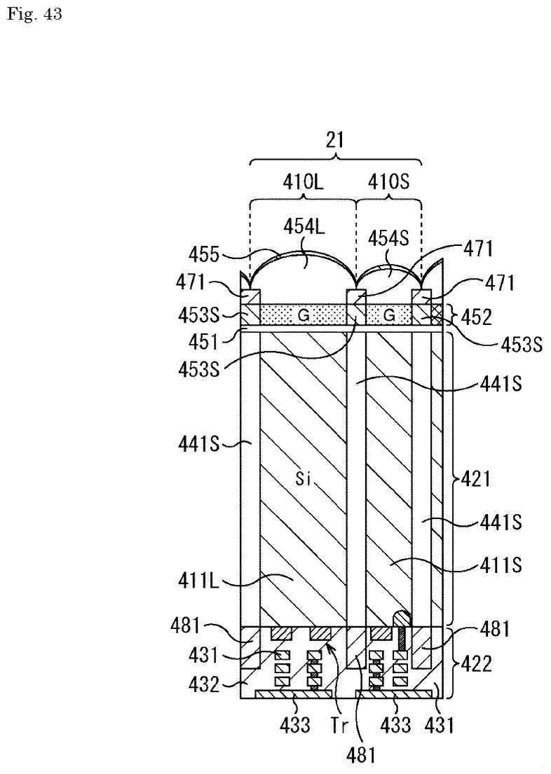

FIG. 43 is a sectional view illustrating an eighth configuration example of the unit pixels 21 according to the third embodiment of the present disclosure and illustrates a sectional view of a part corresponding to the line X-X′ in FIG. 33.

In the aforementioned first configuration example to seventh configuration example, the example in which the element separation units 441 that separate the photoelectric conversion units 411 and the low N walls 453 that separate the color filters 452 are formed such that a width of at least a part of the periphery of the second photoelectric conversion unit 411S of the small pixel 410S is larger than the other widths has been described.

Incidentally, there may be a case where separation units that separate the unit pixels or separate large and small pixels are provided in the on-chip lenses 454 and the wiring layer 422, for example, in addition to the element separation units 441 and the low N walls 453.

For example, each unit pixel 21 according to the eighth configuration example illustrated in FIG. 43 is configured by adding lens separation units 471 that separate the on-chip lenses 454 and wiring layer separation units 481 that separate a part of the wiring layer 422 to the configuration of the unit pixel 21 illustrated in A of FIG. 32. Such lens separation units 471 and wiring layer separation units 481 can also employ the configuration in which widths of at least a part of the periphery of the second photoelectric conversion unit 411S of the small pixel 410S is formed to be larger than the other widths similarly to the configurations of the element separation units 441 or the low N walls 453 in any of the aforementioned first configuration example to seventh configuration example. For the lens separation units 471, a light transmission material that is different from that of the on-chip lenses 454 and has a lower refractive index than that of the on-chip lenses 454 can be employed. As a material for the wiring layer separation units 481, a material with a lower refractive index than the silicon oxide film (SiO₂) which is the material of the inter-layer insulating film 432 or a material such as Al, Cu, or W that is similar to that of the metal wirings 431, for example, can be used.

In the eighth configuration example illustrated in FIG. 43, configurations other than the lens separation units 471 and the wiring layer separation units 481 are similar to those in the first configuration example illustrated in FIG. 32, and description thereof will thus be omitted.

It is possible to suppress color mixing between the unit pixels 21 and to further enhance suppression of color mixing from the large pixels 410L to the small pixels 410S also in the unit pixels 21 according to the eighth configuration example in the third embodiment described above. It is thus possible to suppress colored flare and to reduce degradation of image quality of the small pixels 410S.

### 6.9 Summary of Third Embodiment

Each unit pixel 21 according to the third embodiment includes the first photoelectric conversion unit 411L and the second photoelectric conversion unit 411S with different areas of photoelectric conversion regions formed in the semiconductor substrate 421, the element separation units 441 that penetrate through the semiconductor substrate 421 and separate the first photoelectric conversion unit 411L and the second photoelectric conversion unit 411S, the color filters 452 that are provided on the side of the incident light relative to the semiconductor substrate 421, the low N walls 453 that are formed in the same layer as the color filters 452 and have lower refractive indexes than the color filters 452, and the on-chip lenses 454 that collect the incident light on the photoelectric conversion units 411.

According to the unit pixels 21 of the third embodiment, it is possible to reflect incident light or stray light at a high angle that is about to pass between the unit pixels 21 or between the large pixels 410L and the small pixels 410S and to suppress color mixing between the unit pixels 21 by providing the low N walls 453 in the same layer as the color filter 452. It is thus possible to suppress colored flare.

Furthermore, according to the unit pixels 21 in the third embodiment, at least one of the element separation units 441 that separate the photoelectric conversion units 411, the low N walls 453 that separate the color filters 452, the lens separation units 471 that separate the on-chip lenses 454, and the wiring layer separation units 481 that separate a part of the wiring layer 422 is configured such that the width at a first boundary portion that is a boundary between the first photoelectric conversion unit 411L of the large pixel 410L and the second photoelectric conversion unit 411S of the small pixel 410S is different from the width at a second boundary portion that is a boundary between the first photoelectric conversion unit 411L of the large pixel 410L and another first photoelectric conversion unit 411L of the large pixel 410L. In this manner, it is possible to further enhance suppression of color mixing from the large pixels 410L to the small pixels 410S and to suppress colored flare. It is possible to reduce degradation of image quality of the small pixels 410S.

### 7. Fourth Embodiment of Unit Pixels

### 7.1 Configuration Example in Fourth Embodiment

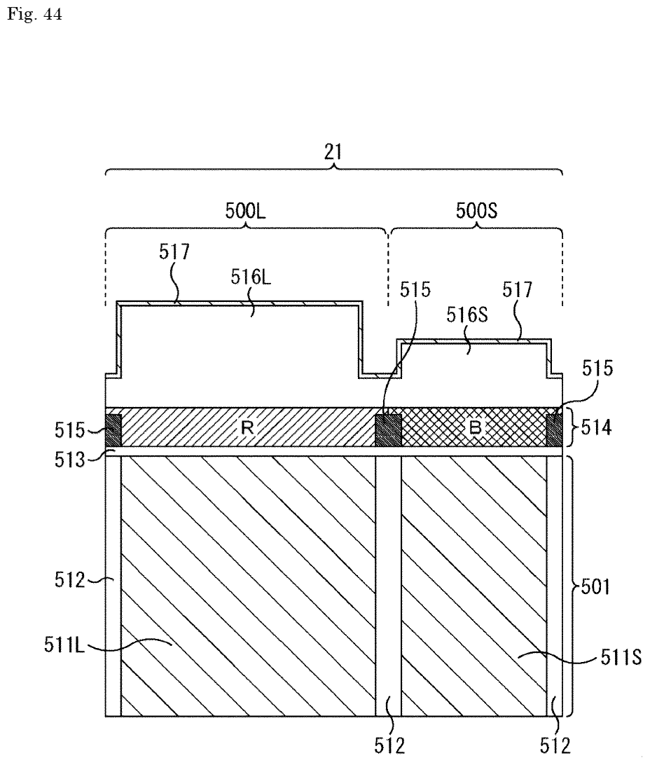

FIG. 44 is a sectional view of unit pixels 21 according to a fourth embodiment of the present disclosure.

In the fourth embodiment, the first layout example illustrated in FIG. 2 is employed as a layout of the unit pixels 21, and FIG. 44 corresponds to a sectional view in the diagonal direction in FIG. 2. Although reference signs that are different from those in the aforementioned first to third embodiments will be applied in the fourth embodiment, parts corresponding to those in the first to third embodiments will be briefly described.

Each unit pixel 21 according to the fourth embodiment includes a large pixel 500L including a first photoelectric conversion unit 511L with high sensitivity and a small pixel 500S including a second photoelectric conversion unit 511S with low sensitivity. The first photoelectric conversion unit 511L and the second photoelectric conversion unit 511S have different areas of photoelectric conversion regions formed in a semiconductor substrate 501, and the second photoelectric conversion unit 511S is formed of a photoelectric conversion region with a smaller area than that of the first photoelectric conversion unit 511L. The semiconductor substrate 421 is configured of a silicon substrate using silicon (Si), for example, as a semiconductor and corresponds to the semiconductor substrate 121 in the first embodiment. Although a wiring layer in which pixel transistors Tr (FIG. 7) and the like are formed similarly to the first embodiment is formed on the front surface side of the semiconductor substrate 501 which is the lower side in the drawing, illustration thereof is omitted.

In the drawings, an insulating film 513 configured of a silicon oxide film (SiO₂) or the like is formed on the side of the rear surface, which is the surface on the upper side, of the semiconductor substrate 501. Note that the insulating film 513 may be formed on a fixed charge film as in the first embodiment. For the insulating film 513, it is possible to use SiO₂ or a composite material (such as SiON or SiOC) containing SiO₂ as a main component, similarly to the insulating film 182 of the first embodiment.

Color filters 514 are formed on the upper surface of the insulating film 513. The color filters 514 of a red (R) color, a green (G) color, or a blue (B) color, for example, are arranged in the Bayer layout for each unit pixel 21 as illustrated in B of FIG. 2. An inter-pixel light shielding film 515 is formed in the same layer as the color filter 514 and above the element separation unit 512. The inter-pixel light shielding film 515 can be formed using a material that is similar to that of the inter-pixel light shielding film 183 in the first embodiment.

On-chip lenses 516 are formed on the color filters 514 and the inter-pixel light shielding film 515. The on-chip lenses 516 include a large on-chip lens 516L formed in the large pixel 500L and a small on-chip lens 516S formed in the small pixel 500S. In a case where the large on-chip lens 516L and the small on-chip lens 516S are not distinguished, the large on-chip lens 516L and the small on-chip lens 516S will be simply referred to as on-chip lenses 516. As a material of the on-chip lenses 516, it is possible to use, for example, an organic resin material such as a styrene-based resin including a styrene thermosetting resin (STSR), an acrylic resin, a styrene-acrylic resin, or a siloxane-based resin. Also, a material with a higher refractive index than the color filters 514 in the layer below the on-chip lenses 516, for example, SiN or SiON may be used as the material of the on-chip lenses 516. The refractive index of STSR is about 1.4 to 1.6, and the refractive index of SiN is equal to or greater than 1.9. The materials of the on-chip lenses 187 described as examples in the aforementioned first embodiment may be used as the material of the on-chip lenses 516. An anti-reflection film 517 using a material that has a refractive index that is different from that of the on-chip lenses 516 is formed on the surfaces of the on-chip lenses 516. As a material of the anti-reflection film 517, it is possible to use a silicon oxide film such as a low temperature oxide (LTO) film, for example. The refractive index of the LTO film is about 1.45.

The on-chip lenses 516 have a quadrangular shape in a plan view and is formed into a rectangular parallelepiped shape with a flat surface thereof which is parallel to the substrate surface of the semiconductor substrate 501 included as an upper surface and with flat surfaces that are perpendicular to the upper surface included as side wall surfaces as illustrated in FIG. 44.

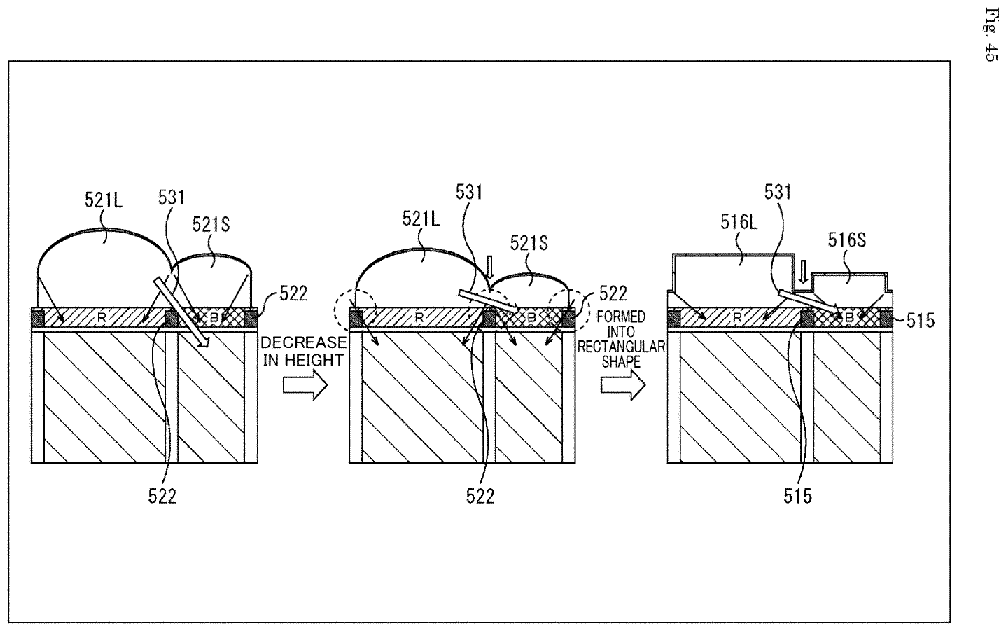

An effect of the on-chip lenses 516 formed into the rectangular parallelepiped shape will be described with reference to FIGS. 45 to 47.

As illustrated in FIG. 45, flare occurs due to incident light at a high angle or light reflected again from a seal glass or the like arranged further upward than the on-chip lenses 521 in the on-chip lenses 521 (a large on-chip lens 521L and a small on-chip lenses 521S) with a hemispherical shape. In particular, colored flare occurs due to light passing through the boundary portion between the large on-chip lens 521L and the small on-chip lens 521S as illustrated by the arrow 531 in the unit pixel in which the large pixel and the small pixel are arranged.

It is possible to minimize the thickness of depression at the boundary portion between the large on-chip lens 521L and the small on-chip lens 521S, which is the thinnest portion of the on-chip lenses 521, by reducing the heights of the large on-chip lens 521L and the small on-chip lens 521S, to reduce the amount of light passing through the boundary portion between the large on-chip lens 521L and the small on-chip lens 521S, and to reduce color mixing.

However, in a case where the on-chip lenses 521 are the hemispherical shape, vignetting occurs at the parts of the inter-pixel light shielding film 522 surrounded by the dashed-line circles, and light receiving sensitivity is degraded.

It is possible to reduce vignetting due to the inter-pixel light shielding film 515 and to prevent degradation of light receiving sensitivity by adopting the rectangular parallelepiped shape as the shape of the on-chip lenses 516 and obtaining rectangular lenses with shorter focal points as in the present embodiment.

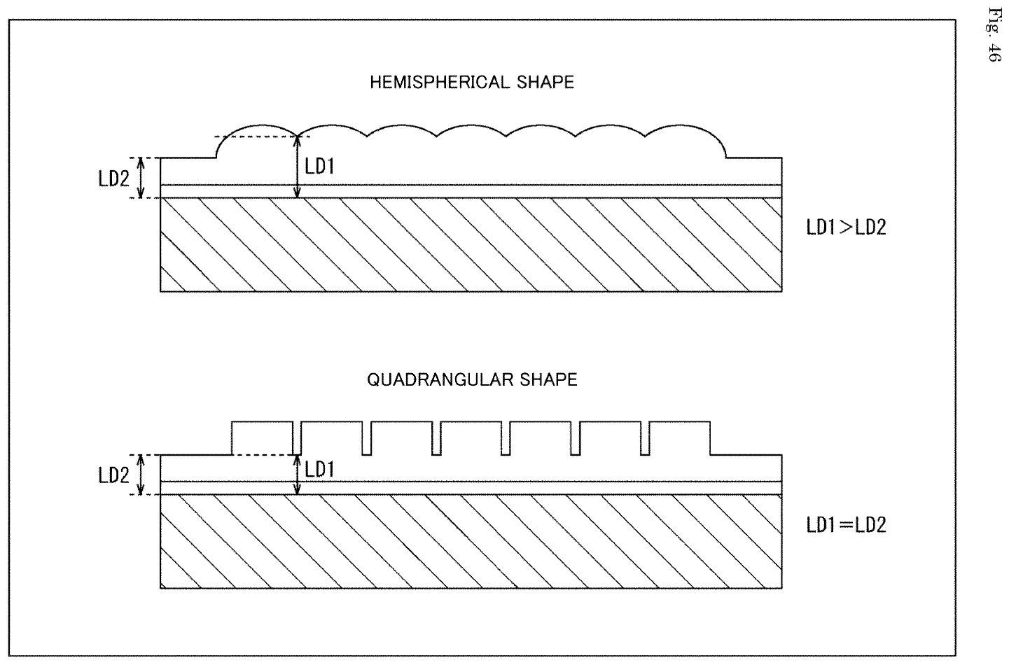

Also, in a case where the shape of the on-chip lenses is a hemispherical shape as illustrated in FIG. 46, a thickness LD1 between depression bottom portions of the on-chip lenses and the substrate is thicker than a thickness LD2 of the thinnest portion of the lens layer (LD1>LD2) to secure a margin for fabrication.

On the contrary, in a case where the shape of the on-chip lenses are quadrangular shapes, it is possible to control working precision to be high and thereby to form the thickness LD1 between the depression bottom portions of the on-chip lenses and the substrate to be the same thickness as or a thickness close to the thickness LD2 of the thinnest portion of the lens layer (LD1=LD2). In this manner, it is possible to reduce the heights of the on-chip lenses 516 as compared with the hemispherical shape.

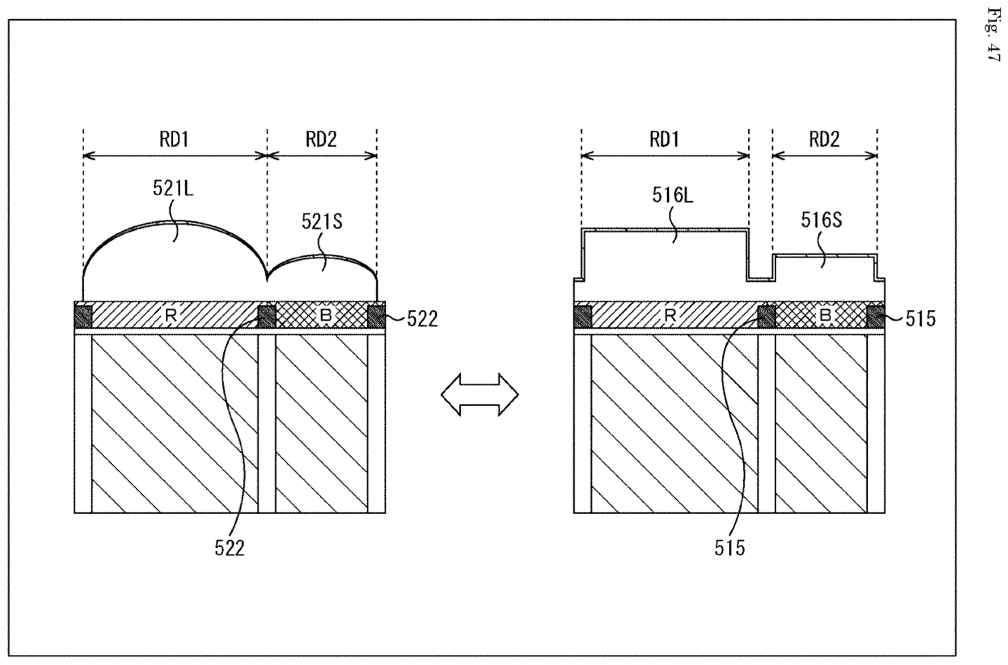

Also, it is also difficult to control widths RD1 and RD2 of the on-chip lenses in the planar direction in the case where the on-chip lens shape is a hemispherical shape as illustrated in FIG. 47, and a variation in sensitivity ratio between the large pixel and the small pixel increases. In the case where the on-chip lens shape is a quadrangular shape, control is easy, and it is thus possible to suppress the variation in sensitivity ratio between the large pixel and the small pixel.

### 7.2 Modification Example

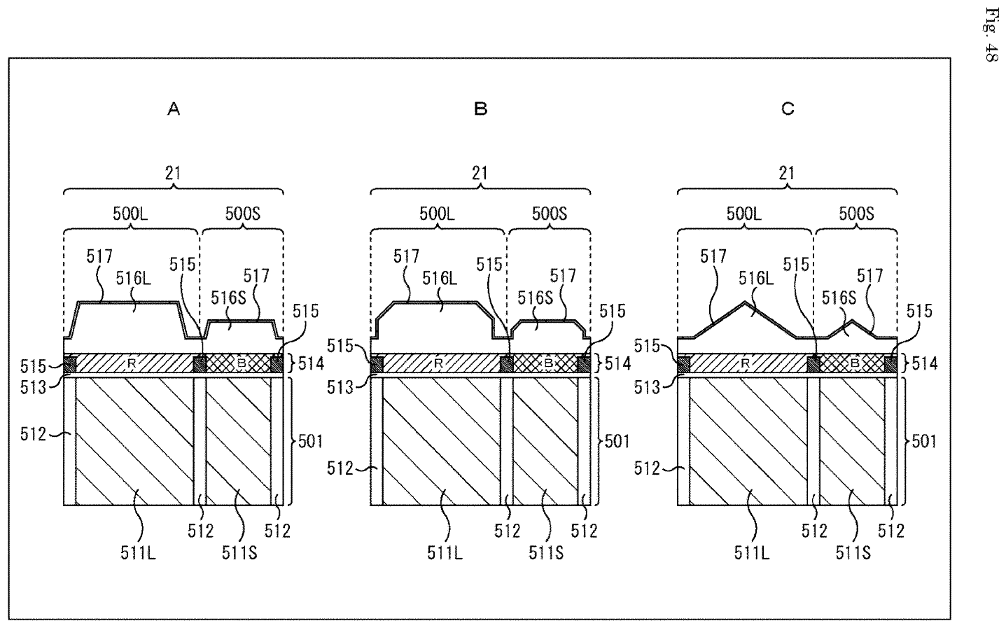

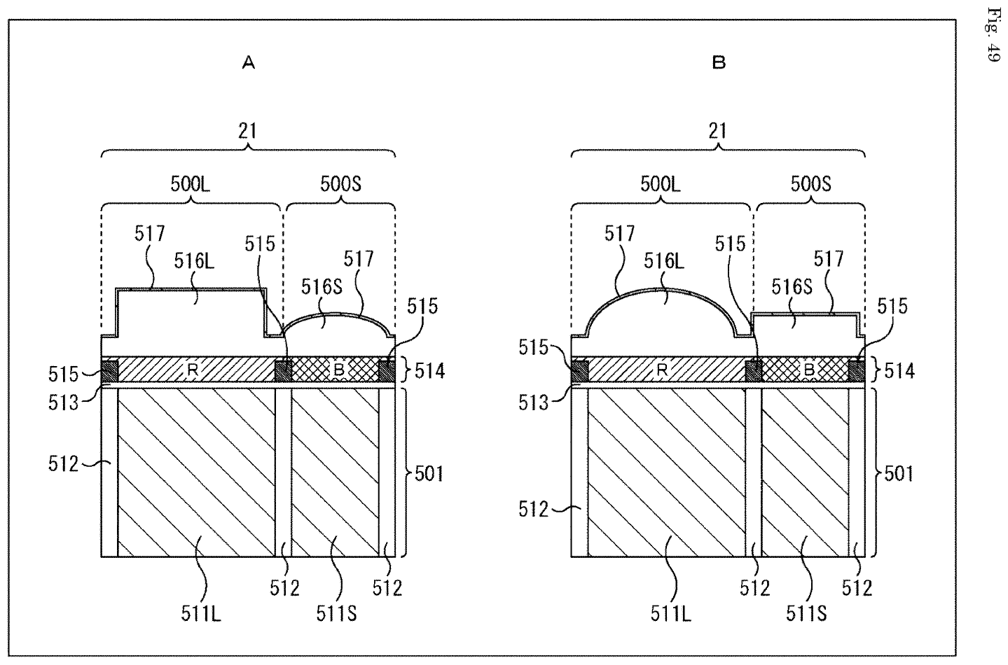

FIGS. 48 and 49 are sectional views of the unit pixels 21 illustrating modification examples of the fourth embodiments.

Although the example in which each of the shapes of the large on-chip lens 516L and the small on-chip lens 516S is the rectangular parallelepiped shape with a quadrangular shape in a plan view has been described as a basic structure in the fourth embodiment illustrated in FIG. 44, the shape is not limited to the rectangular parallelepiped shape. For example, the shapes illustrated in A to C of FIG. 48 or A and B of FIG. 49 may be employed.

In FIG. 48, A illustrates an example in which each of the shapes of the large on-chip lens 516L and the small on-chip lens 516S is a truncated quadrangular pyramid with a quadrangular shape in a plan view and with side wall surfaces inclined on the center side.

In FIG. 48, B illustrates an example in which each of the shapes of the large on-chip lens 516L and the small on-chip lens 516S is a rectangular parallelepiped shape with a quadrangular shape in a plan view, and a chamfered shape obtained by obliquely cutting corner portions of the upper surfaces and the side wall surfaces.

In FIG. 48, C illustrates an example in which each of the shapes of the large on-chip lens 516L and the small on-chip lens 516S is a quadrangular pyramid shape with a quadrangular shape in a plan view.

In FIG. 49, A illustrates an example in which the shape of the large on-chip lens 516L is a rectangular parallelepiped shape and the shape of the small on-chip lens 516S is a hemispherical shape.

In FIG. 49, B illustrates an example in which the shape of the large on-chip lens 516L is a hemispherical shape and the shape of the small on-chip lens 516S is a rectangular parallelepiped shape.

In FIG. 49, A and B are examples in which the shapes of any one of the large on-chip lens 516L and the small on-chip lens 516S is a hemispherical shape and the shape of the other one of them is a rectangular parallelepiped shape, the combination may be a combination between a truncated quadrangular pyramid shape or a quadrangular pyramid shape other than the parallelepiped shape and the hemispherical shape. In addition, the combination may not be a combination with the hemispherical shape, and the shapes of the large on-chip lens 516L and the small on-chip lens 516S may be an arbitrary combination of a rectangular parallelepiped shape, a truncated quadrangular pyramid shape, and a quadrangular pyramid shape.

Also, the shapes of the large on-chip lens 516L and the small on-chip lens 516S are not limited to the prisms, truncated pyramids, or pyramids with quadrangular shapes in a plan view and may be prisms, truncated pyramids, or pyramids with polygonal shapes other than the quadrangular shapes. It is a matter of course that the prisms or truncated pyramids of polygonal shapes other than the quadrangular shapes obtained by obliquely cutting corner portions of upper surfaces thereof as in B of FIG. 48 may also be adopted.

The shape of at least one of the large on-chip lens 516L and the small on-chip lens 516S may be a lens shape having at least two flat surface regions. In other words, in a case where a shape in which corners between surfaces are not rounded is adopted for at least one of the large on-chip lens 516L and the small on-chip lens 516S, it is only necessary for the lens shape to have one or more vertexes, and the vertexes may include roundness caused depending on working precision.

### 7.3 Summary of Fourth Embodiment

Each unit pixel 21 according to the fourth embodiment includes the first photoelectric conversion unit 511L and the second photoelectric conversion unit 511S with different areas of photoelectric conversion regions formed in the semiconductor substrate 501, the element separation units 512 that penetrate through the semiconductor substrate 501 and separate the first photoelectric conversion unit 501L and the second photoelectric conversion unit 501S, the color filters 514 that are provided on the side of the incident light relative to the semiconductor substrate 501, the inter-pixel light shielding film 515 that is formed in the same layer as the color filters 514, and the on-chip lenses 516 that collect the incident light on the photoelectric conversion units 511.

At least one of the large on-chip lens 516L and the small on-chip lens 516S in the unit pixel 21 according to the fourth embodiment has the lens shape including at least two flat surface regions. In this manner, it is possible to suppress leaking of light from the large pixels 410L to the small pixels 410S and to suppress colored flare.

The on-chip lenses 516 according to the fourth embodiment can be mounted as the on-chip lenses in the aforementioned first to third embodiments.

### 8. Fifth Embodiment of Unit Pixels

Next, a configuration example of unit pixels 21 according to a fifth embodiment of the present disclosure will be described.

In the fifth embodiment, Fresnel-type on-chip lenses are employed as lens shapes of on-chip lenses.

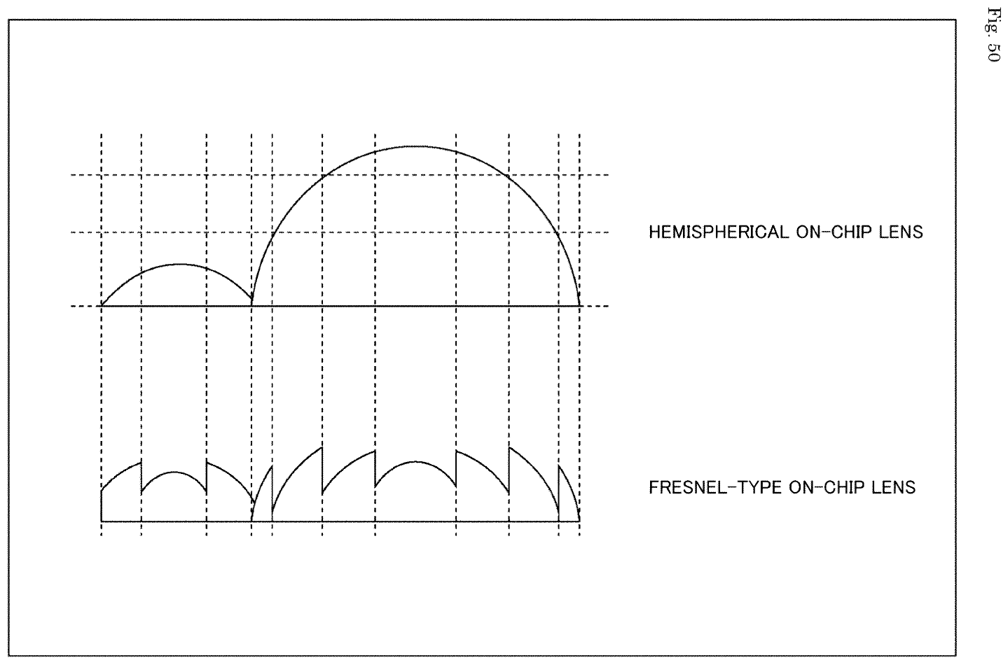

FIG. 50 is a sectional view of hemispherical on-chip lenses (hereinafter, also referred to as hemispherical lenses) and Fresnel-type on-chip lenses (hereinafter, also referred to as Fresnel lenses).

The thicknesses of the on-chip lenses which are hemispherical lenses differ for the large pixel and the small pixel with different areas of photoelectric conversion regions, and the thickness of the on-chip lens of the large pixel is thicker than the thickness of the on-chip lens of the small pixel. In this manner, the amount of decrease in sensitivity of the small pixel is larger in a case where light is obliquely incident than in a case where light is incident perpendicularly to the lens. In other words, since the sensitivity ratio changes, the amount of decrease in SN ratio at a signal connecting position from the large pixel that is the high sensitivity pixel to the small pixel that is the low sensitivity pixel and a dynamic range vary depending on F values of the lenses.

The Fresnel lenses are lenses that are concentrically divided into a plurality of regions in a plan view, each of which has a sawtooth shape in a sectional view. In the example in FIG. 50, the number of split concentric regions of the large on-chip lens is four, and the number of split concentric regions of the small on-chip lens is two. Curved surfaces of the plurality of split concentric regions are different from each other. The Fresnel lenses can be formed to have thin thicknesses as compared with the hemispherical on-chip lenses, and the thicknesses can be the same or substantially the same at the lens center portion and the outer peripheral portion, by concentrically dividing the Fresnel lenses into the plurality of regions (concentric regions, for example) in a plan view and forming them into the sawtooth shape in a sectional view. In this manner, a difference in sensitivity properties with respect to a light incident angle between the high sensitivity pixel and the low sensitivity pixel decreases, the sensitivity ratio is kept constant regardless of a change in F values of the lenses, and it is possible to suppress variations in the amount of decrease in SN ratio at the signal connecting position and the dynamic range. Also, since the on-chip lenses can be formed to be thin, it is possible to suppress flare of the small pixel caused by leakage of light from the large pixel to the small pixel. Moreover, it is also possible to reduce materials to be used as compared with the hemispherical lenses.

### 8.1 First Configuration Example in Fifth Embodiment

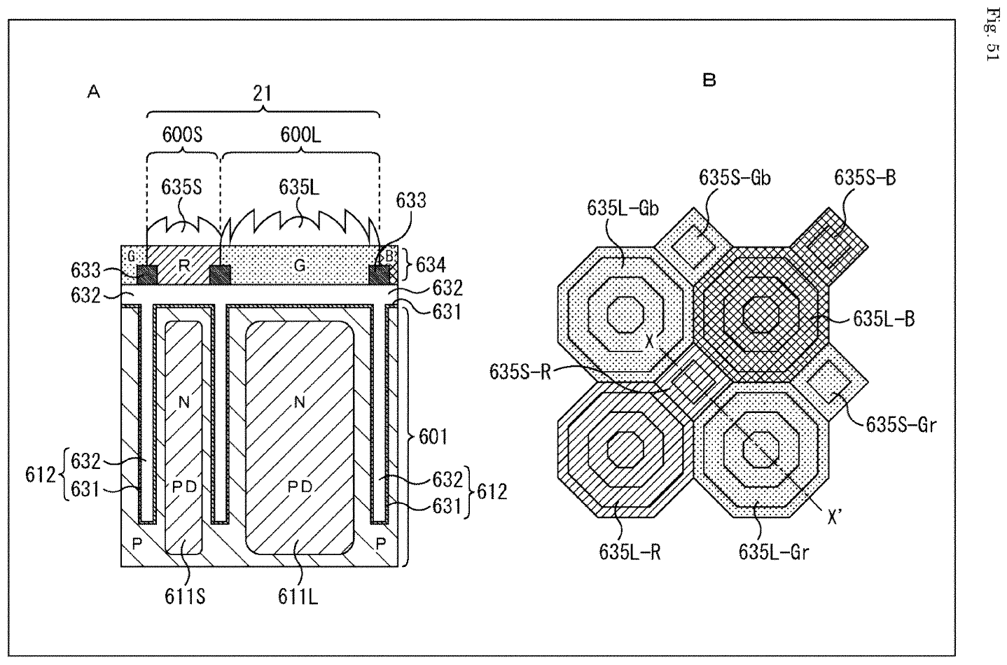

In FIG. 51, A is a sectional view illustrating a first configuration example of the unit pixels 21 according to the fifth embodiment of the present disclosure, and illustrates a sectional view along the line X-X′ in B of FIG. 51. In FIG. 51, B is a top view of the unit pixels 21 according to the second configuration example in the fifth embodiment.

In the first configuration example in the fifth embodiment, the first layout example illustrated in FIG. 2 is employed as a layout of the unit pixels 21. Although reference signs that are different from those in the aforementioned first to fourth embodiments will be applied in the fifth embodiment, parts corresponding to those in the first to fourth embodiments will be briefly described.

Each unit pixel 21 according to the first configuration example includes a large pixel 600L including a first photoelectric conversion unit 611L with high sensitivity and a small pixel 600S including a second photoelectric conversion unit 611S with low sensitivity. The first photoelectric conversion unit 611L and the second photoelectric conversion unit 611S have different areas of photoelectric conversion regions formed in a semiconductor substrate 601, and the second photoelectric conversion unit 611S is formed of a photoelectric conversion region with a smaller area than that of the first photoelectric conversion unit 611L. In a case where the first photoelectric conversion unit 611L and the second photoelectric conversion unit 611S are not particularly distinguished, the first photoelectric conversion unit 611L and the second photoelectric conversion unit 611S will be simply referred to as photoelectric conversion units 611.

The semiconductor substrate 601 is configured of a silicon substrate using silicon (Si), for example, as a semiconductor and is configured of a P-type (first conductivity type) semiconductor region, for example. The photoelectric conversion units 611 are configured of PN junction-type photodiodes with N-type (second conductivity type) semiconductor regions formed inside the P-type semiconductor region of the semiconductor substrate 601. A vicinity of interfaces of both front and rear surfaces of the semiconductor substrate 601 are P-type semiconductor regions also serving as hole charge accumulation regions to suppress a dark current. Although a wiring layer in which pixel transistors Tr (FIG. 7) and the like are formed similarly to the first embodiment is formed on the front surface side of the semiconductor substrate 601, which is the lower side in the drawing, illustration thereof is omitted.

In the semiconductor substrate 601, element separation units 612 that separate the photoelectric conversion units 611 (photoelectric conversion elements) are formed in the region between the first photoelectric conversion unit 611L and the second photoelectric conversion unit 611S. The element separation unit 612 are configured by embedding a fixed charge film 631 and an insulating film 632 inside trenches formed by digging the semiconductor substrate 601 from the rear surface side thereof to a predetermined depth. An effect of the element separation units 612 is similar to that of the element separation units 141 (FIG. 7) in the aforementioned first embodiment.

Color filters 634 are formed on the upper surface of the insulating film 632 above the semiconductor substrate 601. The color filters 634 are arranged in a layout similar to that in B of FIG. 2, that is, a red (R) color, a green (G) color, or a blue (B) color is arranged in a Bayer layout for each unit pixel 21. Inter-pixel light shielding films 633 are embedded in the color filters 634 in the same layer as the color filters 634 and above the element separation units 612. The inter-pixel light shielding film 633 can be formed using a material that is similar to that of the inter-pixel light shielding film 183 in the first embodiment.

A large on-chip lens 635L and a small on-chip lens 635S are formed on the color filters 634. The large on-chip lens 635L is a Fresnel-type on-chip lens formed in the large pixel 600L, and the small on-chip lens 635S is a Fresnel-type on-chip lens formed in the small pixel 500S. In a case where the large on-chip lens 635L and the small on-chip lens 635S are not distinguished, the large on-chip lens 635L and the small on-chip lens 635S will be simply referred to as on-chip lenses 635. The on-chip lenses 635 can be formed using a material similar to that of the on-chip lenses 187 in the first embodiment, for example.

An anti-reflection film may be formed on the surfaces of the large on-chip lens 635L and the small on-chip lens 635S using the same material as that of the anti-reflection film 188 in the first embodiment.

In FIG. 51, B illustrates a layout of the large on-chip lenses 635L, the small on-chip lenses 635S, and the color filters 634. In B of FIG. 51, hyphens and “R”, “Gr”, “Gb”, and “B” in accordance with the colors of the color filters 634 are applied after the reference signs of the large on-chip lenses 635L and the small on-chip lenses 635S.

Each large on-chip lens 635L has an octagonal planar shape and is concentrically divided into four regions. Each small on-chip lens 635S has a quadrangular planar shape and is divided into two regions with concentric quadrangular shapes. The actual numbers of split Fresnel lenses are optimized in consideration of influences of diffraction.

As described above, a solid-state imaging device 1 including the unit pixels 21 according to the fifth embodiment is a back-illuminated-type solid-state imaging device in which incident light is collected by the on-chip lenses 635 formed on the rear surface side of the semiconductor substrate 601 and is then subjected to the photoelectric conversion by the photoelectric conversion units 611. Each unit pixel 21 according to the fifth embodiment includes the large pixel 600L including the first photoelectric conversion unit 611L with a large area of photoelectric conversion region and the small pixel 600S including the second photoelectric conversion unit 611S with a smaller photoelectric conversion region than that of the first photoelectric conversion unit 611L and enables high-sensitivity imaging with the large pixel 600L and low-sensitivity imaging with the small pixel 600S.

Each unit pixel 21 according to the first configuration example in the fifth embodiment includes the first photoelectric conversion unit 611L and the second photoelectric conversion unit 611S with different areas of photoelectric conversion regions formed in the semiconductor substrate 601, the element separation units 612 that separate the first photoelectric conversion unit 611L and the second photoelectric conversion unit 611S, the color filters 634 that are provided on the side of the incident light relative to the semiconductor substrate 601, and the on-chip lenses 635 that collect the incident light on the photoelectric conversion units 611.

According to the unit pixels 21 of the first configuration example, the large on-chip lenses 635L and the small on-chip lenses 635S are formed of the Fresnel-type on-chip lenses. In this manner, the lens thicknesses of the large on-chip lens 635L in the large pixel 600L and the small on-chip lens 635S in the small pixel 600S can be the same or substantially the same, and it is possible to eliminate a difference in oblique incidence properties due to a difference in lens thicknesses. Moreover, it is possible to reduce oblique incidence resulting from light reflected again from the seal glass or the like arranged on the side further upward than the on-chip lenses 635 being incident at a high angle, to suppress flare, and to reduce color mixing.

### 8.2 Second Configuration Example in Fifth Embodiment

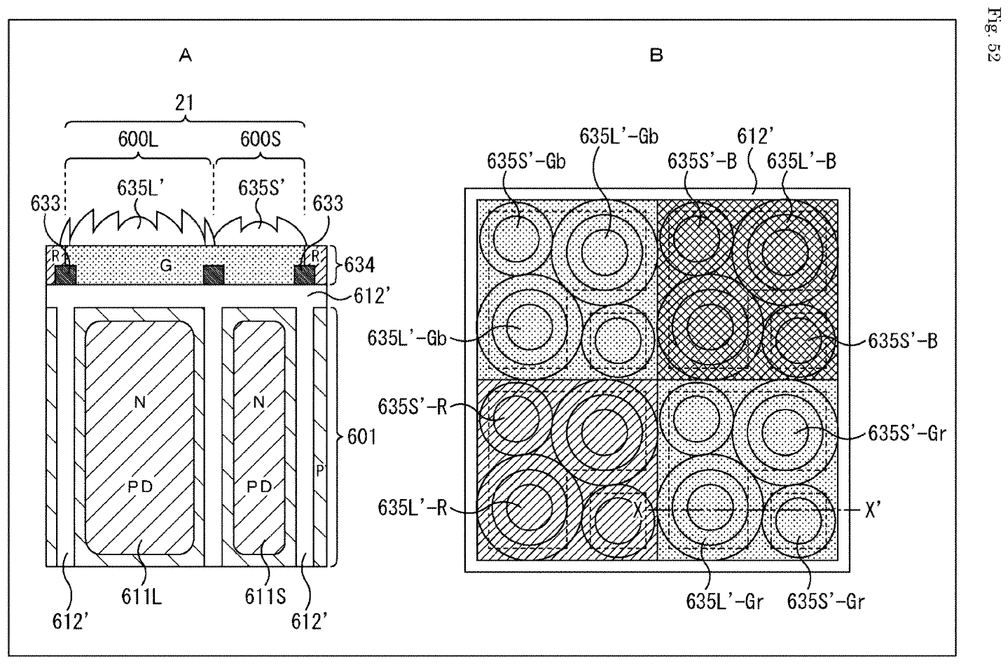

In FIG. 52, A is a sectional view illustrating a second configuration example of the unit pixels 21 according to the fifth embodiment of the present disclosure and illustrates a sectional view along the line X-X′ in B of FIG. 52. In FIG. 52, B is a top view of the unit pixels 21 according to the second configuration example in the fifth embodiment.

In the second configuration example in the fifth embodiment, the second layout example illustrated in FIG. 3 is employed as a layout of the unit pixels 21. As a layout of the on-chip lenses, the layout in B of FIG. 4 in which the on-chip lenses with different sizes are arranged is employed. In the second configuration example in FIG. 52, parts corresponding to those in the first configuration example illustrated in FIG. 51 are denoted by the same reference signs, and description will be given by focusing on parts different from those in the first configuration example.

In the second configuration example in FIG. 52, element separation units 612′ are formed instead of the element separation units 612 in the first configuration example. Although the element separation units 612 in the first configuration example has trench structures obtained by digging the semiconductor substrate 601 from the rear surface side of the semiconductor substrate 601 up to the predetermined depth without penetrating through the semiconductor substrate 601, the element separation units 612′ in the second configuration example penetrate through and completely separate the semiconductor substrate 601. The element separation units 612′ are configured by embedding insulating films of silicon oxide (SiO₂) films or the like in trenches that penetrate through the semiconductor substrate 601.

A large on-chip lens 635L′ and a small on-chip lens 635S′ are formed on the color filters 634. The large on-chip lens 635L′ and the small on-chip lens 635S′ are Fresnel-type on-chip lenses similarly to the first configuration example.

In FIG. 52, B illustrates a layout of the large on-chip lenses 635L′, the small on-chip lenses 635S′, and the color filters 634. In B of FIG. 52, hyphens and “R”, “Gr”, “Gb”, and “B” in accordance with colors of the color filters 634 are applied after reference signs of the large on-chip lenses 635L′ and the small on-chip lenses 635S′.

In the second configuration example, the second layout example illustrated in FIG. 3 is employed as the layout of the unit pixels 21, and the first photoelectric conversion unit 611L formed into an L shape and the second photoelectric conversion unit 611S formed into a quadrangular shape are thus arranged in each unit pixel 21 with a quadrangular shape surrounded by the element separation units 612′.

The large on-chip lenses 635L′ and the small on-chip lenses 635S′ are arranged in an aligned manner in the diagonal direction as illustrated in B of FIG. 52, and the small on-chip lenses 635S′ and the large on-chip lenses 635L′ are alternately arranged in the column direction and the row direction. Each small on-chip lens 635S′ is arranged on the second photoelectric conversion unit 611S′.

Each large on-chip lens 635L′ has a circular planar shape and is concentrically divided into three regions. Each small on-chip lens 635S′ has a circular planar shape and is concentrically divided into two regions. The actual numbers of the split Fresnel lenses are optimized in consideration of influences of diffraction.

According to the unit pixels 21 of the second configuration example, the large on-chip lenses 635L′ and the small on-chip lenses 635S′ are formed of Fresnel-type on-chip lenses. In this manner, the lens thicknesses of the large on-chip lenses 635L′ in the large pixels 600L and the small on-chip lenses 635S′ in the small pixels 600S can be the same or substantially the same, and it is possible to eliminate a difference in oblique incidence properties caused by a difference in lens thicknesses. Also, it is possible to reduce oblique incidence resulting from light reflected again from the seal glass or the like arranged on the side further upward than the on-chip lenses 635′ being incident at a high angle, to suppress flare, and to reduce color mixing.

### 8.3 Third Configuration Example in Fifth Embodiment

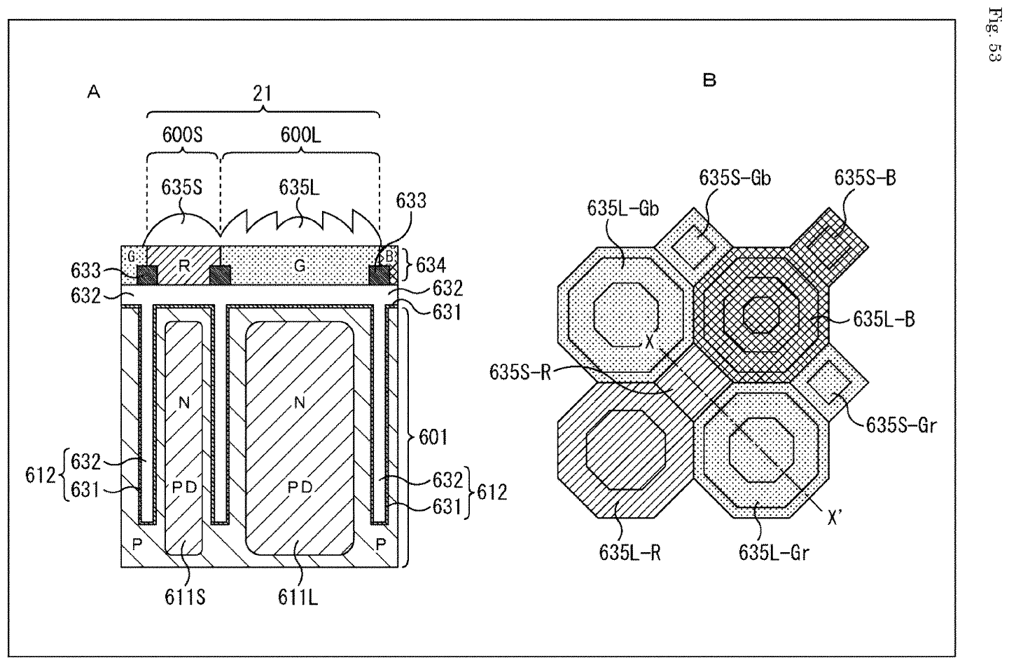

In FIG. 53, A is a sectional view illustrating a third configuration example of the unit pixels 21 according to the fifth embodiment of the present disclosure and illustrates a sectional view along the line X-X′ in B of FIG. 53. In FIG. 53, B is a top view of the unit pixels 21 according to the third configuration example in the fifth embodiment.

In the third configuration example in the fifth embodiment, the first layout example illustrated in FIG. 2 is employed as a layout of the unit pixels 21. In the third configuration example in FIG. 53, parts corresponding to those in the first configuration example illustrated in FIG. 51 are denoted by the same reference signs, and description will be given by focusing on parts different from those in the first configuration example.

The unit pixels 21 according to the third configuration example are different from those in the aforementioned first configuration example in that the numbers of split concentric regions of the large on-chip lens 635L and the small on-chip lens 635S formed on the color filters 634 are different in accordance with the colors of the color filters 634, in other words, wavelengths of incident light that the color filters 634 allow to be transmitted therethrough.

Specifically, as illustrated in the plan view in B of FIG. 53, the number of divided regions in the large on-chip lens 635L-R on the red color filter 634 is two, and the number of split regions in the small on-chip lens 635S-R is zero (no splitting), in other words, the small on-chip lens 635S-R is a hemispherical lens. The number of split regions in each of the large on-chip lenses 635L-Gb and 635L-Gr on the green color filter 634 is three, and the number of split regions in each of the small on-chip lenses 635S-Gb and 635S-Gr is two. The number of split parts in the large on-chip lens 635L-B on the blue color filter 634 is four, and the number of split parts in the small on-chip lens 635S-B is two.

In comparison between the large on-chip lenses 635L, the number of split regions in the large on-chip lens 635L-R on the red color filter 634 is two, the number of split regions in each of the large on-chip lenses 635L-Gb and 635L-GR on the green color filter 634 is three, and the number of split regions in the large on-chip lens 635L-B on the blue color filter 634 is four. In comparison between the small on-chip lenses 635S, the number of split regions in the red small on-chip lens 635S-R is zero (no splitting), that is, the red small on-chip lens 635S-R is a hemispherical lens, and both the number of the split regions in each of the green small on-chip lenses 635S-Gb and 635S-Gr and the number of split regions in the blue small on-chip lens 635S-B are two.

According to the unit pixels 21 of the third configuration example, the large on-chip lenses 635L and the small on-chip lenses 635S are formed of Fresnel-type on-chip lenses. In this manner, it is possible to eliminate a difference in oblique incidence properties caused by a difference in lens thicknesses between the large on-chip lenses 635L in the large pixels 600L and the small on-chip lenses 635S in the small pixels 600S. Moreover, it is possible to reduce oblique incidence resulting from light reflected again from the seal glass or the like arranged on the side further upward than the on-chip lenses 635 being incident at a high angle, to suppress flare, and to reduce color mixing.

Also, it is possible to optimize the sensitivity properties for each transmission wavelength and to improve light receiving sensitivity by changing the numbers of split regions in the large on-chip lenses 635L and the small on-chip lenses 635S in accordance with the colors of the color filters 634, that is, the wavelengths of incident light that the color filters 634 allow to be transmitted therethrough. Although the third configuration example is the example in which the first layout example in FIG. 2 is employed as the layout of the unit pixels 21, the configuration in which the numbers of split regions are changed in accordance with the wavelengths of the incident light that the color filters 634 allow to be transmitted therethrough is similarly possible in a case where the second layout example in FIG. 3 is employed as in the second configuration example as well.

### 8.4 Fourth Configuration Example in Fifth Embodiment

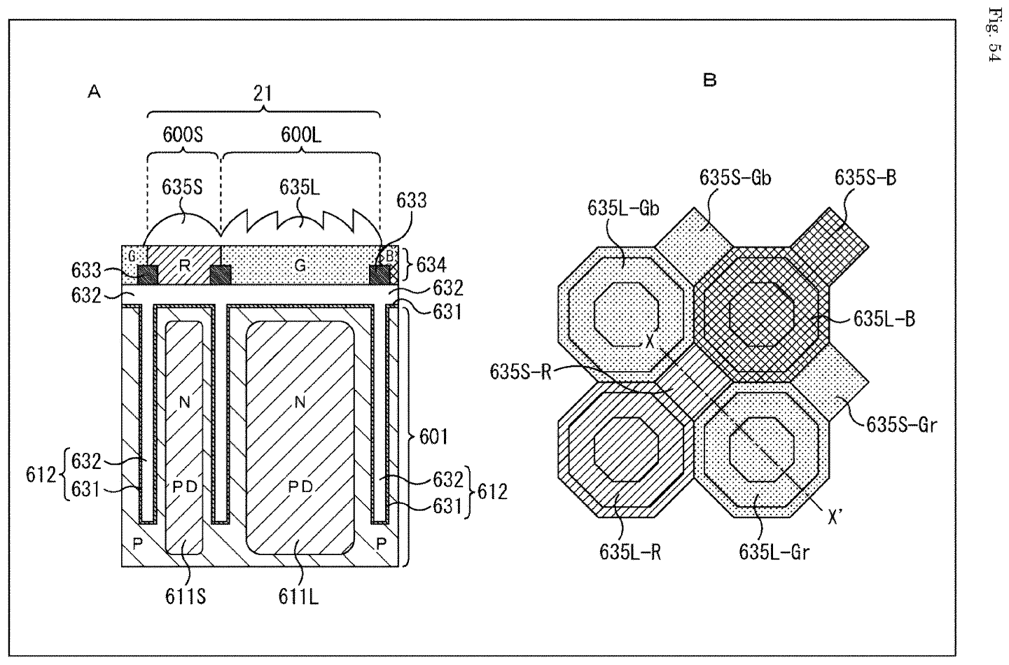

In FIG. 54, A is a sectional view illustrating a fourth configuration example of the unit pixels 21 according to the fifth embodiment of the present disclosure and illustrates a sectional view along the line X-X′ in B of FIG. 54. In FIG. 54, B is a top view of the unit pixels 21 according to the fourth configuration example in the fifth embodiment.

In the fourth configuration example in the fifth embodiment, the first layout example illustrated in FIG. 2 is employed as a layout of the unit pixels 21. In the fourth configuration example in FIG. 54, parts corresponding to those in the first configuration example illustrated in FIG. 51 are denoted by the same reference signs, and description will be given by focusing on parts different from those in the first configuration example.

In the first configuration example illustrated in FIG. 51, both the large on-chip lens 635L in the large pixel 600L and the small on-chip lens 635S in the small pixel 600S are configured of Fresnel-type on-chip lenses.

On the contrary, the unit pixel 21 according to the fourth configuration example is different from that in the aforementioned first configuration example in that only the large on-chip lens 635L in the large pixel 600L is configured of a Fresnel lens and the small on-chip lens 635S in the small pixel 600S is configured of a hemispherical lens.

As illustrated in the plan view in B of FIG. 54, each of the large on-chip lenses 635L-R, 635L-Gb, 635L-Gr, and 635L-B is configured of a Fresnel lens, the number of split regions of which is three, and each of the small on-chip lenses 635S-R, 635S-Gb, 635S-Gr, and 635S-B is configured of a hemispherical lens. The small on-chip lens 635S has a small planar size, the lens height can be kept low even in a case where the hemispherical lens is adopted, and the hemispherical lens may thus be used.

According to the unit pixels 21 of the fourth configuration example, the large on-chip lenses 635L are configured of the Fresnel lenses, and the small on-chip lenses 635S are configured of the hemispherical lenses. In this manner, the lens thicknesses of the large on-chip lenses 635L in the large pixels 600L and the small on-chip lenses 635S in the small pixels 600S can be the same or substantially the same, and it is possible to eliminate a difference in oblique incidence properties caused by a difference in lens thicknesses. Moreover, it is possible to reduce oblique incidence resulting from light reflected again from the seal glass or the like arranged on the side further upward than the on-chip lenses 635 being incident at a high angle, to suppress flare, and to reduce color mixing. Although the fourth configuration example is the example in which the first layout example in FIG. 2 is employed as the layout of the unit pixels 21, the configuration in which only the large on-chip lenses 635L are configured of the Fresnel lenses is similarly possible even in a case where the second layout example in FIG. 3 is employed as in the second configuration example.

### 8.5 Fifth Configuration Example in Fifth Embodiment

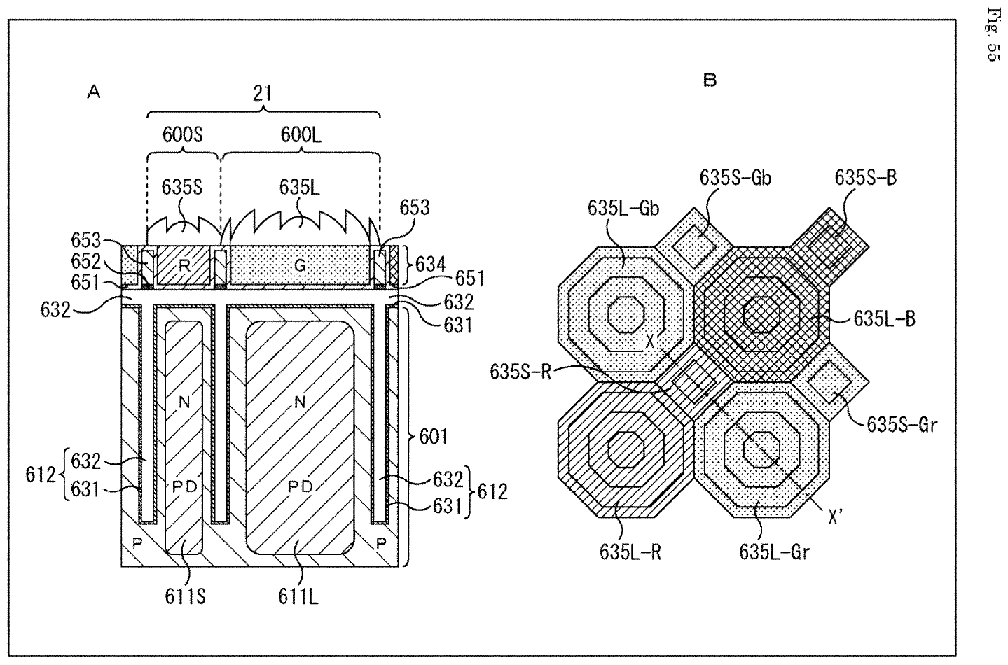

In FIG. 55, A is a sectional view illustrating a fifth configuration example of unit pixels 21 according to the fifth embodiment of the present disclosure and illustrates a sectional view along the line X-X′ in B of FIG. 55. In FIG. 55, B is a top view of the unit pixels 21 according to the fifth configuration example in the fifth embodiment.

In the fifth configuration example in the fifth embodiment, the first layout example illustrated in FIG. 2 is employed as a layout of the unit pixels 21. In the fifth configuration example in FIG. 55, parts corresponding to those in the first configuration example illustrated in FIG. 51 are denoted by the same reference signs, and description will be given by focusing on parts different from those in the first configuration example.

In the first configuration example illustrated in FIG. 51, the inter-pixel light shielding films 633 are formed by being embedded in the color filters 634.

On the contrary, a second insulating film 651 is laminated on the insulating film 632, and inter-pixel light shielding films 652 are formed in the same layer as the second insulating films 651 and above the element separation units 612 in the fifth configuration example in A of FIG. 55. Therefore, the inter-pixel light shielding films 652 are arranged in a layer that is different from that of the color filters 634. Low N walls 653 using a material with a lower refractive index than the color filters 634 are formed above the inter-pixel light shielding films 652 and in the same layer as the color filter 634. Upper surfaces and side walls of the low N walls 653 are covered with the second insulating films 651. The second insulating films 651 may be a material that is the same as or different from that of the insulating film 632. The second insulating films 651 are configured of silicon oxide films, for example.

Since the layout of the large on-chip lenses 635L, the small on-chip lenses 635S, and the color filters 634 illustrated in B of FIG. 55 is similar to that in the first configuration example, description thereof will be omitted.

According to the unit pixels 21 of the fifth configuration example, the large on-chip lenses 635L and the small on-chip lenses 635S are formed of Fresnel-type on-chip lenses. In this manner, it is possible to eliminate a difference in oblique incidence properties caused by a difference in lens thicknesses between the large on-chip lenses 635L in the large pixels 600L and the small on-chip lenses 635S in the small pixels 600S. Moreover, it is possible to reduce oblique incidence resulting from light reflected again from the seal glass or the like arranged on the side further upward than the on-chip lenses 635 being incident at a high angle, to suppress flare, and to reduce color mixing.

Also, according to the unit pixels 21 of the fifth configuration example, the low N walls 653 with a lower refractive index than the color filters 634 are provided above the inter-pixel light shielding films 652 and in the same layer as the color filters 634. In this manner, it is possible to reflect oblique incidence that is incident at a high angle by the low N walls 653, to suppress flare, and to further reduce color mixing.

Although the fifth configuration example is the example in which the first layout example in FIG. 2 is employed as the layout of the unit pixels 21, the configuration in which the low N walls 653 in the same layer as the color filters 634 is similarly possible for the pixel structure employing the second layout example in FIG. 3 as in the second configuration example.

### 8.6 Sixth Configuration Example in Fifth Embodiment

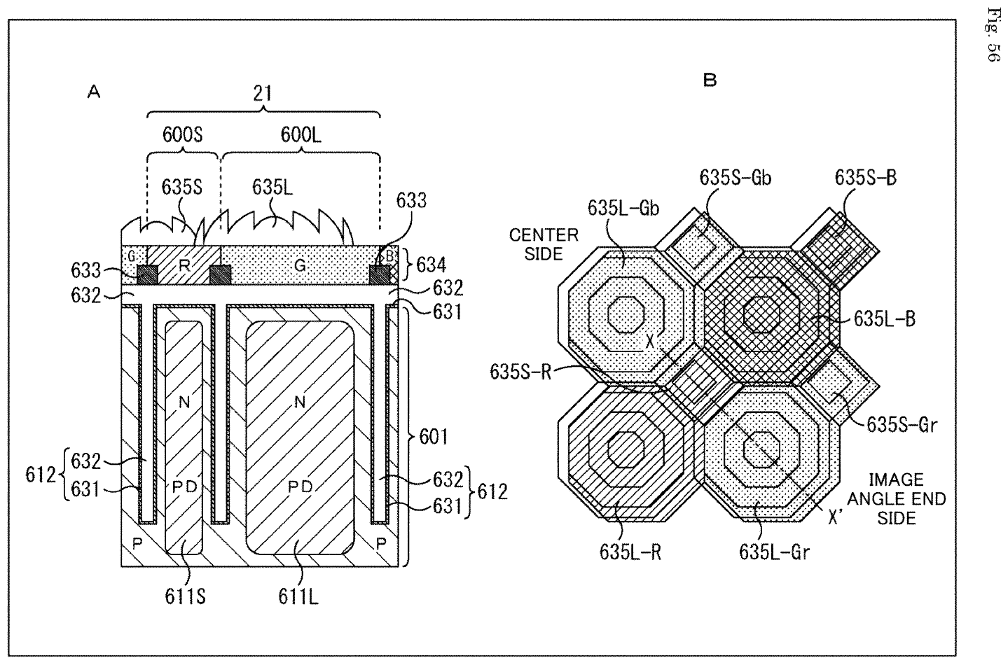

In FIG. 56, A is a sectional view illustrating a sixth configuration example of the unit pixels 21 according to the fifth embodiment of the present disclosure and illustrates a sectional view along the line X-X′ in B of FIG. 56. In FIG. 56, B is a top view of the unit pixels 21 according to the sixth configuration example in the fifth embodiment.

In the sixth configuration example in the fifth embodiment, the first layout example illustrated in FIG. 2 is employed as a layout of the unit pixels 21. In the sixth configuration example in FIG. 56, parts corresponding to those in the first configuration example illustrated in FIG. 51 are denoted by the same reference signs, and description will be given by focusing on parts different from those in the first configuration example.

The sixth configuration example in FIG. 56 is different from the first configuration example illustrated in FIG. 51 in that the large on-chip lenses 635L and the small on-chip lenses 635S configured of the Fresnel lenses are arranged with a shift in the planar direction to perform pupil correction, and the other points are the same.

In other words, the positions of the large on-chip lenses 635L and the small on-chip lenses 635S with respect to the positions of the first photoelectric conversion units 611L and the second photoelectric conversion units 611S differ depending on the pixel positions in the pixel array unit 11 and are arranged with a shift in the direction to the center portion of the pixel array unit 11 as illustrated in A and B of FIG. 56. The amount of shift of the large on-chip lenses 635L and the small on-chip lenses 635S increases as they approach the outer peripheral portion (image angle end) of the pixel array unit 11.

According to the unit pixels 21 of the sixth configuration example, the large on-chip lenses 635L and the small on-chip lenses 635S are formed of the Fresnel-type on-chip lenses. In this manner, it is possible to eliminate a difference in oblique incidence properties caused by a difference in lens thicknesses between the large on-chip lenses 635L in the large pixels 600L and the small on-chip lenses 635S in the small pixels 600S. Moreover, it is possible to reduce oblique incidence resulting from light reflected again from the seal glass or the like arranged on the side further upward than the on-chip lenses 635 being incident at a high angle, to suppress flare, and to reduce color mixing.

Also, according to the unit pixels 21 of the sixth configuration example, it is possible to form the arrangement of the large on-chip lenses 635L and the small on-chip lenses 635S as an arrangement with a shift to the positions for performing pupil correction. In this manner, it is possible to address an incident angle that increases as it approaches the outer peripheral portion of the pixel array unit 11, to suppress flare, and to further reduce color mixing.

Although the sixth configuration example is the example in which the first layout example in FIG. 2 is employed as the layout of the unit pixels 21, it is possible to similarly form the large on-chip lenses 635L and the small on-chip lenses 635S in the arrangement with the shift to the positions for performing pupil correction in the pixel structure employing the second layout example in FIG. 3 as in the second configuration example as well.

### 8.7 Seventh Configuration Example in Fifth Embodiment

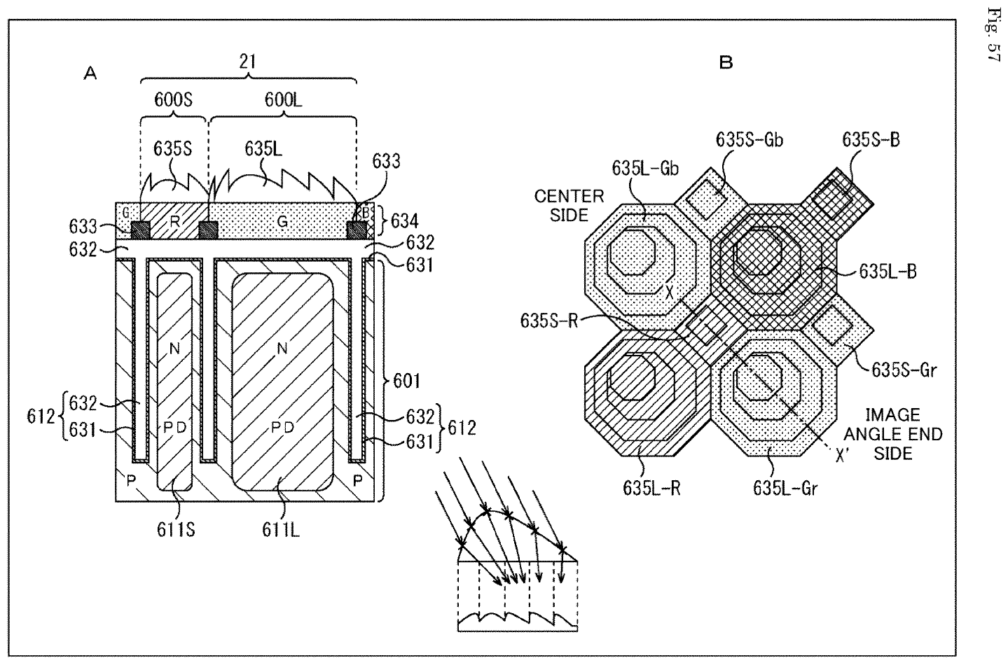

In FIG. 57, A is a sectional view illustrating a seventh configuration example of the unit pixels 21 according to the fifth embodiment of the present disclosure and illustrates a sectional view along the line X-X′ in B of FIG. 57. In FIG. 57, B is a top view of the unit pixels 21 according to the seventh configuration example in the fifth embodiment.

In the seventh configuration example in the fifth embodiment, the first layout example illustrated in FIG. 2 is employed as a layout of the unit pixels 21. In the seventh configuration example in FIG. 57, parts corresponding to those in the first configuration example illustrated in FIG. 51 are denoted by the same reference signs, and description will be given by focusing on parts different from those in the first configuration example.

The seventh configuration example in FIG. 57 is the same as the sixth configuration example in FIG. 56 in that the large on-chip lenses 635L and the small on-chip lenses 635S perform pupil correction. However, instead of shifting the positions of the large on-chip lenses 635L and the small on-chip lenses 635S with respect to the positions of the first photoelectric conversion units 611L and the second photoelectric conversion units 611S as in the sixth configuration example, the large on-chip lenses 635L and the small on-chip lenses 635S formed of Fresnel lenses are formed such that centers of gravity of the shapes thereof differ depending on the pixel positions in the pixel array unit 11. In other words, the large on-chip lenses 635L and the small on-chip lenses 635S are formed such that the centers of gravity of the shapes thereof are shifted on the center side of the pixel array unit 11 as they approach the outer peripheral portion (image angle end) of the pixel array unit 11 as illustrated in A and B of FIG. 56. The amounts of eccentricity of the large on-chip lenses 635L and the small on-chip lenses 635S increase as they approach the outer peripheral portion (image angle end) of the pixel array unit 11. The seventh configuration example is similar to the first configuration example illustrated in FIG. 51 other than that the large on-chip lenses 635L and the small on-chip lenses 635S are formed with the centers of gravity thereof deviating to perform pupil correction.

According to the unit pixels 21 of the seventh configuration example, the large on-chip lenses 635L and the small on-chip lenses 635S are formed of Fresnel-type on-chip lenses. In this manner, it is possible to eliminate a difference in oblique incidence properties caused by a difference in lens thicknesses between the large on-chip lenses 635L in the large pixels 600L and the small on-chip lenses 635S in the small pixels 600S. Moreover, it is possible to reduce oblique incidence resulting from light reflected again from the seal glass or the like arranged on the side further upward than the on-chip lenses 635 being incident at a high angle, to suppress flare, and to reduce color mixing.

In addition, according to the unit pixels 21 of the seventh configuration example, the large on-chip lenses 635L and the small on-chip lenses 635S are formed such that the centers of gravity of the shapes thereof deviate to perform pupil correction. In this manner, it is possible to address an incident angle that increases as it approaches the outer peripheral portion of the pixel array unit 11, to suppress flare, and to further reduce color mixing. Although color mixing due to light being incident from the outer peripheral direction like light reflected again from the seal glass or the like is likely to occur in pupil correction achieved by lens shift in the sixth configuration example, this does not happen in the case of pupil correction achieved by changing the shapes.

Although the seventh configuration example is the example that employs the first layout example in FIG. 2 as the layout of the unit pixels 21, it is possible to similarly form the large on-chip lenses 635L and the small on-chip lenses 635S with the centers of gravity deviating to the positions to perform pupil correction for the pixel structure that employs the second layout example in FIG. 3 as in the second configuration example.

### 8.8 Summary of Fifth Embodiment

Each unit pixel 21 according to the fifth embodiment includes the first photoelectric conversion unit 611L and the second photoelectric conversion unit 611S with different areas of photoelectric conversion regions formed in the semiconductor substrate 601, the element separation units 612 that separate the first photoelectric conversion unit 601L and the second photoelectric conversion unit 601S, the color filters 634 that are provided on the side of the incident light relative to the semiconductor substrate 601, the inter-pixel light shielding films 633 that are provided between the color filters 634, and the on-chip lenses 635 that collect the incident light on the photoelectric conversion units 611.

The large on-chip lenses 635L and the small on-chip lenses 635S in the unit pixels 21 according to the fifth embodiment include the Fresnel-type on-chip lenses. There are a case where only the large on-chip lenses 635L are the Fresnel-type on-chip lenses and a case where the large on-chip lenses 635L and the small on-chip lenses 635S are the Fresnel-type on-chip lenses. It is possible to suppress leakage of light from the large pixels 600L to the small pixels 600S and to suppress colored flare by adopting the Fresnel-type on-chip lenses as at least either the large on-chip lenses 635L or the small on-chip lenses 635S. Moreover, the lens thicknesses of the large pixels 600L and the small pixels 600S can be the same or substantially the same, and it is possible to thin the lens thicknesses as compared with the hemispherical on-chip lenses. In this manner, it is possible to reduce a difference in oblique incidence properties of the large pixels 600L and the small pixels 600S and to suppress dependency of the sensitivity ratio on the F values.

It is possible to perform pupil correction by arranging the Fresnel-type large on-chip lenses 635L and small on-chip lenses 635S with a shift by a predetermined shift amount to the center side of the pixel array unit 11 or by forming the Fresnel-type large on-chip lenses 635L and small on-chip lenses 635S such that the centers of gravity of the shapes thereof deviate on the center side of the pixel array unit 11, in accordance with the pixel positions in the pixel array unit 11.

In this manner, it is possible to improve the degree of freedom in designing the lenses.

The on-chip lenses 635 in the fifth embodiment can be mounted as the on-chip lenses in the aforementioned first to third embodiments.

### 9. Summary of all Embodiments

All the unit pixels 21 according to the aforementioned first to fifth embodiments can suppress leakage of light from the large pixels to the small pixels and suppress colored flare. It is thus possible to suppress degradation of image quality of the small pixels. The structures employed for the unit pixels 21 according to the first to fifth embodiments can be arbitrarily combined.

### 10. Exemplary Use of Solid-State Imaging Device

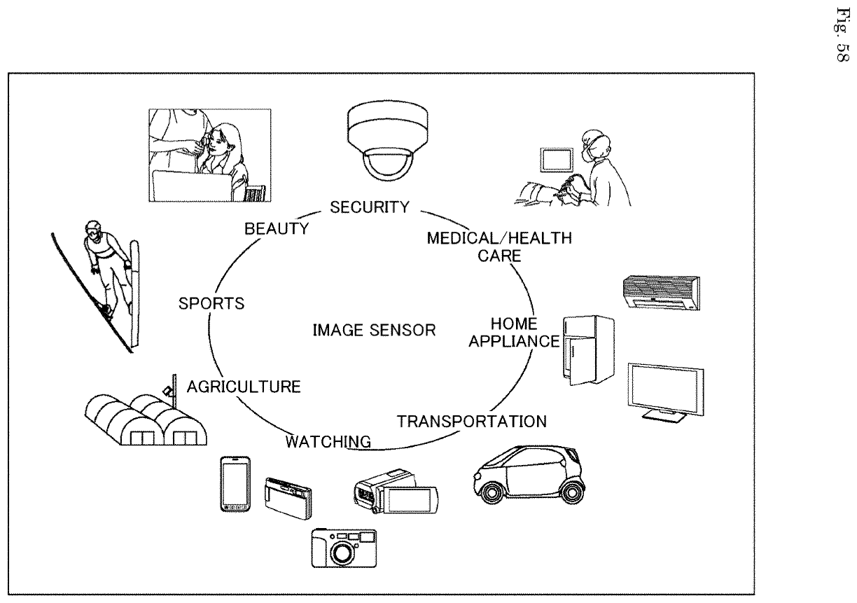

FIG. 58 is a diagram illustrating an example of how an image sensor including the solid-state imaging device 1 is used.

The aforementioned solid-state imaging device 1 can be used for various cases that sense light such as visible light, infrared light, ultraviolet light, and X-rays as follows, for example, as an image sensor.
Devices that capture images used for viewing, such as digital cameras and mobile devices with camera functions.
Devices used for transportation, such as in-vehicle sensors that capture front, rear, surrounding, and interior view images of automobiles, monitoring cameras that monitor traveling vehicles and roads, ranging sensors that measure a distance between vehicles, and the like, for safe driving such as automatic stop, recognition of a driver's condition, and the like
Devices used for home appliances such as TVs, refrigerators, and air conditioners in order to capture an image of a user's gesture and perform device operations in accordance with the gesture
Devices used for medical treatment and healthcare, such as endoscopes and devices that perform angiography by receiving infrared light
Devices used for security, such as monitoring cameras for crime prevention and cameras for personal authentication
Devices used for beauty, such as a skin measuring device that captures images of the skin and a microscope that captures images of the scalp
Devices used for sports, such as action cameras and wearable cameras for sports applications
Devices used for agriculture, such as cameras for monitoring conditions of fields and crops

### 11. Example of Application to Electronic Device

the Technology of the Present Disclosure is not Limited to an Application to a Solid-state imaging device. In other words, the technology of the present disclosure can be generally applied to electronic devices using solid-state imaging devices in image capturing units (photoelectric conversion units), such as an imaging device for a digital still camera or a video camera, a mobile terminal device having an imaging function, and a copy machine using a solid-state imaging device in an image reading unit. The solid-state imaging device may be in the form of a single chip, or may be in a module form having an imaging function, in which an imaging unit and a signal processing unit or an optical system are packaged together.

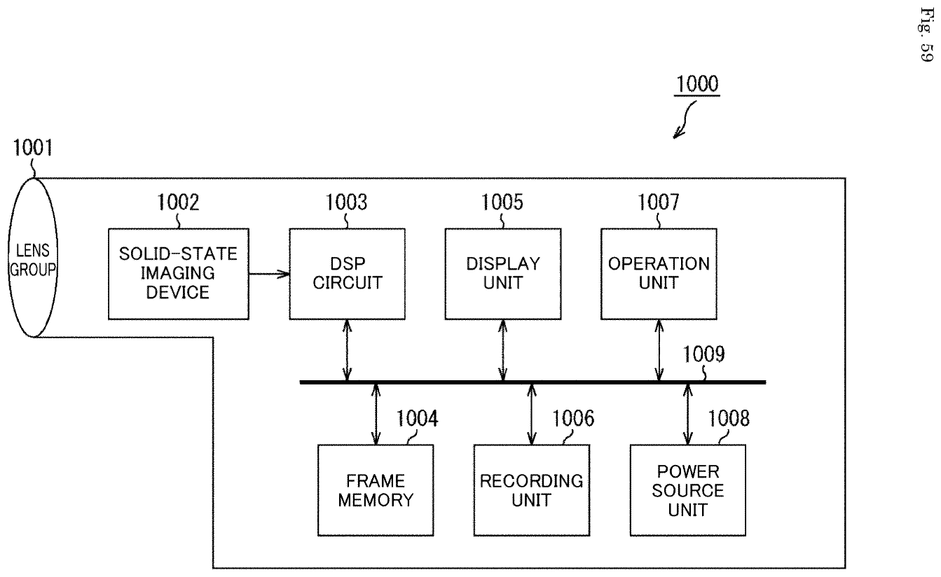

FIG. 59 is a block diagram illustrating a configuration example of an imaging device as an electronic device to which the technology of the present disclosure is applied.

An imaging device 1000 in FIG. 59 includes an optical unit 1001 constituted by a lens group and the like, a solid-state imaging device (an imaging device) 1002 having the configuration of the solid-state imaging device 1 in FIG. 1, and a digital signal processor (DSP) circuit 1003 serving as a camera signal processing circuit. The imaging device 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected via a bus line 1009.

The optical unit 1001 captures incident light (image light) from an object and forms an image on an image forming surface of the solid-state imaging device 1002. The solid-state imaging device 1002 converts the amount of incident light formed as an image on the image forming surface by the optical unit 1001 into an electrical signal for each pixel, and outputs the electrical signal as a pixel signal. As the solid-state imaging device 1002, it is possible to use the solid-state imaging device 1 in FIG. 1, that is, the solid-state imaging device that includes at least the first photoelectric conversion units and the second photoelectric conversion units that are formed in the semiconductor substrate and have different areas of photoelectric conversion regions, the element separation units that separates the first photoelectric conversion units and the second photoelectric conversion units, the color filters that are provided on the side of the incident light relative to the semiconductor substrate, the inter-pixel light shielding films that are provided between the color filters, and the on-chip lenses that collect the incident light on the photoelectric conversion units, suppresses leakage of light from the large pixels to the small pixels, and suppresses colored flare.

The display unit 1005 is configured of, for example, a thin display such as a liquid crystal display (LCD) or an organic electro luminescence (EL) display, for example, and displays a moving image or a still image captured by the solid-state imaging device 1002. The recording unit 1006 records the moving images or the still images captured by the solid-state imaging device 1002 in a recording medium such as a hard disk or a semiconductor memory.

The operation unit 1007 issues operation commands for various functions of the imaging device 1000 on the basis of operations of a user. The power supply unit 1008 appropriately supplies various types of power serving as operation power supplies of the DSP circuit 1003, the frame memory 1004, the display unit 1005, the recording unit 1006, and the operation unit 1007 to supply targets.

As described above, it is possible to suppress leakage of light from the large pixels to the small pixels and to suppress colored flare by using the solid-state imaging device 1 to which at least a part of the aforementioned first to fifth embodiments is applied as the solid-state imaging device 1002. Accordingly, a high captured image quality can be achieved in images captured by the imaging device 1000 employed in a video camera, a digital still camera, and furthermore, in a camera module for a mobile device, including a mobile phone.

### 12. Example of Application to Moving Body

The technology according to the present disclosure (the present technology) can be applied to various products. For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

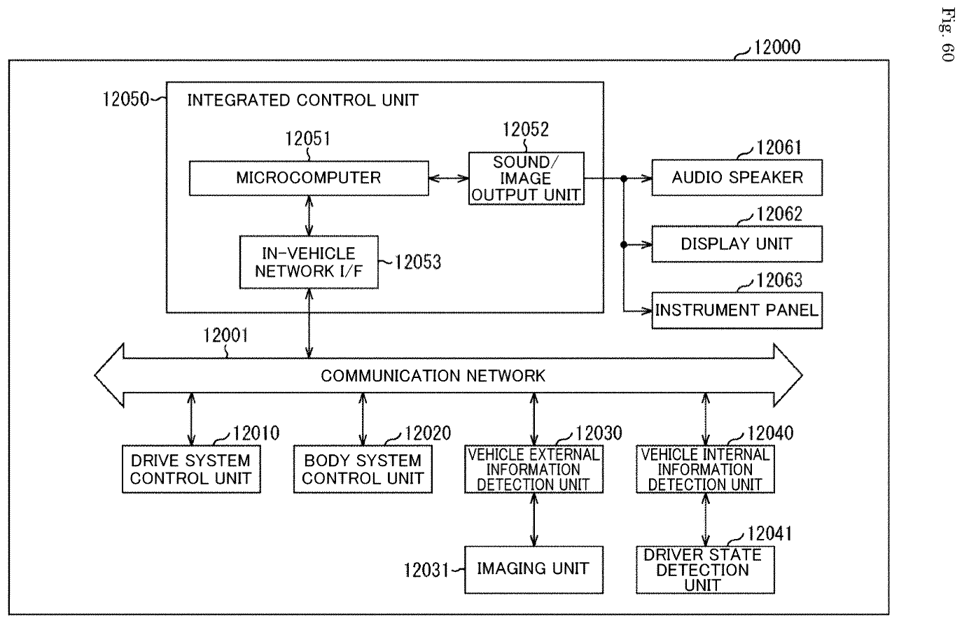

FIG. 60 is a block diagram illustrating a schematic configuration example of a vehicle control system, which is an example of a moving body control system to which the technology according to the present disclosure can be applied.

A vehicle control system 12000 includes a plurality of electronic control units connected thereto via a communication network 12001. In the example shown in FIG. 60, the vehicle control system 12000 includes a drive system control unit 12010, a body system control unit 12020, a vehicle external information detection unit 12030, a vehicle internal information detection unit 12040, and an integrated control unit 12050. In addition, as a functional configuration of the integrated control unit 12050, a microcomputer 12051, a sound/image output unit 12052, and an in-vehicle network interface (I/F) 12053 are shown.

The drive system control unit 12010 controls an operation of an apparatus related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle having the vehicle control system 12000 mounted thereon. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for peoples, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle acquired by the vehicle external information detection unit 12030 or the vehicle internal information detection unit 12040 and output a control command to the drive system control unit 12010. For example, the microcomputer 12051 can perform cooperative control for the purpose of obtaining functions of an Advanced Driver Assistance System (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle external information detection unit 12030 or the vehicle internal information detection unit 12040.

In addition, the microcomputer 12051 can output a control command to the body system control unit 12020 based on the information acquired by the vehicle external information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle external information detection unit 12030.

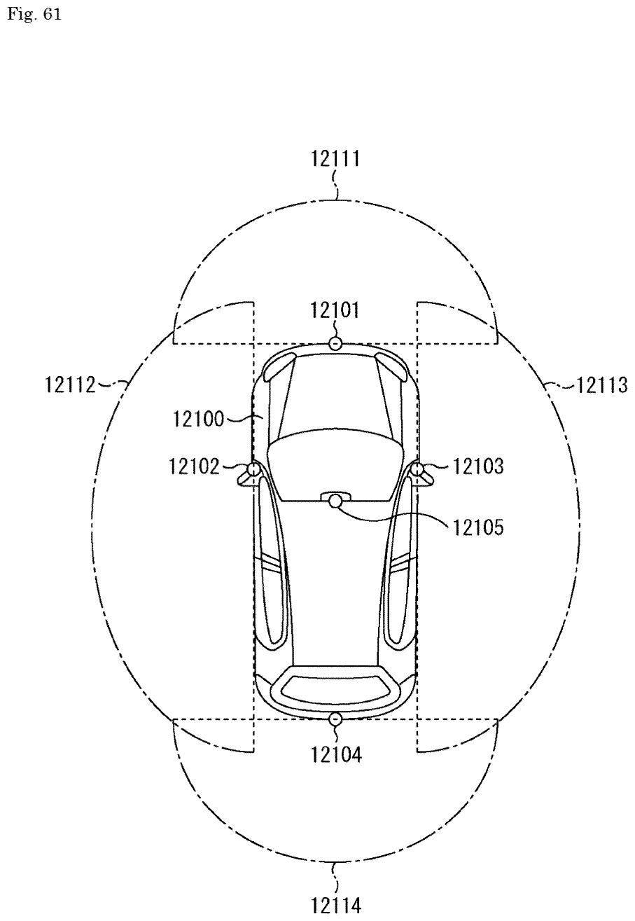

The sound/image output unit 12052 transmits an output signal of at least one of sound and an image to an output device capable of visually or audibly notifying a passenger or the outside of the vehicle of information. In the example of FIG. 60, an audio speaker 12061, a display unit 12062, and an instrument panel 12063 are illustrated as examples of the output device. The display unit 12062 may include at least one of an on-board display and a head-up display, for example. FIG. 61 is a diagram showing an example of an installation position of the imaging unit 12031.

In FIG. 61, a vehicle 12100 includes imaging units 12101, 12102, 12103, 12104, and 12105 as the imaging unit 12031.

The imaging units 12101, 12102, 12103, 12104, and 12105 are provided at positions such as a front nose, side-view mirrors, a rear bumper, a back door, and an upper portion of a windshield in a vehicle interior of the vehicle 12100, for example. The imaging unit 12101 provided on the front nose and the imaging unit 12105 provided in the upper portion of the windshield in the vehicle interior mainly acquire images of the front of the vehicle 12100. The imaging units 12102 and 12103 provided on the side-view mirrors mainly acquire images of a lateral side of the vehicle 12100. The imaging unit 12104 provided on the rear bumper or the back door mainly acquires images of the rear of the vehicle 12100. Front view images acquired by the imaging units 12101 and 12105 are mainly used for detection of preceding vehicles, pedestrians, obstacles, traffic lights, traffic signs, lanes, and the like.

FIG. 61 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, the closest three-dimensional object on a path along which the vehicle 12100 is traveling, which is a three-dimensional object traveling at a predetermined speed (for example, 0 km/h or higher) in the substantially same direction as the vehicle 12100, as a vehicle ahead by acquiring a distance to each three-dimensional object in the imaging ranges 12111 to 12114 and a temporal change of this distance (a relative speed with respect to the vehicle 12100) on the basis of the distance information obtained from the imaging units 12101 to 12104.

Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated traveling or the like in which a vehicle automatedly travels without the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the sound/image output unit 12052 controls the display unit 12062 so that a square contour line for emphasis is superimposed and displayed with the recognized pedestrian. In addition, the sound/image output unit 12052 may control the display unit 12062 so that an icon indicating a pedestrian or the like is displayed at a desired position.

An example of the vehicle control system to which the technology according to the present disclosure can be applied has been described above. The technology according to the present disclosure can be applied to the imaging unit 12031 within the configuration described above. Specifically, it is possible to apply the solid-state imaging device 1 to which at least a part of the first to fifth embodiments is applied as the imaging unit 12031. Applying the technology of the present disclosure to the imaging unit 12031 makes it possible to obtain a clearer captured image and obtain distance information while at the same time reducing the size of the unit. In addition, using the obtained shot image and the distance information makes it possible to reduce driver fatigue and increase the safety for the driver and the vehicle.

Although the solid-state imaging device in which the first conductivity type is the P type, the second conductivity type is the N type, and electrons are signal charges has been described in the above example, it is also possible to apply the present disclosure to a solid-state imaging device in which holes are signal charges. In this case, the first conductivity type can be the N type, the second conductivity type can be the P type, and each of the aforementioned semiconductor regions can be configured of a semiconductor region of an inverse conductivity type.

Also, the present disclosure can be applied not only to a solid-state imaging device that detects distribution of incident light amounts of visible light and captures the distribution as an image but also generally to a solid-state imaging device that captures, as an image, distribution of the incident light amounts of infrared light, X rays, particles, or the like, and in a broad sense, a solid-state imaging device (physical amount distribution detection device) such as a fingerprint detection sensor that detects distribution of other physical amounts, such as pressures or electrostatic capacities, and captures the distribution as an image.

Moreover, the technology of the present disclosure can be applied not only to the solid-state imaging devices but also generally to semiconductor devices that have other semiconductor integrated circuits.

The embodiments of the present disclosure are not limited to the above-described embodiments, and various modifications can be made without departing from the essential spirit of the technology of the present disclosure.

For example, a combination of all or part of the above-mentioned plurality of embodiments may be employed.

The advantageous effects described in the present specification are merely exemplary and are not limited, and other advantageous effects of the advantageous effects described in the present specification may be achieved.

The technology of the present disclosure can be configured as follows.

(1)

A solid-state imaging device including:
a pixel array unit in which a plurality of unit pixels are two-dimensionally arranged,
in which each of the unit pixels includes
a first photoelectric conversion unit that is formed in a semiconductor substrate,
a second photoelectric conversion unit that has a smaller area than an area of the first photoelectric conversion unit,
an inter-pixel light shielding film that is provided on at least a part of a boundary between the unit pixels on a side of incident light relative to the semiconductor substrate,
a spacer layer that is provided on the side of the incident light relative to the inter-pixel light shielding film, and
a light shielding wall that is provided on at least a part of the boundary between the unit pixels on the side of the incident light relative to the inter-pixel light shielding film and sections the spacer layer.
   (2)

The solid-state imaging device according to above (1), in which a minimum opening width of the inter-pixel light shielding film surrounding the second photoelectric conversion unit is formed to be equal to or less than a total height of the light shielding wall and the inter-pixel light shielding film.

(3)

The solid-state imaging device according to above (1) or (2), in which each of the unit pixels further includes a color filter in at least a partial region, and the light shielding wall is formed in at least a part of the same layer as the color filter.

(4)

The solid-state imaging device according to above (3), in which the light shielding wall is formed up to the same height as a height of an upper surface of the color filter.

(5)

The solid-state imaging device according to any one of above (1) to (4), in which the light shielding wall is configured of two or more stages.

(6)

The solid-state imaging device according to above (5), in which the light shielding wall including the two or more stages is provided to include deviation in a planar direction at a position where pupil correction is performed.

(7)

The solid-state imaging device according to any one of above (1) to (6), in which the light shielding wall is formed up to a predetermined depth of the semiconductor substrate.

(8)

The solid-state imaging device according to any one of above (1) to (7), in which a width of the inter-pixel light shielding film is formed to be larger than a width of the light shielding wall.

(9)

The solid-state imaging device according to above (8), in which in relation to a projecting portion of the inter-pixel light shielding film that projects in a planar direction relative to the light shielding wall, a width of the projecting portion on a side of the first photoelectric conversion unit is formed to be smaller than the projecting portion on a side of the second photoelectric conversion unit.

(10)

The solid-state imaging device according to any one of above (1) to (9), in which each of the unit pixels further includes an on-chip lens that collects incident light on the first photoelectric conversion unit or the second photoelectric conversion unit, and the on-chip lens has a lens shape including at least two planar regions.

(11)

The solid-state imaging device according to above (10), in which the shape of the on-chip lens is a rectangular parallelepiped shape.

(12)

The solid-state imaging device according to above (10), in which the shape of the on-chip lens is a pyramid or truncated pyramid shape.

(13)

The solid-state imaging device according to any one of above (10) to (12), in which the shape of the on-chip lens is a shape obtained by obliquely cutting corner portions between an upper surface and a side wall surface of the on-chip lens.

(14)

The solid-state imaging device according to any one of above (10) to (13), the shape of the on-chip lens is a shape having one or more vertexes in a case where a shape in which corner portions between surfaces are not rounded is adopted.

(15)

The solid-state imaging device according to any one of above (10) to (14), in which the shape of one of the on-chip lens that collects incident light on the first photoelectric conversion unit or the on-chip lens that collects incident light on the second photoelectric conversion unit is a hemispherical shape.

(16)

The solid-state imaging device according to any one of above (10) to (15), in which the on-chip lens is configured of an organic resin material.

(17)

The solid-state imaging device according to any one of above (10) to (16), in which the on-chip lens is configured of a material with a higher refractive index than refractive indexes of layers located below the on-chip lens.

(18)

The solid-state imaging device according to any one of above (1) to (9), in which each of the unit pixels further includes on-chip lenses that collect incident light on the first photoelectric conversion unit or the second photoelectric conversion unit, and the on-chip lenses include Fresnel-type on-chip lenses.

(19)

The solid-state imaging device according to above (18), in which the on-chip lens provided above the first photoelectric conversion unit includes lenses, the number of which is a first region splitting number, and lenses, the number of which is a second region splitting number that is different from the first region splitting number, and the on-chip lens provided on the second photoelectric conversion unit includes lenses, the number of which is a third region splitting number, and lenses, the number of which is a fourth region splitting number that is different from the third region splitting number.

(20)

The solid-state imaging device according to above (18) or (19), in which each of the unit pixels further includes color filters above the first photoelectric conversion unit and the second photoelectric conversion unit, and the number of split regions of the Fresnel-type on-chip lenses differs for each of a first color and a second color of the color filters.

(21)

The solid-state imaging device according to any one of above (18) to (20), in which only the on-chip lens provided above the first photoelectric conversion unit is the Fresnel-type on-chip lens.

(22)

The solid-state imaging device according to any one of above (18) to (21), in which the on-chip lens provided above the first photoelectric conversion unit and the on-chip lens provided above the second photoelectric conversion unit are the Fresnel-type on-chip lenses.

(23)

The solid-state imaging device according to any one of above (18) to (22), in which a position of the on-chip lens relative to a position of the first photoelectric conversion unit or the second photoelectric conversion unit is configured to differ depending on a pixel position inside the pixel array unit.

(24)

The solid-state imaging device according to any one of above (18) to (23), in which a shape of the on-chip lens is configured to differ depending on a pixel position inside the pixel array unit.

(25)

The solid-state imaging device according to any one of above (18) to (24), in which each of the unit pixels further includes a low N wall with a lower refractive index than a refractive index of the color filter in the same layer as the color filter.

(26)

A solid-state imaging device including:
a pixel array unit in which a plurality of unit pixels are two-dimensionally arranged,
in which each of the unit pixels includes
a first photoelectric conversion unit that is formed in a semiconductor substrate,
a second photoelectric conversion unit that has a smaller area than an area of the first photoelectric conversion unit,
a color filter that is provided on a side of incident light relative to the semiconductor substrate, and
a low N wall that is formed in the same layer as the color filter and has a lower refractive index than a refractive index of the color filter.
   (27)

The solid-state imaging device according to above (26), in which the low N wall includes an organic resin film.

(28)

The solid-state imaging device according to above (26) or (27), in which the low N wall is configured of a lamination including an inter-pixel light shielding film and a low refractive index resin film.

(29)

The solid-state imaging device according to any one of above (26) to (28), in which the low N wall is provided only on a boundary between the unit pixels.

(30)

The solid-state imaging device according to any one of above (26) to (28), in which the low N wall is provided on a boundary between the unit pixels and a boundary between the first photoelectric conversion unit and the second photoelectric conversion unit.

(31)

The solid-state imaging device according to any one of above (26) to (28), in which the low N wall is provided at a ¼ pixel cycle of the unit pixels.

(32)

The solid-state imaging device according to any of above (26) to (31), in which each of the unit pixels further includes one or more recessed portions that are formed in a light receiving surface of the semiconductor substrate.

(33)

The solid-state imaging device according to above (32), in which surfaces of the recessed portions are formed of (111) planes.

(34)

The solid-state imaging device according to above (32) or (33), in which the recessed portions are formed of inverted pyramid structures.

(35)

The solid-state imaging device according to above (32) or (33), in which the recessed portions are formed of trench structures.

(36)

The solid-state imaging device according to any one of above (32) to (35), in which the unit pixels include a plurality of the recessed portions.

(37)

The solid-state imaging device according to any one of above (32) to (36), in which each of the unit pixels includes the one or more recessed portions in each of the first photoelectric conversion unit and the second photoelectric conversion unit.

(38)

The solid-state imaging device according to any one of above (32) to (37), in which each of the unit pixels includes a plurality of the recessed portions in each of the first photoelectric conversion unit and the second photoelectric conversion unit.

(39)

The solid-state imaging device according to any one of above (32) to (38), in which the color filters are embedded inside the recessed portions.

(40)

The solid-state imaging device according to above (26), in which in a plan view, a width of at least a part of a first boundary portion which is a boundary between the first photoelectric conversion unit and the second photoelectric conversion unit is configured to be different from a width of a second boundary portion which is a boundary between the first photoelectric conversion unit and the first photoelectric conversion unit of another unit pixel.

(41)

The solid-state imaging device according to above (40), in which in a plan view, the width of the entire first boundary portion surrounding the second photoelectric conversion unit is configured to be different from the width of the second boundary portion.

(42)

The solid-state imaging device according to above (40) or (41), in which each of the first boundary portion and the second boundary portion is the low N wall.

(43)

The solid-state imaging device according to above (40) or (41), in which the first boundary portion and the second boundary portion are element separation units that separate the first photoelectric conversion unit and the second photoelectric conversion unit in the semiconductor substrate.

(44)

The solid-state imaging device according to above (40) or (41), in which the first boundary portion and the second boundary portion are an element separation unit and the low N wall that separate the first photoelectric conversion unit and the second photoelectric conversion unit in the semiconductor substrate.

(45)

The solid-state imaging device according to any one of above (40) to (44), in which the first boundary portion and the second boundary portion are lens separation units that separate an on-chip lens that collects incident light on the first photoelectric conversion unit or the second photoelectric conversion unit.

(46)

The solid-state imaging device according to any one of above (40) to (45), in which the first boundary portion and the second boundary portion are wiring layer separation units that separate a part of a wiring layer that is formed on a surface of the semiconductor substrate on a side opposite to a side of incident light.

### (Y1)

A solid-state imaging device including:
a pixel array unit in which a plurality of unit pixels are two-dimensionally arranged,
in which each of the unit pixels includes
a first photoelectric conversion unit that is formed in a semiconductor substrate,
a second photoelectric conversion unit that has a smaller area than an area of the first photoelectric conversion unit, and
on-chip lenses that collect incident light on the first photoelectric conversion unit or the second photoelectric conversion unit,
and
the on-chip lens has a lens shape including at least two planar regions.

### (M1)

A solid-state imaging device including:
a pixel array unit in which a plurality of unit pixels are two-dimensionally arranged,
in which each of the unit pixels includes
a first photoelectric conversion unit that is formed in a semiconductor substrate,
a second photoelectric conversion unit that has a smaller area than an area of the first photoelectric conversion unit, and
on-chip lenses that collect incident light on the first photoelectric conversion unit or the second photoelectric conversion unit,
and
the on-chip lenses include Fresnel-type on-chip lenses.

### (T1)

A solid-state imaging device including:
a pixel array unit in which a plurality of unit pixels are two-dimensionally arranged,
in which each of the unit pixels includes
a first photoelectric conversion unit that is formed in a semiconductor substrate,
a second photoelectric conversion unit that has a smaller area than an area of the first photoelectric conversion unit,
and
in a plan view, a width of at least of a first boundary portion which is a boundary between the first photoelectric conversion unit and the second photoelectric conversion unit is configured to be different from a width of a second boundary portion which is a boundary between the first photoelectric conversion unit and the first photoelectric conversion unit of another unit pixel.

### REFERENCE SIGNS LIST

1 Solid-state imaging device
11 Pixel array unit
21 Unit pixel
81 On-chip lens
81L Large on-chip lens
81S Small on-chip lens
100 Pixel
100L Large pixel
100L′ Large pixel
100S Small pixel
100S′ Small pixel
121 Semiconductor substrate
122 Wiring layer
131 Metal wiring
132 Inter-layer insulating film
133 Junction electrode
141 Element separation unit
181 Fixed charge film
182 Insulating film
183 Inter-pixel light shielding film
183L Projecting portion
183S Projecting portion
184 Light shielding wall
184A Light shielding wall
184B Light shielding wall
184B1 Light shielding wall
184B2 Light shielding wall
184C Light shielding wall
184C1 Light shielding wall
184C2 Light shielding wall
185 Spacer layer
186 Color filter
187 On-chip lens
187L Large on-chip lens
187S Small on-chip lens
188 Anti-reflection film
214 Protection film
301 Semiconductor substrate
311 Photoelectric conversion unit
311L First photoelectric conversion unit
311S Second photoelectric conversion unit
312 Element separation unit
313 Recessed portion
314 Insulating film
314′ Insulating film
315 Color filter
315′ Color filter
316 Low N wall
317 On-chip lens
321 Inter-pixel light shielding film
322 Low refractive index resin film
351 Recessed portion
400L Large pixel
410 On-chip lens
410L Large pixel
410S Small pixel
411 Photoelectric conversion unit
411L First photoelectric conversion unit
411S Second photoelectric conversion unit
421 Semiconductor substrate
422 Wiring layer
431 Metal wiring
432 Inter-layer insulating film
433 Junction electrode
441 Element separation unit
441L Element separation unit
441S Element separation unit
441S′ Element separation unit
451 Insulating film
452 Color filter
453 Low N wall
453L Low N wall
453S Low N wall
453S′ Low N wall
454 On-chip lens
454L Large on-chip lens
454S Small on-chip lens
454S′ Small on-chip lens
455 Anti-reflection film
471 Lens separation unit
481 Wiring layer separation unit
500L Large pixel
500S Small pixel
501 Semiconductor substrate
501L First photoelectric conversion unit
501S Second photoelectric conversion unit
511 Photoelectric conversion unit
511L First photoelectric conversion unit
511S Second photoelectric conversion unit
512 Element separation unit
513 Insulating film
514 Color filter
515 Inter-pixel light shielding film
516 On-chip lens
516L Large on-chip lens
516S Small on-chip lens
517 Anti-reflection film
521 On-chip lens
521L Large on-chip lens
521S Small on-chip lens
522 Inter-pixel light shielding film
600L Large pixel
600S Small pixel
601 Semiconductor substrate
601L First photoelectric conversion unit
601S Second photoelectric conversion unit
611 Photoelectric conversion unit
611L First photoelectric conversion unit
611S Second photoelectric conversion unit
611S′ Second photoelectric conversion unit
612 Element separation unit
612′ Element separation unit
631 Fixed charge film
632 Insulating film
633 Inter-pixel light shielding film
634 Color filter
635 On-chip lens
635′ On-chip lens
635L Large on-chip lens
635L′ Large on-chip lens
635S Small on-chip lens
635S′ Small on-chip lens
651 Second insulating film
652 Inter-pixel light shielding film
653 Low N wall
1000 Imaging device
1002 Solid-state imaging device

1. A solid-state imaging device comprising:
a pixel array unit in which a plurality of unit pixels are two-dimensionally arranged,
wherein each of the unit pixels includes
a first photoelectric conversion unit that is formed in a semiconductor substrate,
a second photoelectric conversion unit that has a smaller area than an area of the first photoelectric conversion unit,
an inter-pixel light shielding film that is provided on at least a part of a boundary between the unit pixels on a side of incident light relative to the semiconductor substrate,
a spacer layer that is provided on the side of the incident light relative to the inter-pixel light shielding film, and
a light shielding wall that is provided on at least a part of the boundary between the unit pixels on the side of the incident light relative to the inter-pixel light shielding film and sections the spacer layer.

2. The solid-state imaging device according to claim 1, wherein a minimum opening width of the inter-pixel light shielding film surrounding the second photoelectric conversion unit is formed to be equal to or less than a total height of the light shielding wall and the inter-pixel light shielding film.

3. The solid-state imaging device according to claim 1,
wherein each of the unit pixels further includes a color filter in at least a partial region, and
the light shielding wall is formed in at least a part of the same layer as the color filter.

4. The solid-state imaging device according to claim 3, wherein the light shielding wall is formed up to the same height as a height of an upper surface of the color filter.

5. The solid-state imaging device according to claim 1, wherein the light shielding wall is configured of two or more stages.

6. The solid-state imaging device according to claim 5, wherein the light shielding wall including the two or more stages is provided to include deviation in a planar direction at a position where pupil correction is performed.

7. The solid-state imaging device according to claim 1, wherein the light shielding wall is formed up to a predetermined depth of the semiconductor substrate.

8. The solid-state imaging device according to claim 1, wherein a width of the inter-pixel light shielding film is formed to be larger than a width of the light shielding wall.

9. The solid-state imaging device according to claim 8, wherein in relation to a projecting portion of the inter-pixel light shielding film that projects in a planar direction relative to the light shielding wall, a width of the projecting portion on a side of the first photoelectric conversion unit is formed to be smaller than the projecting portion on a side of the second photoelectric conversion unit.

10. The solid-state imaging device according to claim 1,
wherein each of the unit pixels further includes an on-chip lens that collects incident light on the first photoelectric conversion unit or the second photoelectric conversion unit, and
the on-chip lens has a lens shape including at least two planar regions.

11. The solid-state imaging device according to claim 10, wherein the shape of the on-chip lens is a rectangular parallelepiped shape.

12. The solid-state imaging device according to claim 10, wherein the shape of the on-chip lens is a pyramid or truncated pyramid shape.

13. The solid-state imaging device according to claim 10, wherein the shape of the on-chip lens is a shape obtained by obliquely cutting corner portions between an upper surface and a side wall surface of the on-chip lens.

14. The solid-state imaging device according to claim 10, wherein the shape of the on-chip lens is a shape having one or more vertexes in a case where a shape in which corner portions between surfaces are not rounded is adopted.

15. The solid-state imaging device according to claim 10, wherein the shape of one of the on-chip lens that collects incident light on the first photoelectric conversion unit or the on-chip lens that collects incident light on the second photoelectric conversion unit is a hemispherical shape.

16. The solid-state imaging device according to claim 10, wherein the on-chip lens is configured of an organic resin material.

17. The solid-state imaging device according to claim 10, wherein the on-chip lens is configured of a material with a higher refractive index than refractive indexes of layers located below the on-chip lens.

18. The solid-state imaging device according to claim 1,
wherein each of the unit pixels further includes on-chip lenses that collect incident light on the first photoelectric conversion unit or the second photoelectric conversion unit, and
the on-chip lenses include Fresnel-type on-chip lenses.

19. The solid-state imaging device according to claim 18, wherein the on-chip lens provided above the first photoelectric conversion unit includes lenses, the number of which is a first region splitting number, and lenses, the number of which is a second region splitting number that is different from the first region splitting number, and the on-chip lens provided on the second photoelectric conversion unit includes lenses, the number of which is a third region splitting number, and lenses, the number of which is a fourth region splitting number that is different from the third region splitting number.

20. The solid-state imaging device according to claim 18,
wherein each of the unit pixels further includes color filters above the first photoelectric conversion unit and the second photoelectric conversion unit, and
a region splitting number of the Fresnel-type on-chip lenses differs for each of a first color and a second color of the color filters.

21. The solid-state imaging device according to claim 18, wherein only the on-chip lens provided above the first photoelectric conversion unit is the Fresnel-type on-chip lens.

22. The solid-state imaging device according to claim 18, wherein the on-chip lens provided above the first photoelectric conversion unit and the on-chip lens provided above the second photoelectric conversion unit are the Fresnel-type on-chip lenses.

23. The solid-state imaging device according to claim 18, wherein a position of the on-chip lens relative to a position of the first photoelectric conversion unit or the second photoelectric conversion unit is configured to differ depending on a pixel position inside the pixel array unit.

24. The solid-state imaging device according to claim 18, wherein a shape of the on-chip lens is configured to differ depending on a pixel position inside the pixel array unit.

25. The solid-state imaging device according to claim 18, wherein each of the unit pixels further includes a low N wall with a lower refractive index than a refractive index of the color filter in the same layer as the color filter.

26. A solid-state imaging device comprising:
a pixel array unit in which a plurality of unit pixels are two-dimensionally arranged,
wherein each of the unit pixels includes
a first photoelectric conversion unit that is formed in a semiconductor substrate,
a second photoelectric conversion unit that has a smaller area than an area of the first photoelectric conversion unit,
a color filter that is provided on a side of incident light relative to the semiconductor substrate, and
a low N wall that is formed in the same layer as the color filter and has a lower refractive index than a refractive index of the color filter.

27. The solid-state imaging device according to claim 26, wherein the low N wall includes an organic resin film.

28. The solid-state imaging device according to claim 26, wherein the low N wall is configured of a lamination including an inter-pixel light shielding film and a low refractive index resin film.

29. The solid-state imaging device according to claim 26, wherein the low N wall is provided only on a boundary between the unit pixels.

30. The solid-state imaging device according to claim 26, wherein the low N wall is provided on a boundary between the unit pixels and a boundary between the first photoelectric conversion unit and the second photoelectric conversion unit.

31. The solid-state imaging device according to claim 26, wherein the low N wall is provided at a ¼ pixel cycle of the unit pixels.

32. The solid-state imaging device according to claim 26, wherein each of the unit pixels further includes one or more recessed portions that are formed in a light receiving surface of the semiconductor substrate.

33. The solid-state imaging device according to claim 32, wherein surfaces of the recessed portions are formed of (111) planes.

34. The solid-state imaging device according to claim 32, wherein the recessed portions are formed of inverted pyramid structures.

35. The solid-state imaging device according to claim 32, wherein the recessed portions are formed of trench structures.

36. The solid-state imaging device according to claim 32, wherein the unit pixels include a plurality of the recessed portions.

37. The solid-state imaging device according to claim 32, wherein each of the unit pixels includes the one or more recessed portions in each of the first photoelectric conversion unit and the second photoelectric conversion unit.

38. The solid-state imaging device according to claim 37, wherein each of the unit pixels includes a plurality of the recessed portions in each of the first photoelectric conversion unit and the second photoelectric conversion unit.

39. The solid-state imaging device according to claim 32, wherein the color filters are embedded inside the recessed portions.

40. The solid-state imaging device according to claim 26, wherein in a plan view, a width of at least a part of a first boundary portion which is a boundary between the first photoelectric conversion unit and the second photoelectric conversion unit is configured to be different from a width of a second boundary portion which is a boundary between the first photoelectric conversion unit and the first photoelectric conversion unit of another unit pixel.

41. The solid-state imaging device according to claim 40, wherein in a plan view, the width of the entire first boundary portion surrounding the second photoelectric conversion unit is configured to be different from the width of the second boundary portion.

42. The solid-state imaging device according to claim 40, wherein each of the first boundary portion and the second boundary portion is the low N wall.

43. The solid-state imaging device according to claim 40, wherein the first boundary portion and the second boundary portion are element separation units that separate the first photoelectric conversion unit and the second photoelectric conversion unit in the semiconductor substrate.

44. The solid-state imaging device according to claim 40, wherein the first boundary portion and the second boundary portion are an element separation unit and the low N wall that separate the first photoelectric conversion unit and the second photoelectric conversion unit in the semiconductor substrate.

45. The solid-state imaging device according to claim 40, wherein the first boundary portion and the second boundary portion are lens separation units that separate an on-chip lens that collects incident light on the first photoelectric conversion unit or the second photoelectric conversion unit.

46. The solid-state imaging device according to claim 40, wherein the first boundary portion and the second boundary portion are wiring layer separation units that separate a part of a wiring layer that is formed on a surface of the semiconductor substrate on a side opposite to a side of incident light.
